(19) United States
(12) Patent Application Publication
(10) Pub. No.: US 2019/0288147 A1
(43) Pub. Date: Sep. 19, 2019

(54) DILUTE NITRIDE OPTICAL ABSORPTION LAYERS HAVING GRADED DOPING

(71) Applicant: SOLAR JUNCTION CORPORATION, Tempe, AZ (US)

(72) Inventors: PRANOB MISRA, SANTA CLARA, CA (US); REBECCA ELIZABETH JONES-ALBERTUS, WASHINGTON, DC (US); TING LIU, SAN JOSE, CA (US); ILYA FUSHMAN, PALO ALTO, CA (US); HOMAN B. YUEN, SANTA CLARA, CA (US)

(21) Appl. No.: 16/431,521

(22) Filed: Jun. 4, 2019

Related U.S. Application Data
(63) Continuation-in-part of application No. 14/935,145, filed on Nov. 6, 2015, now Pat. No. 10,355,159.
Application No. 14/935,145 is a continuation of application No. 12/914,710, filed on Oct. 28, 2010, now Pat. No. 9,214,580.
Application No. 12/914,710 is a continuation-in-part of application No. 15/595,391, filed on May 15, 2017.
(60) Provisional application No. 62/340,294, filed on May 23, 2016.

(51) Int. Cl. H01L 31/0735; H01L 31/18; H01L 31/0687; H01L 31/0304; H01L 31/0725; H01L 31/065

(52) U.S. Cl. CPC H01L 31/0735; H01L 31/1844; H01L 31/0687; Y02E 10/544; H01L 31/03042; H01L 31/0725; H01L 31/065; H01L 31/03048

(57) ABSTRACT

Dilute nitride optical absorber materials having graded doping profiles are disclosed. The materials can be used in photodetectors and photovoltaic cells. Dilute nitride subcells having graded doping display improved efficiency, short circuit current density, and open circuit voltage.

This application is a continuation-in-part of U.S. application Ser. No. 14/935,145 filed on Nov. 6, 2015, now allowed, which is a continuation of U.S. application Ser. No. 12/914,710 filed on Oct. 28, 2010, issued as U.S. Pat. No. 9,214,580; and this application is a continuation-in-part of U.S. application Ser. No. 15/595,391 filed on May 15, 2017, which claims the benefit under 35 U.S.C. § 119(e) of U.S. Provisional Application No. 62/340,294 filed on May 23, 2016, each of which is incorporated by reference in its entirety.

### FIELD

The field relates to dilute nitride optical absorber materials having graded doping profiles. The materials can be used in photodetectors and photovoltaic cells. Dilute nitride subcells having graded doping display improved efficiency, short circuit current density, and open circuit voltage.

### BACKGROUND

The invention relates to compound semiconductor alloys comprising dilute nitride materials, and the use of the materials as optical absorbing layers for photodetectors, photovoltaic or solar cells and power converters, and in particular to dilute nitride materials wherein at least a portion of the dilute nitride material (such as a base region of a dilute nitride subcell in a photovoltaic cell) has a graded doping profile. Dilute nitride materials having graded doping profiles allow devices, such as photovoltaic cells, to exhibit improved quantum efficiencies across a broad range of irradiance energies.

III-V compound semiconductors materials are widely used in the fabrication of semiconductor optoelectronic devices such as light emitters, modulators, and detectors for a variety of applications. Devices capable of absorbing and detecting light may be used as photodetectors in communications systems, as power converters and as photovoltaic cells in tandem solar cells and multijunction solar cells. The bandgaps of the semiconductor materials used for such devices are chosen to (1) efficiently absorb the particular wavelength(s) of incident radiation relevant to a specific application and (2) convert that absorbed light into current, voltage, and/or energy as efficiently as possible. In the case of photodetectors for operation at telecommunications wavelengths, materials may be chosen to absorb efficiently at wavelengths between about 1.3 μm and 1.55 μm. A solar cell is a type of photodetector that is designed to efficiently absorb solar radiation.

Multijunction (MJ) solar cells may be formed using stacks of different semiconductor materials that have different bandgaps, selected to improve the absorption efficiency across the solar spectrum. Devices are typically fabricated on GaAs or Ge substrates. Selecting materials with the appropriate bandgaps, and in particular, material with a bandgap of approximately 1 eV, results in materials with different lattice constants needing to be integrated together, with metamorphic buffers being used to allow such integration. However, the use of metamorphic buffers requires thicker semiconductor layers, and can introduce defects, such as dislocations, into a material, based on lattice-mismatch between the different semiconductor materials. It is also very difficult to include more junctions within a device since additional bandgaps will occur for compositions of matter with yet further different lattice constants. Other factors equal, lattice-matched systems are preferable because they have proven reliability and require less semiconductor material than metamorphic solar cells.

Dilute nitrides are a class of III-V alloy materials (alloys having one or more elements from Group III on the periodic table along with one or more elements from Group V on the periodic table) with small fractions (e.g., <5 atomic percent) of nitrogen. These alloys are of particular interest for applications including telecommunications, power conversion and solar cells, since their bandgaps can be tuned between about 0.7 eV and 1.3 eV, while being lattice-matched or pseudomorphically strained to an underlying substrate such as GaAs or Ge. This makes it possible to integrate a lattice-matched dilute nitride material with an approximately 1 eV bandgap into a multi junction solar cell with substantial efficiency improvements.

GaInNAs, GaNAsSb and GaInNAsSb are some of the dilute nitride materials that have been studied as potentially useful for multi junction solar cells (see, e.g., A. J. Ptak et al., Journal of Applied Physics 98 (2005) 094501 and Yoon et al., Photovoltaic Specialists Conference (PVSC), 2009 34th IEEE, pp 76-80, 7-12, Jun. 2009; doi: 10.1109/PVSC.2009.5411736). Furthermore, the use of four-junction GaInP/GaAs/dilute-nitride/Ge solar cell structure holds the promise of efficiencies exceeding those of the standard metamorphic and lattice matched three junction cell, which at present are the benchmark for high-efficiency multi junction cell performance. (Friedman et al., Progress in Photovoltaics: Research and Applications 10 (2002), 331). To make that promise a reality, what is needed is a material that is lattice matched to GaAs and Ge with a band gap of near 1 eV and that produces open circuit voltage greater than 0.3 V with sufficient current to match the (Al)InGaP and (In)GaAs sub-cells in a multi-junction solar cell. It should be noted that a multi junction solar cell for terrestrial use is integrated into a concentrated photovoltaic system. Such a system employs concentrating optics consisting of dish reflectors or Fresnel lenses that concentrate sunlight onto the solar cell. It is possible that a concentrator's optics may attenuate light in a particular wavelength region which may be detrimental to the dilute nitride sub-cell. It is therefore of utmost importance that higher current be generated in the dilute nitride sub-cell so any loss due to the concentrator optics does not inhibit the performance of the multi junction solar cell.

In a multi junction solar cell, each of the sub-cells is attached in series to other sub-cells, typically using tunnel junction diodes to connect the individual sub-cells to one another. Since the total current generated by the full stack of sub-cells must pass through all the sub-cells, the sub-cell passing the least amount of current will be the current-limiting cell for the entire stack, and by the same virtue, the efficiency-limiting cell. It is therefore of greatest importance that each sub-cell be current matched to the other sub-cells in the stack for best efficiency. This is particularly important if dilute nitride sub-cells are to be used because dilute nitride semiconductor materials historically have been plagued with poor minority carrier transport properties that prove detrimental when incorporated into a larger solar cell.

Although dilute nitride alloys have other properties that make them desirable for use in multi-junction structures, particularly the flexibility with which their bandgaps and lattice constants can be fine-tuned as part of their design, the minority carrier lifetime and diffusion lengths for these sub-cells are typically worse than with conventional solar cell semiconductors such as GaAs and InGaP used in conventional multi junction solar cells, thus resulting in a loss of short circuit current, open circuit voltage or both. Moreover, the interface between the back-surface field and the base of the dilute nitride sub-cell may have high surface recombination velocity, which could further reduce the short circuit current and open circuit voltage of the sub-cell. As a result of these problems, photocurrents generated in dilute nitride sub-cells are typically lower than with more traditional materials. (D. B. Jackrel et al., Journal of Applied Physics 101 (114916) 2007).

Dopant variation in solar cells is generally known. See M. A. Green, Progress in Photovoltaics: Research and Applications 17 (2009). U.S. Pat. No. 7,727,795 is an example of a solar cell design using exponential doping in parts of a solar cell structure, evidently for multi junction solar cells grown in an inverted metamorphic and lattice mismatched structure. However, the application to dilute nitride sub-cells is not suggested and is not obvious, due to the anomalous characteristics of dilute nitrides. Dilute nitrides are a novel class of materials, which frequently exhibit different behavior than seen in traditional semiconductor alloys. For example, bandgap bowing as a function of alloy composition is very different in dilute nitrides as compared to traditional semiconductors (e.g., Wu et al., Semiconductor Science and Technology 17, 860 (2002)). Likewise, the standard dopants and doping profiles used for traditional semiconductors such as GaAs and InGaP do not result in comparable characteristics in dilute nitride semiconductors. For example, dopant incorporation in dilute nitrides has anomalous behavior. A Yu et al. paper reported that when dilute nitride thin films are doped heavily with Si, the Si and N mutually passivate each other's electronic activity (Yu et. al. App. Phys. Lett. 83, 2844 (2003)). Similarly, Janotti et. al. (Phys. Rev. Lett. 100, 045505 (2008)) suggested that while the physics of n-type and p-type doping in the parent compounds GaAs and GaN is well established, doping in GaAs₁₋ₓNₓ is much less explored and the interaction between extrinsic dopants and N in GaAs₁₋ₓNₓ alloys can lead to entirely new phenomena. They also pointed that rapid thermal annealing of Si-doped dilute (In)GaAsN alloys at temperatures above 800° C. leads to a drastic increase in the electrical resistivity. Due to the uncertainties associated with doping profiles and outcomes, and due to the unique properties of dilute nitrides, it is not apparent to one of ordinary skill how the concepts taught therein could be incorporated into a solar cell employing dilute nitride elements having portions subjected to controlled doping. Moreover, due to difficulties in doping the dilute nitride alloys, the literature teaches that dilute nitride alloys should not be doped (i.e., should be intrinsic) when incorporated into solar cell structures, for enhancement of the current collection (e.g., Ptak et al., J. Appl. Phys. 98, 094501 (2005); Volz et al., J. Crys. Growth 310, 2222 (2008)), and for increasing the minority carrier lifetime (Tukiainen et al., J. Green Eng. 5, 113-132 (2016). Rather, the literature teaches that the use of doping in the base of the dilute nitride solar cell leads to decreased performance.

Known as well, as previously discussed, dilute nitride cells were thought to have significant drawbacks such that their incorporation into multi junction solar cells would have led to substantial loss in the efficiency of such a solar cell, thus making dilute nitride cells less attractive commercially than other types of materials. It is desirable to improve current collection in dilute nitride based sub-cells without an accompanying loss of short circuit current, open circuit voltage or both.

### SUMMARY

According to the invention, a lattice-matched optoelectronic device, such as a photodetector or a solar cell, with a dilute nitride-based optically absorbing layer, such as a base region of a solar cell, has a graded doping profile in all or part of the dilute nitride layer, a graded doping profile being defined as a doping profile wherein the concentration of dopant increases or decreases from the top to bottom of the layer or within a portion of the layer, where top and bottom are defined relative to the orientation of the optoelectronic device in operation, the top being closest to the radiation source.

The dilute nitride base or optical absorber layer can have a bandgap within the range of 0.7 eV to 1.3 eV, or from 0.9 eV to 1.25 eV. A dilute nitride base or optical absorber layer can comprise a GaInNAsSb, GaInNAsBi, GaInNAsSbBi, GaNAsSb, GaNAsBi or GaNAsSbBi alloy, and can comprise an n-type dopant or a p-type dopant.

The optoelectronic device can be a solar cell with at least one dilute nitride based sub-cell. The dilute nitride based subcell includes an emitter layer with a larger bandgap than that of the dilute nitride region that faces incoming light, a dilute nitride base region underlying the emitter layer having a bandgap less than that of the emitter, followed by a back surface field, that has a larger bandgap than the dilute nitride region, overlying a substrate. Each of the emitter, base, and back surface field can be lattice-matched to a substrate such as a GaAs or Ge substrate. A Ge substrate can include a (Si,Sn)Ge material. A dilute nitride base can have a doping profile in which the dopant concentration at the dilute nitride base-back surface field interface is higher than the dopant concentration at the emitter-dilute nitride base interface. The doped dilute nitride subcells exhibit improved properties compared to undoped or intrinsically doped dilute nitride subcells.

An (In)GaAs emitter can overlie a dilute nitride base, the dilute nitride base can overlie a (In)GaAs back surface field, and a (In)GaAs back surface field can overlie a p-type GaAs or p-type Ge substrate. The (In)GaAs emitter can be doped with an n-type dopant such as Si, Te, or Se, or a combination of any of the foregoing. The dilute nitride base can include a first base portion and a second base portion. The first base portion can extend from the interface between the dilute nitride base and the (In)GaAs emitter to the interface between the first base portion and the second base portion. The first base portion can be intrinsically doped. The second base portion can comprise a dopant concentration that increases exponentially or linearly from the interface between the second base portion and the first base portion to the interface between the second base portion and the (In)GaAs back surface field. The second base portion can comprise a p-type dopant such as Be, C, Zn, or a combination of any of the foregoing.

In another embodiment of the invention, an (In)GaAs emitter overlies a dilute nitride base, which overlies an (In)GaAs back surface field on an n-type GaAs or Ge substrate. The (In)GaAs emitter can be doped with Be, C, Zn, or a combination of any of the foregoing. The dilute nitride base comprises a first base portion and a second base portion. The first base portion extends from its interface with the (In)GaAs emitter to its interface with the second base portion and can be intrinsically doped. The second base portion comprises a dopant concentration that increases exponentially or linearly from its interface with the first base portion to its interface with the (In)GaAs back surface field. The dopant in the second base portion can comprise Si, Te, Se, or a combination of any of the foregoing.

In another embodiment of the invention, an (In)GaAs emitter overlies a dilute nitride base, which overlies an (In)GaAs back surface field on an n-type GaAs or an n-type Ge substrate. The (In)GaAs emitter is doped with Be, C, Zn, or a combination of any of the foregoing. The dilute nitride base is characterized by an increase in dopant concentration from its interface with the (In)GaAs emitter to its interface with the (In)GaAs back surface field. The dopant in the dilute nitride base can comprise Si, Te, or Se, or a combination of any of the foregoing. The dilute nitride base can be characterized by a doping profile that is linear or exponential, and the (In)GaAs emitter can be characterized by a doping profile that is constant.

In another embodiment of the invention, an (In)GaAs emitter overlies a dilute nitride base, which overlies an (In)GaAs back surface field on a p-type GaAs or a p-type Ge substrate. The (In)GaAs emitter can be doped with Si, Te, Se, or a combination of any of the foregoing. The dilute nitride base is characterized by an increase in dopant concentration from its interface with the (In)GaAs emitter to its interface with the (In)GaAs back surface field. The dopant in the dilute nitride base can comprise Be, C, Zn, or a combination of any of the foregoing. The dilute nitride base and the (In)GaAs emitter can be characterized by a doping profile that is linear or exponential, and the (In)GaAs emitter can be characterized by a doping profile that is constant.

A lattice matched multi junction solar cell can have an upper sub-cell, a middle sub-cell and a lower dilute nitride sub-cell, the lower dilute nitride sub-cell having graded doping in the base and/or the emitter so as to improve its solar cell performance characteristics. In construction, the dilute nitride sub-cell may have the lowest bandgap and be lattice matched to a substrate; the middle sub-cell typically has a higher bandgap than the dilute nitride sub-cell and is lattice matched to the dilute nitride sub-cell. The upper sub-cell typically has the highest bandgap and is lattice matched to the adjacent sub-cell. In further embodiments, a multi junction solar cell according to the invention may comprise four, five or more sub-cells in which the one or more sub-cells may each contain dilute nitride alloys with a graded doping profile.

An optoelectronic device can be a photodetector with a dilute nitride optical absorber layer having a graded doping profile. The dilute nitride optical absorber can be situated between a first layer of a higher bandgap material having a first doping type and a second layer of a higher bandgap material having a second doping type, opposite to the first doping type that forms a p-i-n (or n-i-p) structure.

In one embodiment, the device is a photodetector and the doping profile for the dilute nitride layer is chosen to have two sub-regions, wherein no doping or uniform doping is used for the sub-region closer to the overlying wider-bandgap layer and graded doping is used in the other sub-region.

Common to all of these embodiments is a significant functional relationship between overall performance and the vertical distribution of doping in the base and/or emitter of the dilute nitride sub-cells, or the dilute nitride absorber layer of a photodetector. The doping concentration may be selected to have positional dependence, in which dependence varies as a function of vertical position in the base or the emitter. By way of an example, the doping could be designed to increase linearly or exponentially from the top to bottom in the base. Stated in mathematical terms, the doping concentration “d” has a functional dependence such that d−F(x) (i.e., doping is a function of position) where the x is the vertical position in the base and or emitter such that x is zero at the emitter/base junction and increases with distance from this junction. The manner and distribution of the doping (i.e., the function F) is selected to improve and ultimately to optimize the short circuit current and the open circuit voltage that would otherwise exist in the dilute nitride layer. The invention thus provides a lattice matched multi junction solar cell containing one or more dilute nitride sub-cells and having enhanced efficiency compared to that of a multi junction solar cell without such distribution of doping.

In one embodiment of the invention, the device is a solar cell and the doping profile for the dilute nitride layer is changed in the base of the solar cell such that it is the least at the emitter base junction and increases away from it. The precise distribution function for the increase is chosen to gain maximum current and voltage enhancement for the dilute nitride sub-cell.

In another embodiment, the device is a solar cell and the doping profile for the dilute nitride layer is chosen to have two sub-regions in the base, wherein no doping or uniform doping is used for the sub-region closer to the emitter-base junction and graded doping is used in the other sub-region.

The invention will be better understood by reference to the following detailed description in connection with the accompanying drawings.

### BRIEF DESCRIPTION OF THE DRAWINGS

FIG. 1 is a schematic of a device including a dilute-nitride layer overlying a GaAs or a Ge substrate.

FIG. 2 is a schematic of a device including a dilute nitride layer overlying a p-type GaAs or a p-type Ge substrate.

FIG. 3 is a schematic of a device including a dilute nitride layer overlying an n-type GaAs or an n-type Ge substrate.

FIG. 4 shows one configuration of various layers of a dilute nitride based solar subcell.

FIGS. 5A-5C show examples of subcell compositions for three-junction, four-junction, and five-junction photovoltaic cells.

FIG. 6 summarizes the composition and function of certain layers of a four junction (Al)InGaP/(Al,In)GaAs/Ga₁₋ₓInₓN_{y}As_{1-y-z}Sb_{z}/Ge multijunction photovoltaic cell.

FIG. 7 is a graph of an exemplary doping profile in the base layer of a dilute nitride sub-cell of a structure as shown in FIG. 1.

FIG. 8 is a graph of an exemplary doping profile of a dilute nitride sub-cell that contains constant doping in the front portion of the base layer and exponential doping in the back portion of the base layer.

FIG. 9 is a graph of exemplary doping profiles of a dilute nitride sub-cell that contains graded doping in the emitter layer.

FIG. 10 is a graph illustrating a comparison of the measured quantum efficiency of a dilute nitride sub-cell having graded doping in the base with that of a sub-cell without the graded doping.

FIG. 11 is a graph illustrating a measured current versus voltage characteristic in comparison to the short circuit current and the open circuit voltage for a dilute nitride sub-cell having graded doping in the base with that of one not having graded doping.

FIG. 12 shows a doping profile of a dilute nitride subcell overlying a p-type substrate.

FIG. 13 is a table showing attributes and properties for various dilute nitride subcells.

FIG. 14 shows the doping profile of dilute nitride subcell 4C determined by Secondary Ion Mass Spectrometry (SIMS).

FIG. 15 shows the doping profile of dilute nitride subcell 4B determined by SIMS.

FIG. 16 is a graph showing a comparison of the efficiency of dilute nitride subcells with and without exponential doping in the dilute nitride base, as described in FIG. 13 and FIG. 7.

FIG. 17 is a graph showing the dependence of current and voltage (IV curves) of dilute nitride subcells with and without exponential doping in the dilute nitride base, as listed in FIG. 13.

FIG. 18. is a table showing attributes and properties for various dilute nitride subcells, with and without doping.

FIGS. 19, 21, 23, 25, and 27 are graphs comparing the efficiency as a function of irradiance wavelength for the dilute nitride subcells described in FIG. 18.

FIGS. 20, 22, 24, 26, and 28 are graphs showing the dependence of current and voltage (IV curves) for the dilute nitride subcells described in FIG. 18.

FIG. 29 shows a doping profile of a dilute nitride subcell overlying an n-type substrate.

FIG. 30 shows a doping profile of a dilute nitride subcell overlying an n-type substrate.

FIG. 31 shows a doping profile of a dilute nitride subcell overlying an n-type substrate.

FIG. 32 shows the efficiency as a function of irradiance wavelength for Ga₁₋ₓInₓN_{y}As_{1-y-z}Sb_{z} subcells having different band gaps within the range from 0.82 eV to 1.24 eV.

FIG. 33A shows the efficiency as a function of irradiance energy for a Ga₁₋ₓInₓN_{y}As_{1-y-z}Sb_{z} subcell having a band gap of 1.113 eV, where x is 0.079, y is 0.017, and z is from 0.007 to 0.008.

FIG. 33B shows the efficiency as a function of irradiance energy for a Ga₁₋ₓInₓN_{y}As_{1-y-z}Sb_{z} subcell having a band gap of 1.115 eV, where x is 0.078, y is 0.0182, and z is from 0.004 to 0.008.

FIG. 33C shows the efficiency as a function of irradiance energy for a Ga₁₋ₓInₓN_{y}As_{1-y-z}Sb_{z} subcell having a band gap of 0.907 eV, where x is from 0.17 to 0.18, y is from 0.043 to 0.048, and z is from 0.012 to 0.016.

FIG. 34 shows the open circuit voltage Voc for Ga₁₋ₓInₓN_{y}As_{1-y-z}Sb_{z} subcells having different band gaps.

FIG. 35A shows the efficiency as a function of irradiance wavelength for each subcell of a three-junction (Al)InGaP/(Al,In)GaAs/Ga₁₋ₓInₓN_{y}As_{1-y-z}Sb_{z} photovoltaic cell measured using a 1 sun AM1.5D spectrum.

FIG. 35B shows the efficiency as a function of irradiance wavelength for each subcell of a three-junction (Al)InGaP/(Al,In)GaAs/Ga₁₋ₓInₓN_{y}As_{1-y-z}Sb_{z} photovoltaic cell measured using a 1 sun AM0 spectrum.

FIG. 35C shows a short circuit/voltage curve for a three junction (Al)InGaP/(Al,In)GaAs/Ga₁₋ₓInₓN_{y}As_{1-y-z}Sb_{z} photovoltaic cell measured using a 1 sun AM0 spectrum.

FIG. 36A shows a short circuit/voltage curve for a four junction (Al)InGaP/(Al,In)GaAs/Ga₁₋ₓInₓN_{y}As_{1-y-z}Sb_{z}/Ge photovoltaic cell.

FIG. 36B shows the efficiency as a function of irradiance wavelength for each subcell of the four-junction (Al)InGaP/(Al,In)GaAs/Ga₁₋ₓInₓN_{y}As_{1-y-z}Sb_{z}/Ge photovoltaic cell presented in FIG. 30A.

FIG. 37A shows the efficiency for each subcell of a four-junction (Al)InGaP/(Al,In)GaAs/Ga₁₋ₓInₓN_{y}As_{1-y-z}Sb_{z}/Ga₁₋ₓInₓN_{y}As_{1-y-z}Sb_{z} photovoltaic cell. The short circuit current density Jsc and band gap for each of the subcells are provided in Table 5.

FIG. 37B shows the efficiency of each subcell of a four-junction (Al)InGaP/(Al,In)GaAs/Ga₁₋ₓInₓN_{y}As_{1-y-z}Sb_{z}/Ga₁₋ₓInₓN_{y}As_{1-y-z}Sb_{z} photovoltaic cell. The short circuit current density Jsc and band gap for each of the subcells are provided in Table 5.

### DETAILED DESCRIPTION OF THE INVENTION

Dilute nitride semiconductor materials are advantageous as photovoltaic cell materials because the lattice constant can be varied substantially to match a broad range of substrates and/or subcells formed from semiconductor materials other than dilute nitrides. Dilute nitrides are also advantageous for photodetectors formed on GaAs substrates, allowing the optical absorption at extended wavelengths up to about 1.6 μm that are typically absorbed using InGaAs materials formed on (more fragile and more expensive) InP substrates. Examples of dilute nitrides include GaInNAsSb, GaInNAsBi, GaInNAsSbBi, GaNAsSb, GaNAsBi and GaNAsSbBi. The lattice constant and band gap of a dilute nitride can be controlled by the relative fractions of the different group IIIA and group VA elements. Thus, by tailoring the compositions (i.e., the elements and quantities) of a dilute nitride material, a wide range of lattice constants and band gaps may be obtained. Further, high quality material may be obtained by optimizing the composition around a specific lattice constant and band gap, while limiting the total Sb and/or Bi content, for example, to no more than 20 percent of the Group V lattice sites, such as no more than 10 percent of the Group V lattice sites. Sb and Bi are believed to act as surfactants that promote smooth growth morphology of the III-AsNV dilute nitride alloys. In addition, Sb and Bi can facilitate uniform incorporation of N and minimize the formation of nitrogen-related defects. The incorporation of Sb and Bi can enhance the overall nitrogen incorporation and reduce the alloy band gap. However, there are additional defects created by Sb and Bi and therefore it is desirable that the total concentration of Sb and/or Bi should be limited to no more than 20 percent of the Group V lattice sites. Further, the limit to the Sb and Bi content decreases with decreasing nitrogen content. Alloys that include In can have even lower limits to the total content because In can reduce the amount of Sb needed to tailor the lattice constant. For alloys that include In, the total Sb and/or Bi content may be limited to no more than 5 percent of the Group V lattice sites, in certain embodiments, to no more than 1.5 percent of the Group V lattice sites, and in certain embodiments, to no more than 0.2 percent of the Group V lattice sites. For example, Ga₁₋ₓInₓN_{y}As_{1-y-z}Sb_{z}, disclosed in U.S. Application Publication No. 2010/0319764, can produce a high-quality material when substantially lattice-matched to a GaAs or a Ge substrate in the composition range of 0.08≤x≤0.18, 0.025≤y≤0.04 and 0.001≤z≤0.03, with a band gap of at least 0.9 eV such as from 0.9 eV to 1.25 eV.

In certain embodiments of dilute nitrides provided by the present disclosure, the N composition is not more than 5.5 percent of the Group V lattice sites. In certain embodiments the N composition is not more than 4 percent, and in certain embodiments, not more than 3.5 percent.

Embodiments of the present disclosure include dilute nitride optical absorption layers, comprising GaInNAsSb, GaInNAsBi, or GaInNAsBiSb that are included in photodetectors or in the base layer of a dilute nitride subcell that can be incorporated into multijunction photovoltaic cells that perform at high efficiencies. The band gaps of the dilute nitrides can be tailored by varying the composition while controlling the overall content of Sb and/or Bi. Thus, a dilute nitride subcell with a band gap suitable for integrating with other subcells may be fabricated while maintaining substantial lattice-matching to each of the other subcells and to the substrate. The band gaps and compositions can be tailored so that the short-circuit current density produced by the dilute nitride subcells will be the same as or slightly greater than the short-circuit current density of each of the other subcells in the photovoltaic cell. Because dilute nitrides provide high quality, lattice-matched and band gap-tunable subcells, photovoltaic cells comprising dilute nitride subcells can achieve high conversion efficiencies. The increase in efficiency is largely due to less light energy being lost as heat, as the additional subcells allow more of the incident photons to be absorbed by semiconductor materials with band gaps closer to the energy of the incident photons. In addition, there will be lower series resistance losses in these multijunction photovoltaic cells compared to other photovoltaic cells due to the lower operating currents. At higher concentrations of sunlight, the reduced series resistance losses become more pronounced. Depending on the band gap of the bottom subcell, the collection of a wider range of photons in the solar spectrum may also contribute to the increased efficiency.

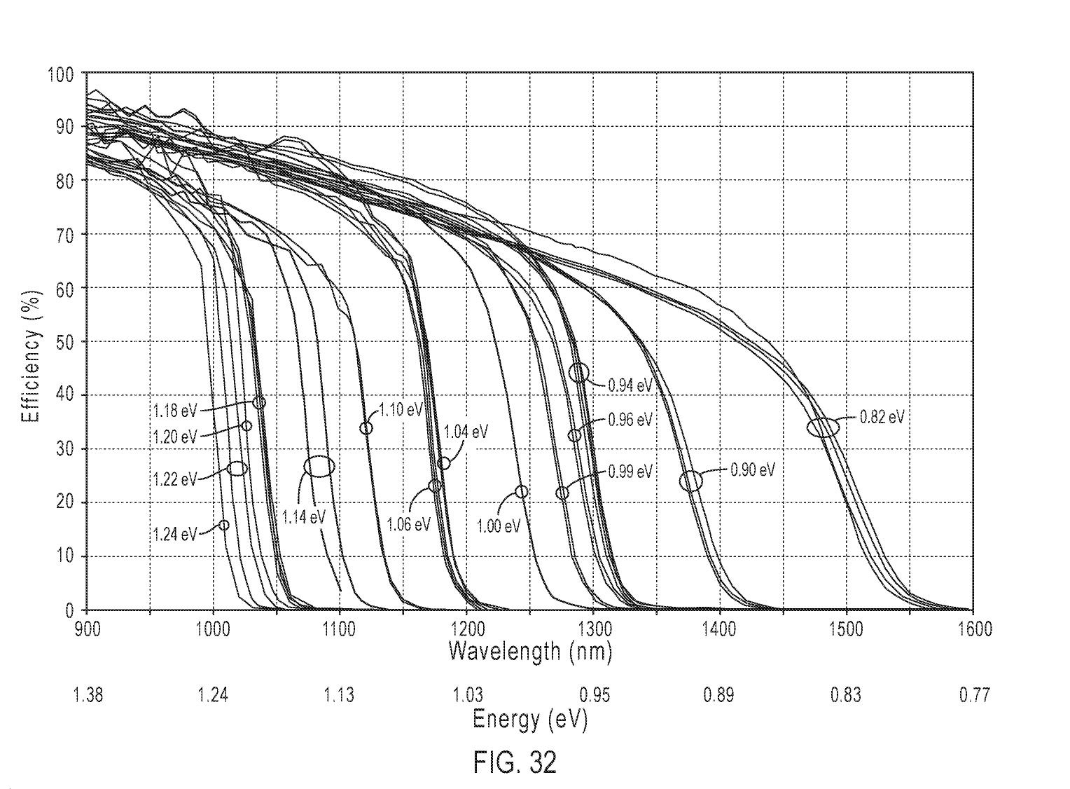

In some embodiments, the GaInNAsSb optical absorption layer, such as the base of a photovoltaic cell, can comprise Ga₁₋ₓInₓN_{y}As_{1-y-z}Sb_{z} having values for x, y, and z of 0.03≤x≤0.19, 0.008≤y≤0.055, and 0.001≤z≤0.05, and a band gap within the range from 0.9 to 1.25 eV. In some embodiments, a GaInNAsSb optical absorption layer can have a composition of Ga₁₋ₓInₓN_{y}As_{1-y-z}Sb_{z} having values for x, y, and z of 0.06≤x≤0.09, 0.01≤y≤0.03, and 0.003≤z≤0.02, and can have a band gap within the range from 1 eV to 1.16 eV. In some embodiments, a GaInNAsSb optical absorption layer can have a composition of Ga₁₋ₓInₓN_{y}As_{1-y-z}Sb_{z} having values for x, y, and z of 0.12≤x≤0.14, 0.025≤y≤0.035, and 0.005≤z≤0.015, and can have a band gap of around 0.96 eV. In some embodiments, a GaInNAsSb optical absorption layer for the base layer of a subcell of a photovoltaic cell can have a composition of Ga₁₋ₓInₓN_{y}As_{1-y-z}Sb_{z} having values for x, y, and z of 0.11≤x≤0.15, 0.025≤y≤0.04, and 0.003≤z≤0.015, and can have a band gap within the range from 0.95 eV to 0.98 eV. In some embodiments, a GaInNAsSb subcell can be characterized by an Eg/q-Voc equal to or greater than 0.55 V measured using a 1 sun AM1.5D spectrum at a junction temperature of 25° C. In some embodiments, a GaInNAsSb subcell can be characterized by an Eg/q-Voc from 0.4 V to 0.7 V measured using a 1 sun AM1.5D spectrum at a junction temperature of 25° C. The Ga₁₋ₓInₓN_{y}As_{1-y-z}Sb_{z} subcells characterized by the alloy compositions and band gaps disclosed in this paragraph can exhibit the efficiencies presented in FIG. 32. These Ga₁₋ₓInₓN_{y}As_{1-y-z}Sb_{z} subcells can exhibit high efficiency of greater than 70% and/or greater than 80% over a range of irradiation energies.

In some embodiments, a GaInNAsBi optical absorption layer can comprise Ga₁₋ₓInₓN_{y}As_{1-y-z}Bi_{z} having values for x, y, and z of 0.03≤x≤0.19, 0.008≤y≤0.055, and 0.001≤z≤0.015, and can have a band gap within a range from 0.9 to 1.25 eV. In some embodiments, a GaInNAsBi optical absorption layer can comprise Ga₁₋ₓInₓN_{y}As_{1-y-z}Bi_{z} having values for x, y and z of 0.06≤x≤0.09, 0.01≤y≤0.03, and 0.001≤z≤0.002, and can have a band gap within a range from 1 eV to 1.16 eV. In some embodiments, a GaInNAsBi optical absorption layer can comprise of Ga₁₋ₓInₓN_{y}As_{1-y-z}Bi_{z} having values for x, y and z of 0.12≤x≤0.14, 0.025≤y≤0.035, and 0.001≤z≤0.005, and can have a band gap of about 0.96 eV. In some embodiments, a GaInNAsBi optical absorption layer can comprise Ga₁₋ₓInₓN_{y}As_{1-y-z}Bi_{z} having values for x, y and z of 0.11≤x≤0.15, 0.025≤y≤0.04, and 0.001≤z≤0.005, and can have a band gap within a range from 0.95 eV to 0.98 eV. In some embodiments, a GaInNAsSbBi optical absorption layer can comprise Ga₁₋ₓInₓN_{y}As_{1-y-z1-z2}Sb_{z1}Bi_{z2} having values for x, y, z1, and z2 of 0.03≤x≤0.19, 0.008≤y≤0.055, and 0.001≤z1+z2≤0.05, and can have a band gap within a range from 0.9 to 1.25 eV. In some embodiments, a GaInNAsSbBi optical absorption layer can comprise Ga₁₋ₓInₓN_{y}As_{1-y-z}Sb_{z1}Bi_{z2} having values for x, y, z1, and z2 of 0.06≤x≤0.09, 0.01≤y≤0.03, and 0.001≤z1+z2≤0.02; and can have a band gap within a range from 1 eV to 1.16 eV. In some embodiments, a GaInNAsSbBi optical absorption layer can comprise Ga₁₋ₓInₓN_{y}As_{1-y-z}Sb_{z1}Bi_{z2} having values for x, y, z1, and z2 of 0.12≤x≤0.14, 0.025≤y≤0.035, and 0.001≤z1+z2≤0.015, and can have a band gap of about 0.96 eV. In some embodiments, a GaInNAsSbBi optical absorption layer can comprise Ga₁₋ₓInₓN_{y}As_{1-y-z1-z2}Sb_{z1}Bi_{z2} having values for x, y, z1, and z2 of 0.11≤x≤0.15, 0.025≤y≤0.04, and 0.001≤z1+z2 ≤0.015, and can have a band gap within a range from 0.95 eV to 0.98 eV.

Dilute nitride subcells provided by the present disclosure can be fabricated to provide a high efficiency. A high efficiency represents an efficiency greater than 70%, greater than 80%, or greater than 90% over at least a portion of incident photon energies between 0.95 eV and 1.38 eV (wavelengths from 1300 nm to 900 nm) depending on the band gap of the dilute nitride solar cell. Factors that contribute to providing high efficiency dilute nitride subcells include, for example, the band gaps of the individual subcells, which in turn depends on the semiconductor composition of the subcells, doping levels and doping profiles, thicknesses of the subcells, quality of lattice matching, defect densities, growth conditions, annealing temperatures and profiles, impurity levels, and the semiconductor alloy electronic properties such as recombination velocity, diffusion length, lifetime, and others.

Embodiments of the present invention includes dilute nitride subcells that are doped with elemental impurities and designed for incorporation into multijunction photovoltaic cells. In certain embodiments provided by the present disclosure, the semiconductor layers can be fabricated using molecular beam epitaxy (MBE) and/or chemical vapor deposition (CVD). Certain embodiments of the invention display improved performance characteristics due to specific doping/impurity profiles, i.e. the tailored vertical distribution of one or more elemental dopants/impurities, within the dilute nitride base and/or the emitter of the subcell. Due to interactions between the different elements, as well as factors such as the strain in the layer, the relationship between composition and band gap for dilute nitrides is not a simple function of composition. As the composition is varied within the dilute nitride material system, the growth conditions need to be modified. For example, for (Al,In)GaAs, the growth temperature will increase as the fraction of Al increases and decrease as the fraction of In increases, in order to maintain the same material quality. Thus, as a composition of either the dilute nitride material or the other subcells of the multijunction photovoltaic cell is changed, the growth temperature as well as other growth conditions must be adjusted accordingly. The thermal dose applied to dilute nitrides after MBE or CVD growth, which is controlled by the intensity of heat applied for a given duration of time (e.g., application of a temperature of 600° C. to 900° C. for a duration of between 10 seconds to 10 hours), also affects the relationship between band gap and composition. This thermal annealing step may be performed in an atmosphere that includes air, nitrogen, arsenic, arsine, phosphorus, phosphine, hydrogen, forming gas, oxygen, helium and any combination of the preceding materials. In general, the band gap changes as thermal annealing parameters change. This is also true for doping profiles. The presence of dopants further complicates determination of the optimal combination of elements, growth parameters and thermal annealing conditions that will produce suitable high efficiency subcells having a specific band gap and vertical distribution of dopants.

Doping introduces an electric field in addition to the built-in electric field at the emitter-base junction of a subcell. The minority carriers generated by the photovoltaic effect in the subcell structure are affected by this additional electric field, influencing current collection. Positioning of a doping profile across a dilute nitride base layer can be designed to generate an optimized additional electric field that pushes minority carries to the front of the junction, resulting in a high recombination velocity and substantial improvement in minority carrier collection. This disclosure describes dilute nitride subcells with improved performance characteristics due to graded doping, where the dopant concentration changes with the vertical axis of a subcell. The doping profile may not be constant, but may be linear, exponential or have other dependence on position, causing different effects on the electric field. When dilute nitride subcells with graded doping are compared to conventional photovoltaic subcells with a wide, uniform region of intrinsic doping (i.e., undoped), for enhanced carrier collection (an accepted best practice for work with conventional semiconductor materials), graded doping dilute nitride subcells, and in particular exponentially doped dilute nitride subcells, exhibit superior performance characteristics. Position-dependent doping can also be applied to the emitter, further increasing current collection for the subcell when used in conjunction with doping of the dilute nitride base.

Various metrics can be used to characterize the quality of a dilute nitride subcell including, for example, the Eg/q-Voc, the efficiency over a range of irradiance energies, the open circuit voltage Voc and the short circuit current density Jsc. The open circuit voltage Voc and short circuit current density Jsc can be measured on subcells having a dilute nitride base layer with a thickness within the range from 1 μm to 4 μm. Those skilled in the art can understand how to extrapolate the open circuit voltage Voc and short circuit current density Jsc measured for a subcell having a particular dilute nitride base thickness to other subcell thicknesses. The Jsc and the Voc are the maximum current density and voltage, respectively, from a photovoltaic cell. However, at both of these operating points, the power from the photovoltaic cell is zero. The fill factor (FF) is a parameter which, in conjunction with Jsc and Voc, determines the maximum power from a photovoltaic cell. The FF is defined as the ratio of the maximum power produced by the photovoltaic cell to the product of Voc and Isc. Graphically, the FF is a measure of the “squareness” of the photovoltaic cell and is also the area of the largest rectangle which will fit within the IV curve. Graded doping subcells have improved values for Jsc, Voc, and FF.

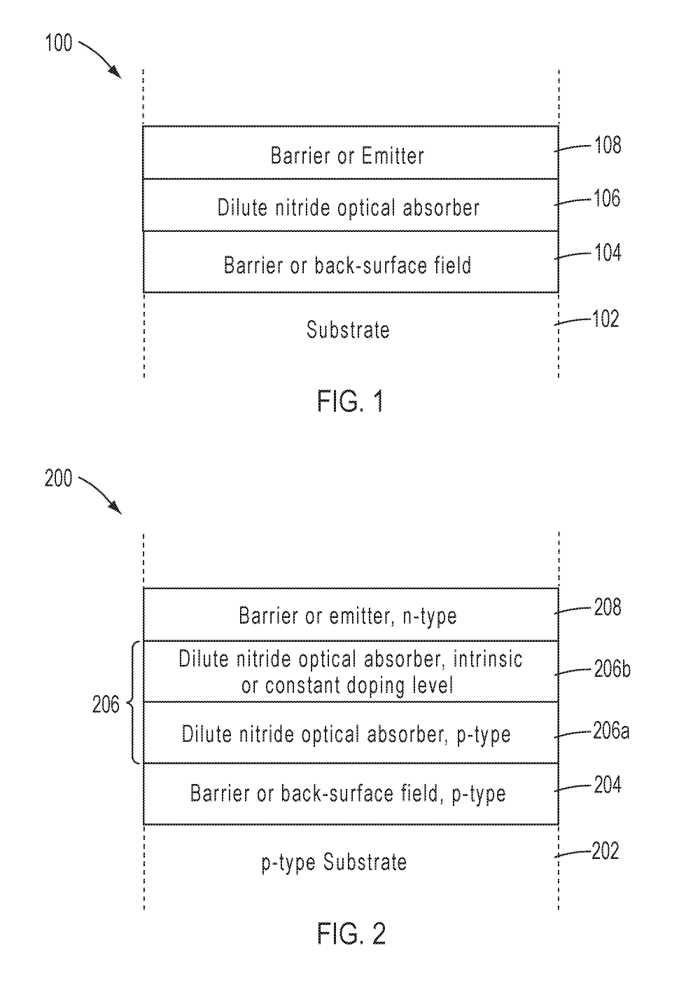

FIGS. 1, 2 and 3 show cross-section examples of devices including dilute nitride optical absorption layers overlying a substrate. In FIG. 1, the device includes a substrate 102. For photodetectors and photovoltaic cells, the substrate is typically GaAs or Ge, although other substrates including (Si,Sn)Ge, InP, and GaSb may also be used. A back-surface field or barrier layer 104 overlies substrate layer 102. Layer 104 includes (In)GaAs, which has a larger bandgap than the overlying dilute nitride optical absorber layer 106. When the device is a photovoltaic cell, layer 104 is usually referred to as a back-surface field layer. A dilute nitride optical absorber layer 106 overlies layer 104. Examples of dilute nitride alloys that can be used for the dilute nitride base include GaInNAsSb, GaInNAsBi, GaInNAsSbBi, GaNAsSb, GaNAsBi and GaNAsSbBi. In certain embodiments, dilute nitride optical absorber layer comprises GaInNAsSb, and in certain embodiments, GaInNAsSbBi. In some embodiments, the thickness of dilute nitride optical absorber layer 106 is between 1,000 nm and 3,000 nm. In some embodiments, the thickness of layer 106 is between 1,000 nm and 2,000 nm. When used as a layer in a photovoltaic cell, optical absorption layer 106 is referred to as a base layer. A barrier or emitter layer 108 overlies dilute nitride optical absorber layer 106, and includes (In)GaAs, which has a larger bandgap than the underlying dilute nitride optical absorber layer 106. When used as a layer in a photovoltaic cell, layer 108 is referred to as an emitter. In some embodiments, the thickness of layer 108 is between 50 nm and 600 nm. In some embodiments of the invention, the thickness of layer 108 is between 100 nm and 200 nm, or between 200 nm and 500 nm.

The thickness of each layer forming a subcell, or a photodetector, can vary in order to optimize current and voltage outputs of the subcell, or the photocurrent produced by a photodetector. This is especially true for the optimal thickness of the dilute nitride base layer 106, where optimal thickness is different for each type of dilute nitride alloy as thickness must change with varying elemental composition. The dilute nitride base 106 and the (In)GaAs emitter 108 can have doping profiles that are linear, exponential, or constant. In some embodiments, the dopant concentration in the dilute nitride base 106 increases linearly or exponentially from the (In)GaAs emitter 108 to the (In)GaAs back surface field 104. In some embodiments, the (In)GaAs emitter 108 has a constant doping profile.

In some embodiments, such as device 200 shown in FIG. 2, the dopant concentration is constant in a first portion of the dilute nitride base 206b, and in a second portion of the dilute nitride base 206a increases linearly or exponentially from the (In)GaAs emitter 208 to the (In)GaAs back surface field 204. Using a dilute nitride subcell as an example, device 200 can comprise an n-type (In)GaAs emitter 208 having a thickness within the range from 50 nm to 600 nm, a first base portion 206b having a thickness within the range from 0 nm to 1,000 nm or from 300 nm to 700 nm and characterized by either intrinsic (or unintentional) doping or a constant doping level, a p-doped second base portion 206a having a thickness within the range from 400 nm to 3,500 nm, or from 1000 nm to 2000 nm, and a p-type (In)GaAs back surface field layer 204. The dilute nitride subcell can overly a p-type Ge or p-type GaAs substrate 202. Dopant types and doping profiles will be described in further detail later.

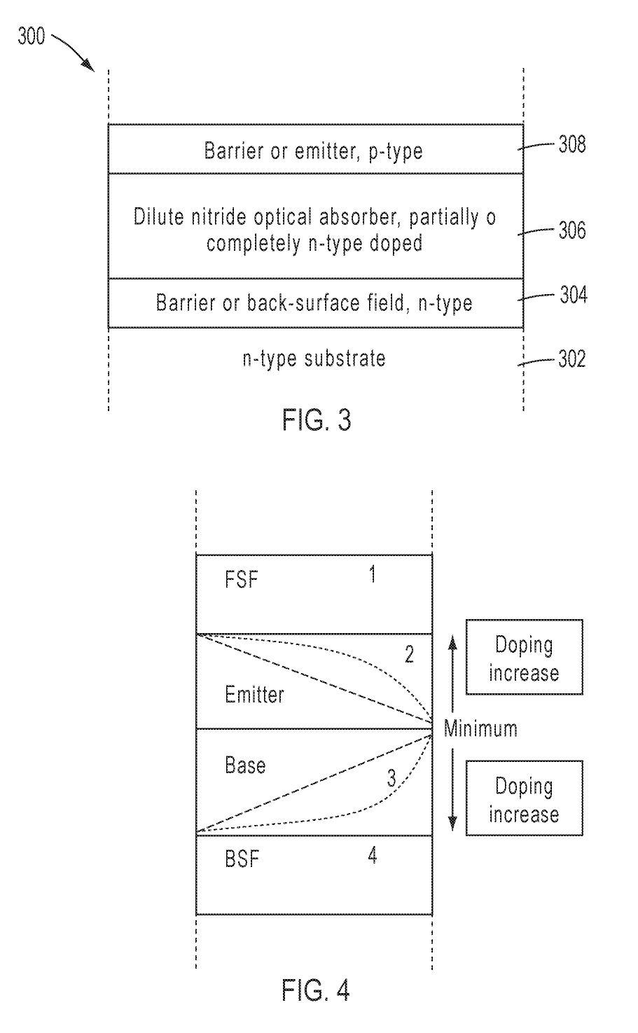

In FIG. 3, device 300 is similar to device 200. Using a dilute nitride subcell as an example, the dilute nitride subcell can have an n-type Ge or GaAs substrate 302. An n-type (In)GaAs back surface field 304 overlies the substrate. A dilute nitride base layer 306 with a thickness between 1,000 nm and 3,500 nm, or between 1,000 nm and 2,000nm) overlies the (In)GaAs back surface field 304. An (In)GaAs emitter layer 308, with a thickness between 50 nm and 600 nm, or between 200 nm and 500 nm or between 100 nm and 200 nm forms the top layer of the dilute nitride subcell. Dopant types and doping profiles will be described in further detail later.

FIG. 4 denotes an exemplary case in which the doping of the base 3 and the emitter 2 of a dilute-nitride subcell has either linearly graded dependence or exponentially graded dependence on the position as measured from the emitter-base junction. Multiple permutations using these exemplary cases can be obtained including an emitter having linear doping and a base having exponential doping and vice versa. Typically, the doping (i.e., impurity concentration) will lie substantially between 1×10¹⁵/cm³ and 1×10¹⁹/cm³, where the lowest doping level is nearest to the emitter-base junction (2-3) and the highest doping level is furthest from the emitter-base junction (1-2) and/or (3-4). In this embodiment, such a positional dependence of doping introduces an electric field in addition to the built-in electric field at the emitter-base junction 2-3. The minority carriers generated by the photovoltaic effect in the sub-cell structure demonstrated in FIG. 4 will be affected by such an electric field. The exact profile of the doping can be varied to introduce an optimized field for substantial improvement in minority carrier collection. This internal field has been determined to improve the current and/or voltage of the solar cell compared to a solar cell with uniform doping. It is determined by this invention that, in dilute nitride-type cells, graded doping is advantageous, as compared to the previously accepted best practice of using a wide intrinsic, i.e., undoped, region to enhance carrier collection, because it yields higher short circuit current, higher open circuit voltage and better fill factors.

In characterizing doping profiles, a constant doping profile refers to a semiconductor layer which is intentionally doped to have a certain concentration of dopant across the thickness of the layer. For example, a semiconductor layer such as the (In)GaAs emitter layer can be doped with a p-type dopant that is, for example, within 1%, within 5%, or within 10% of a nominal concentration. A constant doping concentration refers to a doping concentration that varies less than 1%, less than 5%, or less than 10% from a nominal dopant concentration across the thickness of a layer. For a constant doping profile, a target doping concentration may be intended that nevertheless may vary due to experimental conditions. An exponential doping profile is characterized by a dopant concentration across a layer or portion of a layer that increases exponentially from a beginning dopant concentration to a final dopant concentration. An exponential dopant concentration may increase by one, two, or in certain embodiments, three orders of magnitude across a layer. Again, an exponential dopant concentration may deviate from a true exponential profile due to experimental conditions. A linear doping profile refers to a doping profile that linearly increases across the thickness of a layer.

A practitioner skilled in the art understands that other types of layers may be incorporated or omitted in a photovoltaic cell to create a functional device and are not described here in detail. Briefly, these other types of layers include, for example, coverglass, anti-reflection coating, contact layers, front surface field, tunnel junctions, electrical contacts and a substrate or wafer handle. Each of these layers requires design and selection to ensure that its incorporation into a multijunction photovoltaic cell does not impair high performance. For example, a front-surface field layer may overly or be adjacent to an emitter layer (108, 208, 308) shown in FIGS. 1, 2 and 3.

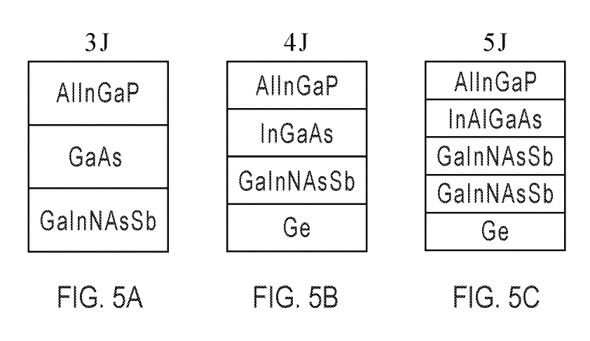

A dilute nitride optical absorber layer (or base layer) can be incorporated into dilute nitride-containing multijunction photovoltaic cells with differing numbers of junctions or subcells (see for example FIGS. 5A-5C showing devices with 3, 4, and 5 subcells, respectively). FIG. 5C shows an example with two dilute nitride subcells, each of which can, independently, have graded doping profiles. The inclusion of more subcells within a multijunction device can improve current collection efficiency within the device, increase the voltage and can lead to higher external quantum efficiencies.

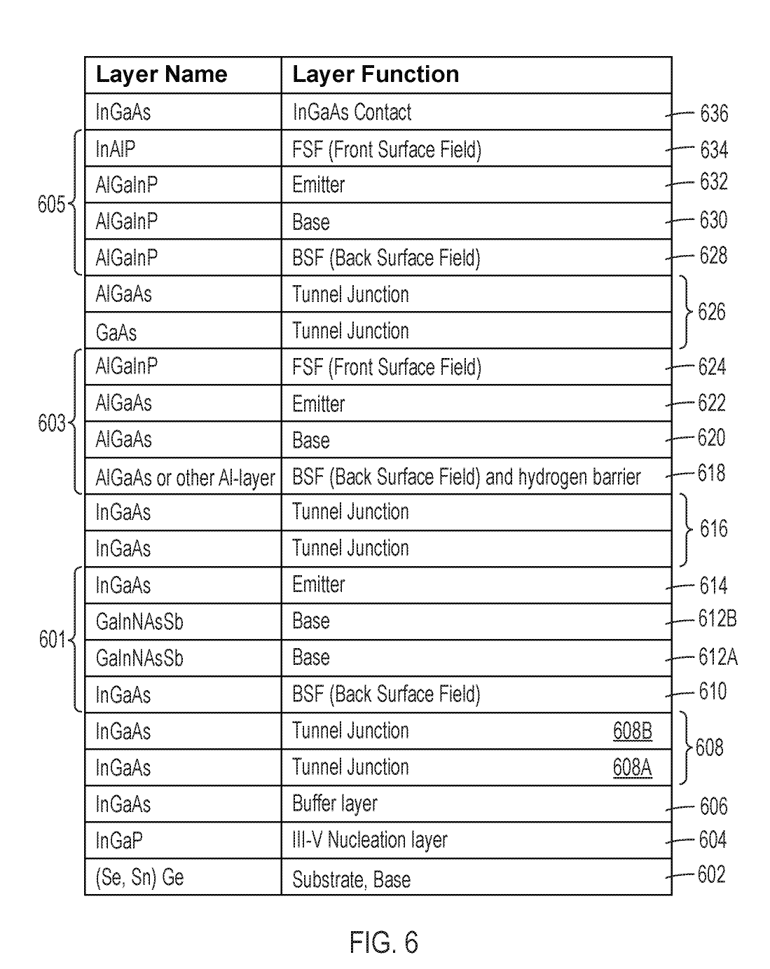

As discussed herein, FIG. 6 shows an example structure with these additional elements. Further, additional elements may be present in a complete photovoltaic cell, such as buffer layers, tunnel junctions, back surface field, window, emitter, and front surface field layers. In this structure, dilute nitride subcell 601 includes GaInNAsSb base layers 612A and 612B, corresponding to layers 206A and 206B in FIG. 2B. FIG. 6 shows a multijunction solar cell including a first subcell 601 overlying tunnel junctions 608, a second subcell 603 overlying tunnel junctions 616, and a third subcell 605 overlying tunnel junctions 626. As shown in FIG. 6, each subcell includes an emitter, a base comprising one or two layers, and a back surface field. The second and third subcells include a front surface field overlying the emitter.

By convention in the photovoltaic cell and photodetector art, the term “front” refers to the exterior surface of the cell (photodetector) that faces the radiation source, and the term “back” refers to the exterior surface that is away from the source. As used in the figures and descriptions, “back” is synonymous with “bottom” and “front” is synonymous with “top.”

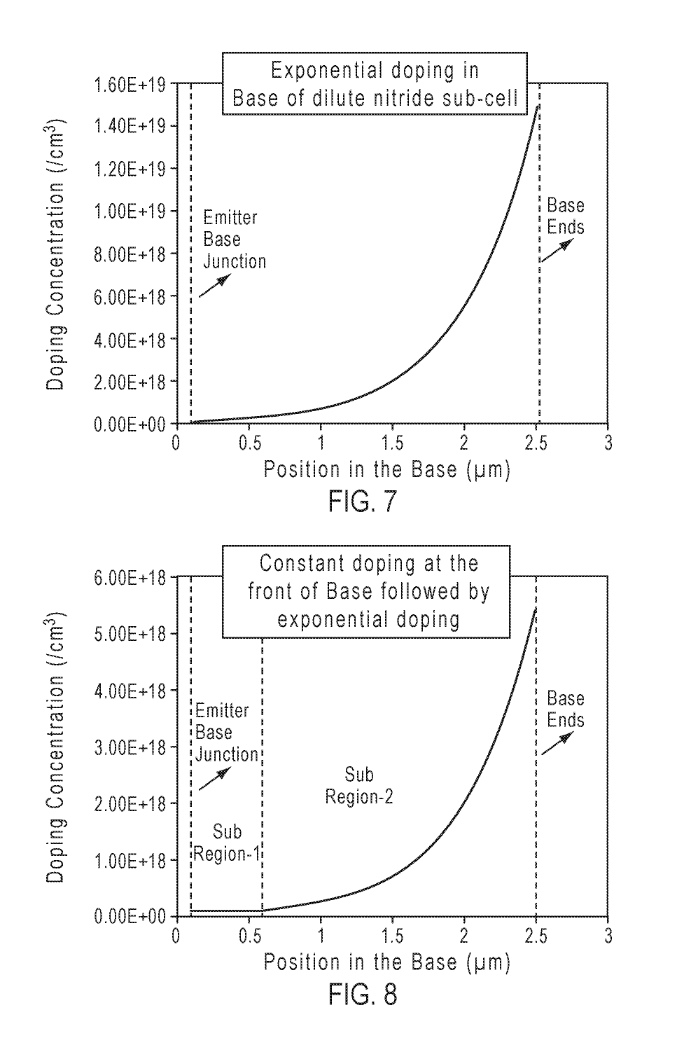

An example of a graded doping profile for a dilute nitride optical absorber shown in FIG. 1 is illustrated by the graph of FIG. 7, wherein the dilute nitride layer is the base layer of a dilute nitride subcell, and wherein an example of the exponential doping with depth is depicted, the least dopant being at the base-emitter junction. As an exemplary case where the dopant concentration varies in a manner as explained in connection with FIG. 7, during manufacturing the dopant flux impinging the epitaxial surface during growth is changed exponentially, keeping other variable parameters as constant. For example, the doping is given by:

Doping=A×e^{Bx};

where A=1×10¹⁵/cm³ to 2×10¹⁷/cm³, B=0.1/μm to 10/μm and x is depth. Using this range would yield doping between 1×10¹⁵/cm³and 1×10¹⁹/cm³ depending on the base thickness. In each case, the dopant flux is minimum at the emitter/base junction (the interface between 108 and 106). The value of the flux is preset to attain a desired value of the dopant concentration in the epitaxial layer. In this example, the thicknesses for the layers shown are 100 nm to 500 nm for back surface field layer 104, from 1000 nm to 2000 nm for dilute nitride optical absorber 106, and from 100 nm to 200 nm for emitter layer 108. An additional front-surface field layer can overly and be adjacent to the emitter layer 108 and can have a thickness between 10 nm and 500 nm, or between 10 nm and 100 nm.

Referring to FIG. 2, the positional dependence of the doping is developed in such a way that the base layer has two sub-regions 206A and 206B. The region closer to the front (i.e., the top) of the emitter-base junction (layer 206B in FIG. 2) has constant doping or no deliberate doping, as illustrated by the dotted line in sub-region 3. For example, the doping is given by

Doping=A;

where A is a constant and ranges from 0 to 2×10¹⁷/cm³. When there is no deliberate doping, the doping level in 206A may be an intrinsic or an unintentional doping level, which may be between about 1×10¹⁵/cm³and 1×10¹⁶/cm³. The remainder of the base (206A) has a doping profile that varies as a function of position in a manner similar to that explained for the previously described embodiment and as illustrated by the dotted line in sub-region 4 of this figure. Using this would yield doping between 1×10¹⁵/cm³and 1×10¹⁹/cm³ in the base for a thickness of 0 μm to 3 μm of the base.

The thickness of each sub-region can be varied in order to optimize the current and voltage output of the sub-cell. In particular, the optimal thicknesses will be different for different dilute nitride materials, and as the composition of the dilute nitride material changes. An example of such a doping profile is shown in FIG. 8. Sub-region 1 (layer 206B) has either constant doping or is undoped. This region is closer to the emitter-base junction. Sub-region 2 (layer 206A) has graded doping which varies exponentially as a function of the depth position in the sub-region 2. The position is measured with respect to the emitter-base junction, at the interface between layer 206B and 208, or with respect to the interface between the two base sub-regions 206A and 206B. As an exemplary case where the dopant concentration varies in a manner as explained in connection with FIG. 8, the dopant flux is maximum at the instant when the back of the base layer 206A is grown. In a typical structure, the back of the base is grown first, and then the dopant flux is changed in a manner so that it exponentially decreases as the remainder of the base is grown. Note that during epitaxy, layer 206A is typically grown first followed by layers 206B and 208 in FIG. 2. The dopant flux is the least at the interface between sub-region 1 and sub-region 2 (i.e. the interface between 206A and 206B). Thereafter either the dopant flux is turned off or kept constant. The doping profile is varied in this manner in order to gain additional current due to a larger depletion width created by the undoped or uniformly doped region. The remainder of the base has positional (depth) dependent doping so as to introduce a drift field to further improve current collection. Furthermore, the extension of the depletion width by introduction of region of constant doping or no doping as opposed to the case with graded doping in the entire base ensures a higher probability of current collection for carriers generated outside of the depletion region of the solar cell. A substantial improvement in current collection is achieved in these embodiments. In some embodiments, the layer with this doping profile may comprise GaAs, InGaP, AlInGaP, AlGaAs or InGaAs.

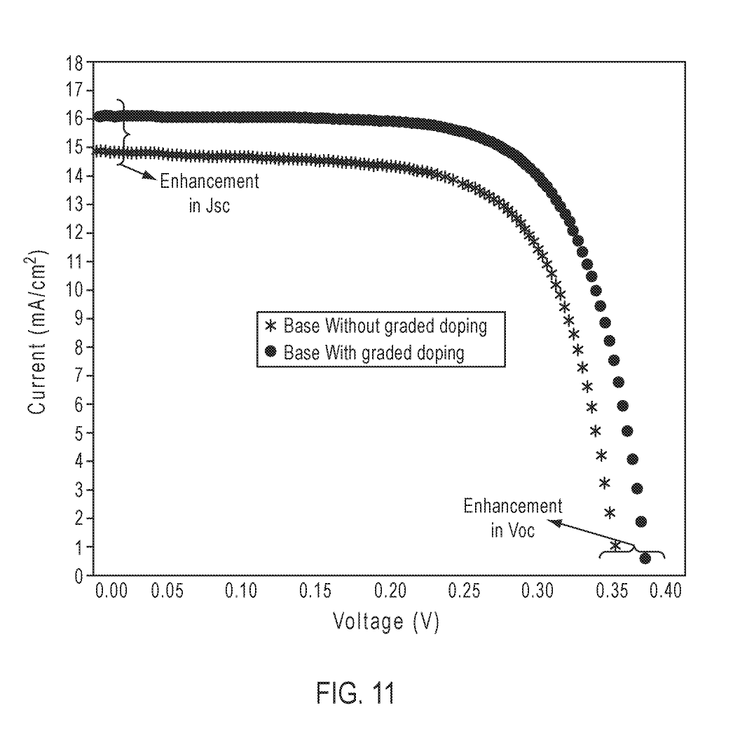

FIG. 10 is a graph that compares the internal quantum efficiency of a dilute nitride sub-cell with and without use of a position dependent doping profile. Internal quantum efficiency is the ratio of the number of carriers collected by the solar cell to the number of photons of a given wavelength that enter the solar cell (i.e., photons that are reflected from the surface are excluded). If all photons of a certain wavelength are absorbed and the resulting carriers are collected, then the internal quantum efficiency at that particular wavelength is unity. The quantum efficiency measurements showed an approximately 8.5% increase in current under an AM1 5D spectrum as a result of the doping, which would translate to an increase of approximately 8.5% in the overall efficiency of the multi junction solar cell if the dilute nitride sub-cell were the current limiting cell. With the use of the invention, there is a substantial improvement in the current collection and thus an improvement in the overall efficiency of the solar cell. In this particular demonstration, the short circuit current improves by 8.5% under an AM1 5D spectrum. Similar improvement can also be seen in FIG. 11, which shows the I-V characteristics of dilute nitride sub-cells. The open circuit voltage, short circuit current and the fill factor show substantial improvement in a sub-cell with a graded doping profile when compared to sub-cell without such a doping profile. The substantial improvement in the current and the voltage of the dilute nitride sub-cell translates directly into an improvement in the efficiency of the multi junction solar cell. This improvement is significantly higher than a dilute nitride sub-cell without graded doping in the base and/or emitter of the dilute nitride sub-cell.

In the embodiment of the invention discussed above, the variations in doping profile are achieved during epitaxial growth of the semiconductor layers. In addition to the creation of the preferred doping profile during epitaxial growth, the profile may also be manipulated by post growth steps on the semiconductor epilayer. Such post-growth steps include but are not limited to annealing the semiconductor material in an atmosphere comprising one or more of the following: As, P, H₂, N₂, forming gas, and/or O₂. Such a process step has multiple variables that must be optimized to achieve a desired doping profile. This includes but is not limited to changing the anneal time, anneal temperature, anneal cycle in addition to anneal environment mentioned above. For example, the anneal temperature may be between 400° C. and 1,000° C., while the duration of the annealing process may lie between 10 sec and 1000 sec, and the ambient condition can be a constant pressure atmosphere of primarily phosphorus, arsenic, hydrogen, oxygen and/or nitrogen. The final objective, irrespective of the process step used to achieve it, is a desirable doping profile for a certain composition of the dilute nitride material.

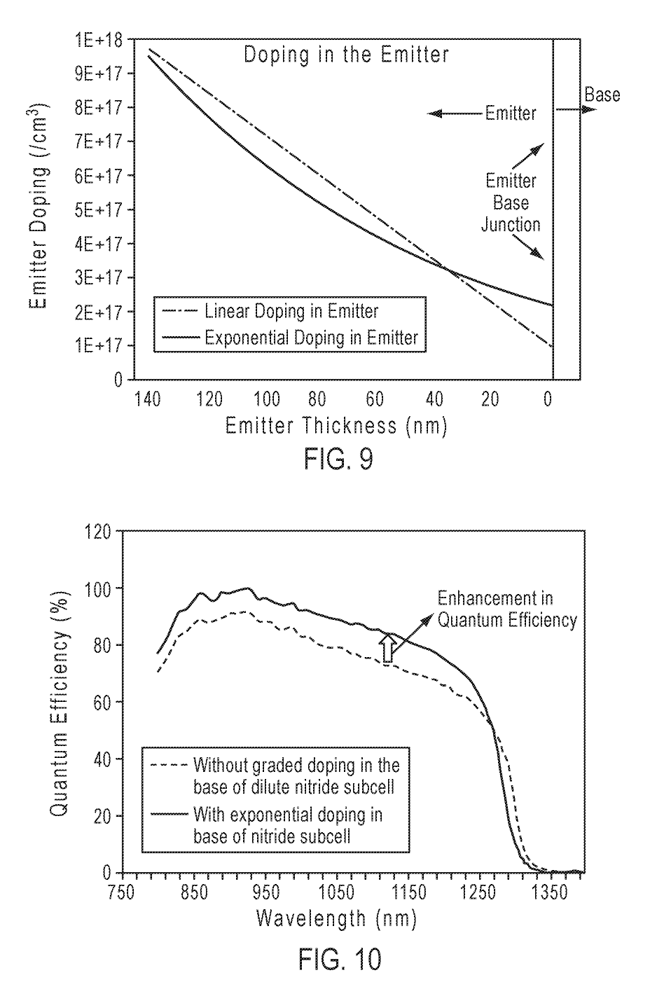

In still another embodiment of this invention, graded doping is introduced in the emitter of the dilute nitride solar cell. In this embodiment, the base may or may not have a graded doping profile according to the embodiments described above. The doping concentration of the emitter (layer 2 in FIG. 4) lies substantially between 1×10¹⁵/cm³ to 1×10¹⁹/cm³. The doping profile increases from the emitter-base junction (interface (2-3) in FIG. 4) towards the front surface field of the solar cell (interface (1-2) in FIG. 4). FIG. 9 outlines the doping in the emitter of the dilute nitride sub-cell. Two exemplary cases are given. In the first case, the doping changes linearly as a function of the position in the emitter. In the second case, such a variation in doping follows an exponential increase away from the emitter-base junction. For both the cases, the doping is the least at the emitter-base junction. The advantages of position dependent doping in the emitter are similar to those achieved from such doping in the base of the solar cell. In particular, the collection of minority carriers is improved, increasing the photocurrent. An exponential doping profile introduces a constant electric field in the emitter of the solar cell, but linear and other doping profiles may also be used to create other fields of differing geometries. Variation in the doping profile is possible so as to change the electric field as a function of the position to improve current collection.

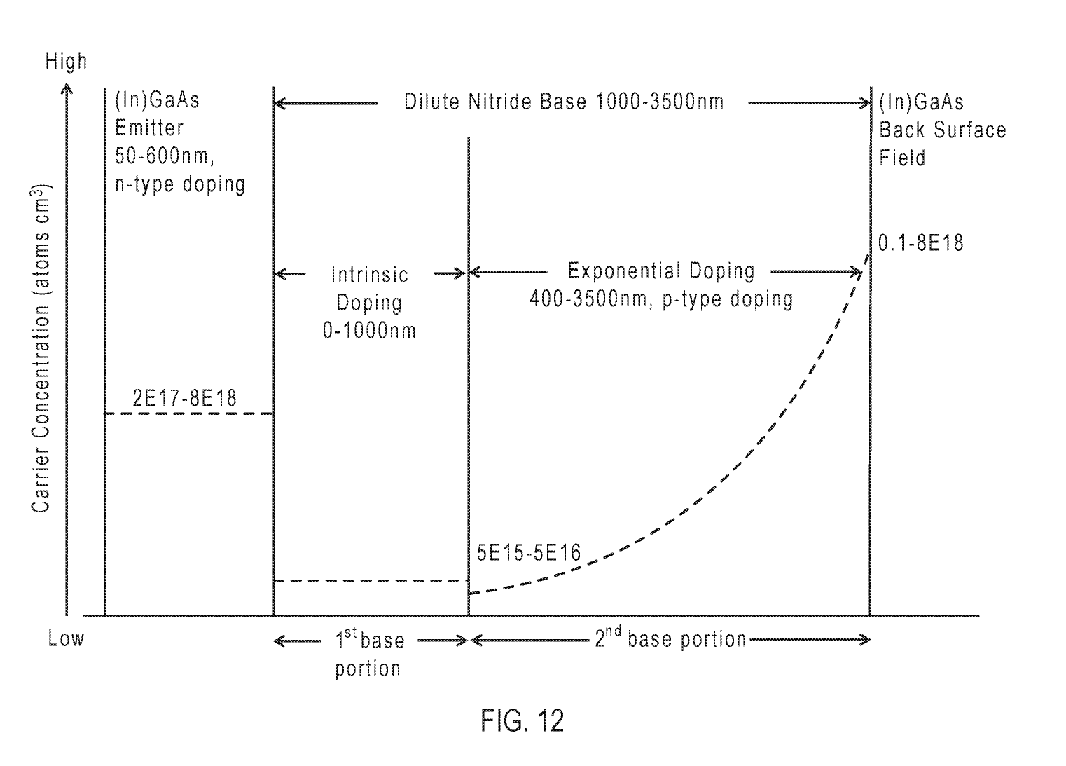

FIGS. 2 and 12 illustrate an embodiment characterized by exponential doping of the dilute nitride base with Be, C, or Zn results in a p-type dilute nitride base. Other p-type dopants can be employed. The (In)GaAs back surface field 204 and GaAs or Ge substrate 202 are p-type as well. The dilute nitride base 206 comprises two portions—a first base portion 206B that extends from the emitter to the second base portion 206A, and a second base portion that extends from the first base portion 206B to the (In)GaAs back surface field 204. The first base portion 206B is no thicker than 1,000 nm and has intrinsic doping. For example, the first base portion 206B can have a thickness from 10 nm to 1,000 nm, from 10 nm to 500, from 100 nm to 500 nm, or other thicknesses. The second base portion 206A is no thinner than 400 nm and has an exponential or a linear doping profile. For example, the second base portion 206A can have a thickness from 400 nm to 3,500 nm, from 400 nm to 2,500 nm, from 400 nm to 1,500 nm, or other thicknesses. The total thickness of the dilute nitride base 206 does not exceed 3,500 nm. For example, the total thickness of the base portion 206 can be from 1,000 nm to 3,500 nm, from 1,000 nm to 2,500 nm, from 1,000 nm to 1,500 nm, or other thickness. The first base portion 206B can have intrinsic doping, and practitioners skilled in the art will understand that a basal level of non-specific doping exists during semiconductor growth, also sometimes referred to as background doping or unintentional doping. For example, intrinsic doping can refer to dopant concentrations within the range from 5E15 atoms/cm³ to 5E16 atoms/cm³. In intrinsic doping, a dopant is not intentionally added to the growth materials and rather is present as an impurity in the semiconductor precursors used to form the semiconductor alloy. For intrinsic doping, a dopant is not intentionally added during semiconductor growth and the intrinsic dopant concentration refers to impurity levels in the semiconductor. These intrinsic doping elements may be present in this first base portion at various low concentrations. The concentration of intrinsic dopants can be constant throughout the first base portion to form a linear or constant intrinsic doping profile. A constant doping profile refers to a doping profile that is approximately constant across the semiconductor layer. For example, a constant doping profile can vary by less than 10% of a nominal value across the semiconductor layer. The second base portion can be doped with Be, C, Zn, or any combination of any of the foregoing, making it p-type. Other p-type dopants may also be employed. The second base portion can have an exponential or linear doping profile, where the dopant concentration is low at the first base portion-second base portion interface and high at the second base portion-(In)GaAs back surface field interface. In certain embodiments, the dopant concentration increases exponentially between these two interfaces from 5E15 atoms/cm³ to 8E18 atoms/cm³. In certain embodiments, the dopant concentration at the first base portion-second base portion interface can be within a range from 5E15 atoms/cm³ to 5E16 atoms/cm³. In certain embodiments, the dopant concentration at the second base portion-(In)GaAs back surface field interface can be within a range from 0.1E18 atoms/cm³ to 8E18 atoms/cm³. The (In)GaAs emitter 208 can be n-type with a thickness within a range from 50 nm to 600 nm. The (In)GaAs emitter can also be doped with an n-type dopant such as Si, Te or Se at a concentration within a range from 2E17 atoms/cm³ to 8E18 atoms/cm³.

Referring to FIGS. 2 and 12 a dilute nitride subcell can comprise an n-type (In)GaAs emitter 208 having a thickness within the range from 50 nm to 600 nm, a first base portion 206B having a thickness within the range from 0 nm to 1,000 nm and characterized by intrinsic doping (or constant doping), a p-doped second base portion 206A having a thickness within the range from 400 nm to 3,500 nm, and a p-type (In)GaAs back surface field 204. The dilute nitride subcell can overly a p-type Ge or p-type GaAs substrate 202. The (In)GaAs emitter 208 can have a constant n-type dopant concentration, for example, within a range, for example, from 2E17 atoms/cm³ to 8E18 atoms/cm³, from 4E17 atoms/cm³ to 6E18 atoms/cm³, from 6E17 atoms/cm³ to 4E18 atoms/cm³, from 8E17 atoms/cm³ to 2E18 atoms/cm³, from 2E17 atoms/cm³to 1E18 atoms/cm³, or within a range from 1E18 atoms/cm³to 8E18 atoms/cm³. The base portion 206 may or may not include a first base portion 206A. Embodiments in which the first base portion has a thickness of 0 nm means that the first base portion 206B is absent. The first base portion 206B can have an intrinsic level of dopant such as, for example, within a range of 5E15 atoms/cm³ to 5E16 atoms/cm³. The second base portion 206A can have an exponential doping profile that increases from the interface with first base portion 206B (or if the first base portion is absent, from the interface with the emitter 208) to the back surface field 204. The concentration of the p-type dopant at the interface with the first base portion 206B (or the emitter 208) can be an intrinsic or unintentional background doping concentration such as, for example, within the range from 5E15 atoms/cm³ to 5E16 atoms/cm³, from 5E15 atoms/cm³ to 1E16 atoms/cm³, from 1E16 atoms/cm³ to 5E16 atoms/cm³, or within the range from 8E15 atoms/cm³ to 2E16 atoms/cm³. At the interface with the back surface field, the p-type dopant concentration can be within the range, for example, of 1E17 atoms/cm³ to 8E18 atoms/cm³, from 3E17 atoms/cm³to 6E18 atoms/cm³ from 5E17 atoms/cm³to 4E18 atoms/cm³, from 7E17 atoms/cm³to 2E18 atoms/cm³, from 1E17 atoms/cm³ to 1E18 atoms/cm³, or within the range from 1E18 atoms/cm³ to 8E18 atoms/cm³. The back surface field 204 can be p-type doped at a concentration within a range, for example, from 0.1E18 atoms/cm³ to 8E18 atoms/cm³. In certain embodiments, the concentration of the p-type dopant in the second base portion 206A can exponentially increase by one order of magnitude from 1E16 atoms/cm³ to 1E17 atoms/cm³, or from 5E16 atoms/cm³ to 5E17 atoms/cm³. In certain embodiments, the concentration of the p-type dopant in the second base portion 206A can increase, for example, from 5E15 atoms/cm³ to 1E17 atoms/cm³, from 5E15 atoms/cm³ to 5E17 atoms/cm³, from 5E15 atoms/cm³ to 1E18 atoms/cm³, or from 5E15 atoms/cm³ to 5E18 atoms/cm³; from 1E16 atoms/cm³ to 1E17 atoms/cm³, from 1E16 atoms/cm³ to 5E17 atoms/cm³, from 1E16 atoms/cm³ to 1E18 atoms/cm³, or from 1E16 atoms/cm³ to 5E18 atoms/cm³; from 5E16 atoms/cm³ to 1E17 atoms/cm³, from 5E16 atoms/cm³ to 5E17 atoms/cm³, from 5E16 atoms/cm3 to 1E18 atoms/cm³, or from 5E16 atoms/cm³ to 5E18 atoms/cm³.

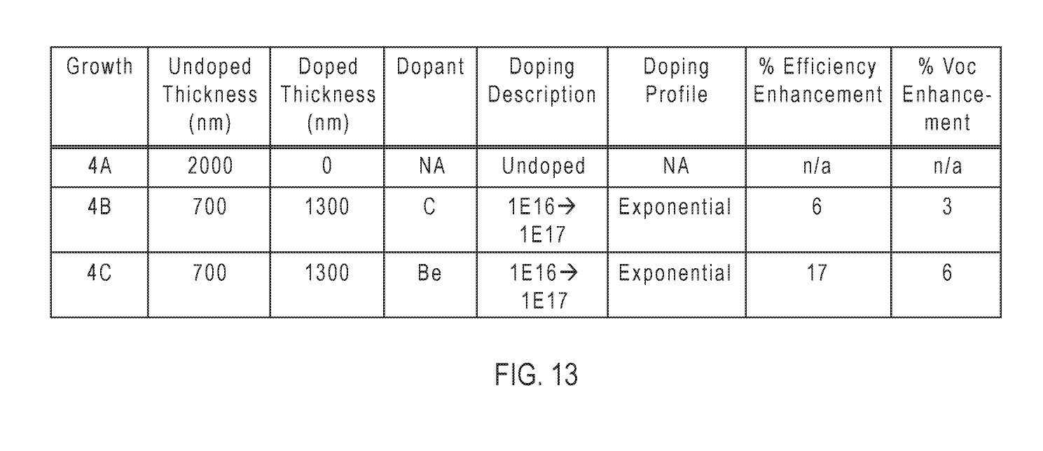

In some embodiments, a dilute nitride subcell with an exponential doping profile in the second base portion 206A exhibits improved performance characteristics. FIG. 13 describes examples of these embodiments, where the dilute nitride subcells are either C or Be doped, and the undoped/intrinsic thickness, doped thickness and dopant concentration are equivalent, at 700 nm, 1,300 nm, and within the range from 1E16 atoms/cm³ to 1E17 atoms/cm³, respectively. These embodiments, identified as dilute nitride subcells 4B and 4C, were analyzed for subcell structure (i.e. doping profiles), efficiency, Voc (open circuit voltage) and Jsc (short circuit current density). The properties of these dilute nitride subcells were compared to those of an undoped dilute nitride subcell, 4A. Secondary Ion Mass Spectrometry (SIMS) was used to obtain information on varying elemental composition with respect to depth measured from the top surface of the subcell. SIMS involves the removal of atoms from the surface and is by nature a destructive technique. SIMS is suited for depth profiling applications and the method is applied to the top of the subcell at the start of the analysis, removing semiconductor material as the incident ion beam etches into the subcell. A subcell depth profile is thus obtained simply by recording sequential SIMS spectra as the surface is gradually removed. A plot of the intensity of a given mass signal as a function of depth is a direct reflection of the elemental abundance/concentration with respect to its vertical position below the top surface.

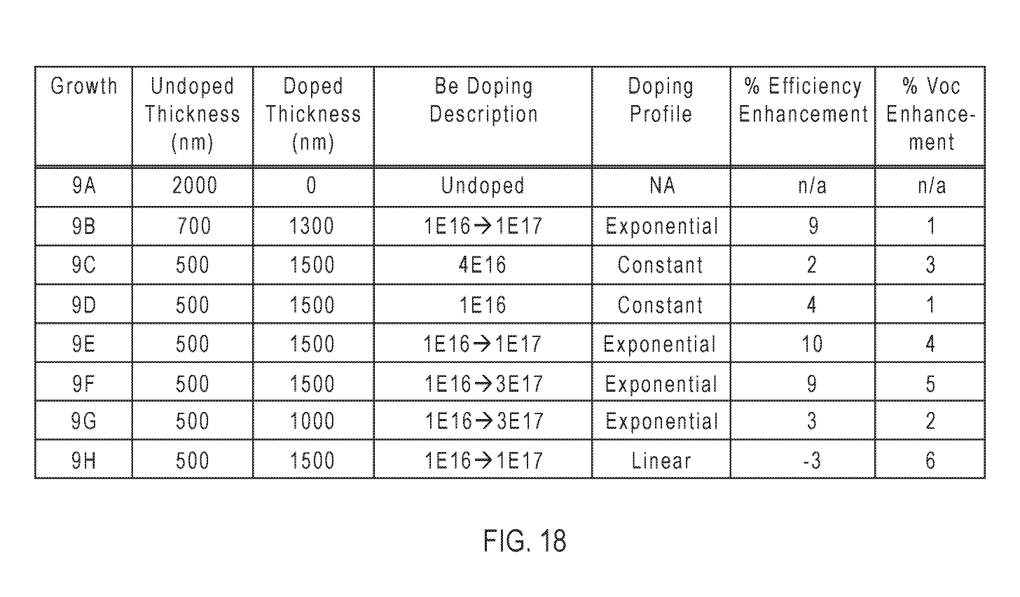

For the GaInNAsSb subcells presented in FIG. 13 and FIG. 18, the emitter had a thickness of 200 nm and was doped with Si at a constant concentration of 2E18 atoms/cm³; the dilute nitride band gap was within the range from 0.95 eV to 0.98 eV; the Ga₁₋ₓInₓN_{y}As_{1-y-z}Sb_{z} composition was 0.11≤x≤0.15, 0.025≤y≤0.04, and 0.003≤z≤0.015 and measurements were made using a 1 sun AM 1.5D spectrum at a junction temperature of 25° C. The doping profile of the Ga₁₋ₓInₓN_{y}As_{1-y-z}Sb_{z} base is presented in FIG. 4 and FIG. 18.

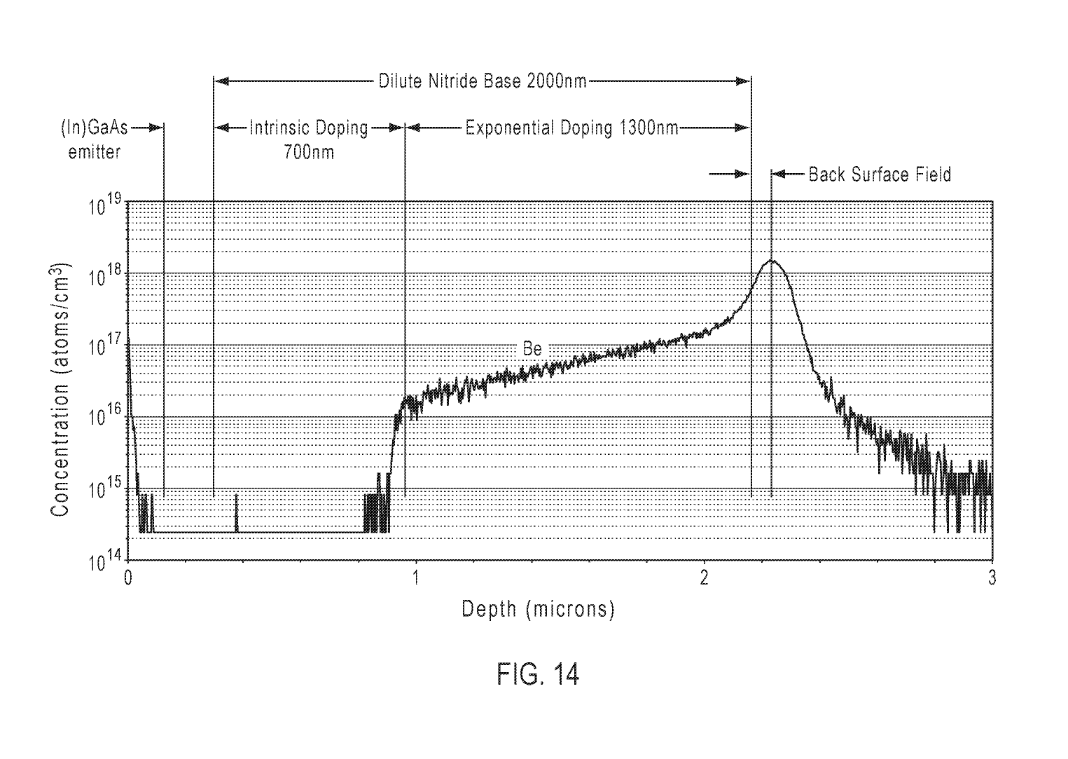

FIG. 14 presents the doping profile of subcell 4C (FIG. 13) measured by SIMS, confirming Be exponential doping in the second base region 206A (FIG. 2). The SIMS analysis shows that the second base region 206A is 1,300 nm deep and the Be concentration increases from about 1E16 atoms/cm³ at the interface between first base portion 206B and second base portion 206A to about 1E17 atoms/cm³ at the interface between second base portion 206A and the (In)GaAs back surface field 204.

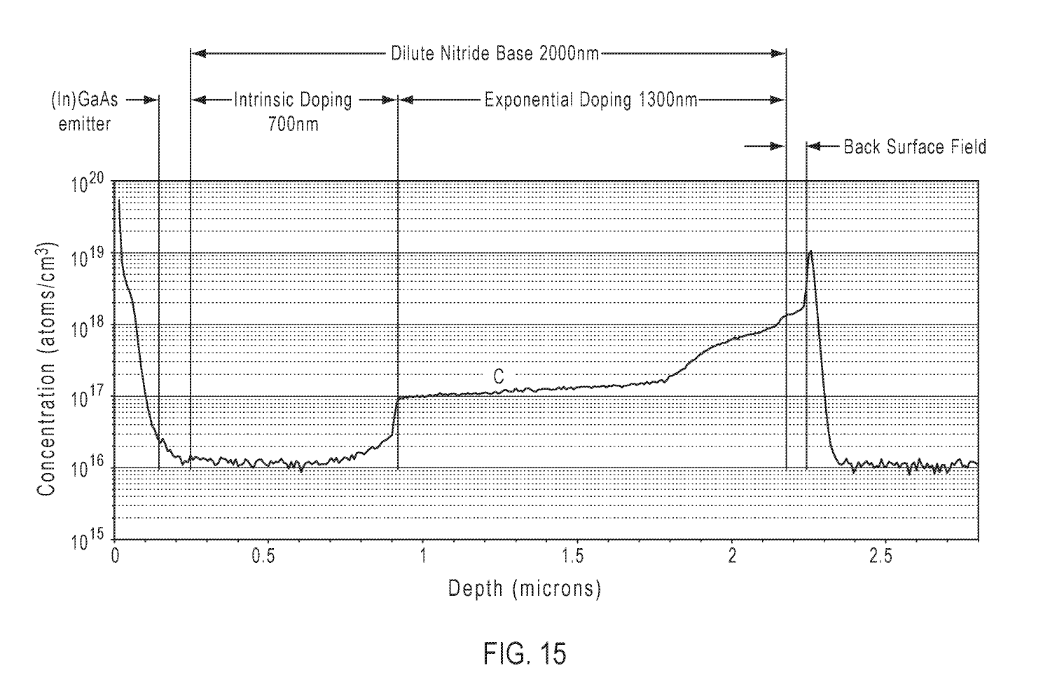

FIG. 15 presents the doping profile of subcell 4B (FIG. 13) measured by SIMS, confirming C exponential doping in the second base region 206A (FIG. 2). The data shows that the second base region 206A is 1,300 nm deep and the C concentration increases from 1E16 atoms/cm³ at the interface between 206A and 206B to 1E17 atoms/cm³ at the interface between 206A and 204.

As shown in FIG. 14, a drop in Be concentration was detected, albeit, in subcell regions deeper than the (In)GaAs back surface field 204. This was also observed for C concentration as shown in FIG. 15. A skilled practitioner in the art understands that a shoulder/rollover is routinely observed on the trailing edge of atomic concentration. A buildup of Be/C atoms is caused by an abundance of Be/C being etched away by the incident beam in previous layers. The appearance of high Be/C concentrations in the (In)GaAs back surface field 204 are artifacts of the SIMS method. Once the elemental buildup is removed, Be/C concentrations drop to expected levels. One skilled in the art can appreciate that Be/C concentrations are low in the (In)GaAs back surface field 204, despite the actual spectra, due to this artifact. FIGS. 14 and 15 show that subcells 4B and 4C (FIG. 13) were subcells grown to desired specifications, including desired doping profiles.

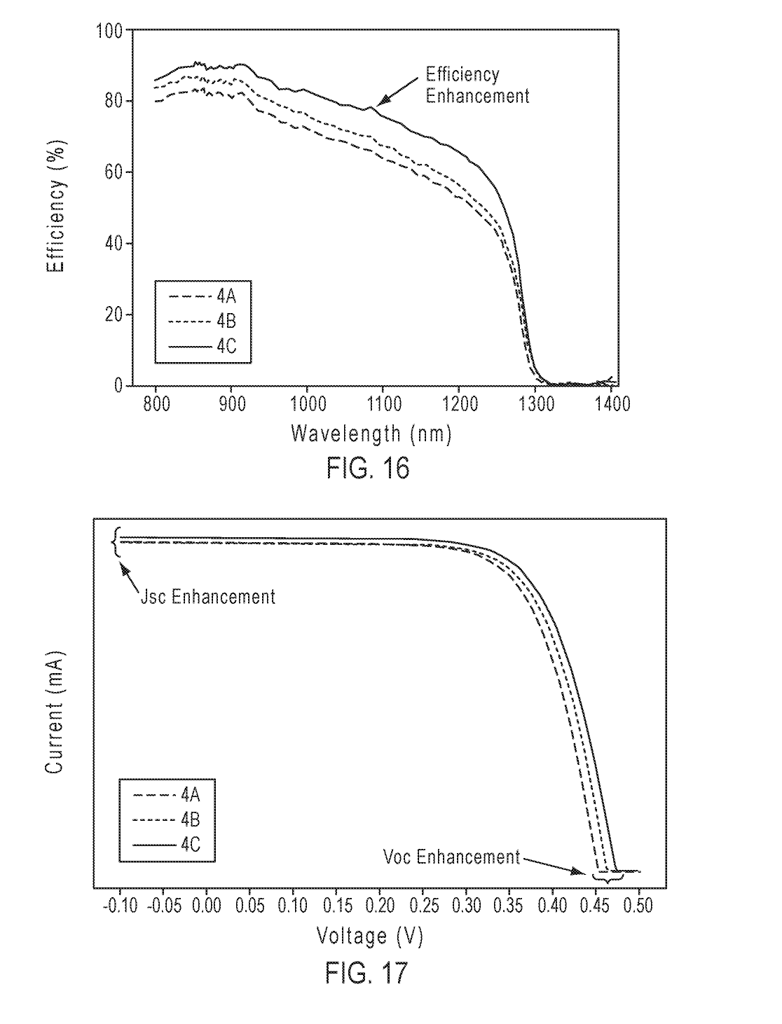

FIG. 16 compares the efficiency of dilute nitride subcells with and without Be/C exponential doping in the dilute nitride base, as described in FIGS. 13-15. Efficiency results in this disclosure refers to the efficiency with which protons that are not reflected or transmitted out of the subcell can generate collectible carriers. Efficiency is the ratio of the number of carriers collected by the photovoltaic cell to the number of photons of a given wavelength that enter the photovoltaic cell (i.e., photons that are at that particular wavelength is unity).

FIG. 17 compares the IV characteristics of these same dilute nitride subcells with and without Be/C exponential doping in the dilute nitride base. The subcells tested were described in FIGS. 4 and 7-8, with the doping profiles indicated in FIGS. 13-15. In one embodiment, subcell 4B, C doping resulted in a 6% enhancement in efficiency and a 5% enhancement in Voc under an AM1.5D spectrum at a junction temperature of 25° C. (FIGS. 4 and 7-8). This translates to an approximate increase of 11% in the efficiency of the dilute nitride subcell. In another embodiment, subcell 4C, Be doping resulted in a 17% efficiency enhancement and 6% Voc enhancement under an AM1.5D spectrum at a junction temperature of 25° C. (FIGS. 13 and 16-17). This translates to an approximate increase of 24% in the efficiency of the dilute nitride subcell. These results demonstrate a substantial improvement in the current collection and thus an improvement in the overall efficiency of the photovoltaic cell, with the Be-doped subcell outperforming the C-doped subcell.

With Be as the dopant, several doping profiles were analyzed for improvement in dilute nitride subcell performance. FIG. 18 describes these embodiments, where the dilute nitride subcells have different undoped/intrinsic thicknesses, doped thicknesses, dopant concentrations, and doping profiles. The performance of these subcells, as described in FIG. 18, were compared to those of an undoped dilute nitride subcell, 9A. In one embodiment, subcell 9B, the undoped/intrinsic thickness was 700 nm, the doped thickness was 1,300 nm, and Be was exponentially doped into the dilute nitride subcell at a concentration within the range from 1E16 atoms/cm³ to 1E17 atoms/cm³. Subcell 9B displayed a 9% enhancement in efficiency and a 1% enhancement in Voc; which represents an approximately 10% enhancement in subcell efficiency. For subcells 9C and 9D, the undoped/intrinsic thickness was 500 nm, the doped thickness was 1,500 nm, and Be was constantly doped into the dilute nitride subcell at either 4E16 atoms/cm³ or 1E16 atoms/cm³, respectively. Dilute nitride subcell 9C displayed a 2% enhancement in efficiency and a 3% enhancement in Voc, which represents an approximately 5% enhancement in subcell efficiency. Subcell 9D displayed a 4% enhancement in efficiency and a 1% enhancement in Voc, which represents an approximately 5% enhancement in subcell efficiency. For subcells 9E and 9F, the undoped/intrinsic thickness was 500 nm, the doped thickness was 1,500 nm, and Be was exponentially doped into the dilute nitride subcell from 1E16 atoms/cm³ to 1E17 atoms/cm³, or from 1E16 atoms/cm³ or 3E17 atoms/cm³, respectively. Subcell 9E displayed a 10% enhancement in efficiency and a 4% enhancement in Voc, which represents an approximately 14% enhancement in subcell efficiency. Subcell 9F displayed a 9% enhancement in efficiency and a 5% enhancement in Voc, which represents an approximately 14% enhancement in subcell efficiency. For subcell 9G, the undoped/intrinsic thickness was 500 nm, the doped thickness was 1,500 nm, and Be was exponentially doped into the dilute nitride subcell at a concentration within the range from 1E16 atoms/cm³ to 3E17 atoms/cm³. Subcell 9G displayed a 3% enhancement in efficiency and a 2% enhancement in Voc, which represents an approximately 5% enhancement in subcell efficiency. For subcell 9H, the undoped/intrinsic thickness was 500 nm, the doped thickness was 1,500 nm, and Be was linearly doped into the dilute nitride subcell at a concentration from 1E16 to 1E17 atoms/cm³. Subcell 9H displayed a 3% decrease in efficiency and a 6% enhancement in Voc, which represents an approximately 9% enhancement in subcell efficiency. The decrease in efficiency for subcell 9H demonstrates that doping of dilute nitride subcells does not necessarily result in enhanced performance. The mere presence of a dopant or a particular doping profile did not always improve the performance of a dilute nitride subcell. Experimentation with various doping parameters demonstrated that the correlation with subcell performance were complex and unpredictable and simultaneously maximizing the performance attributes requires considerable experimentation.

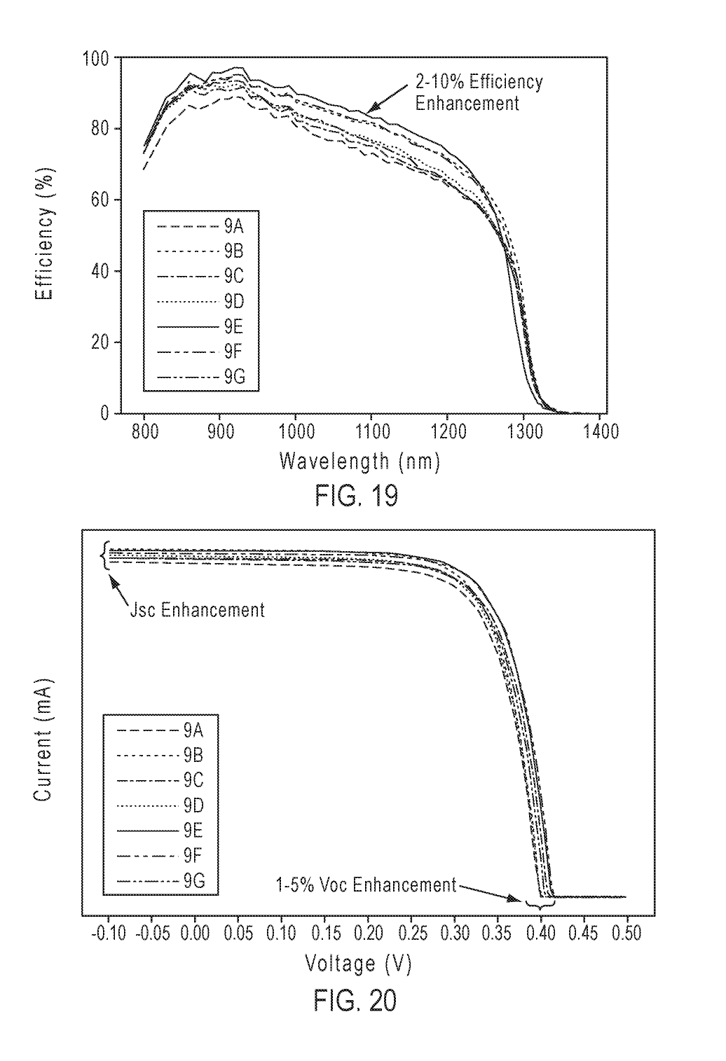

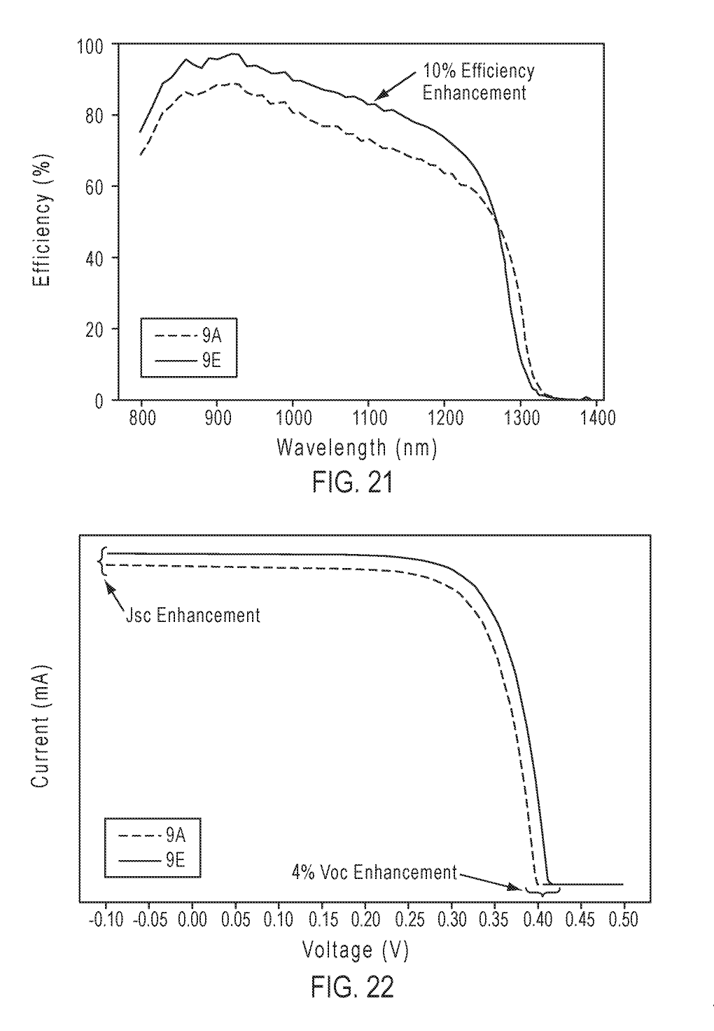

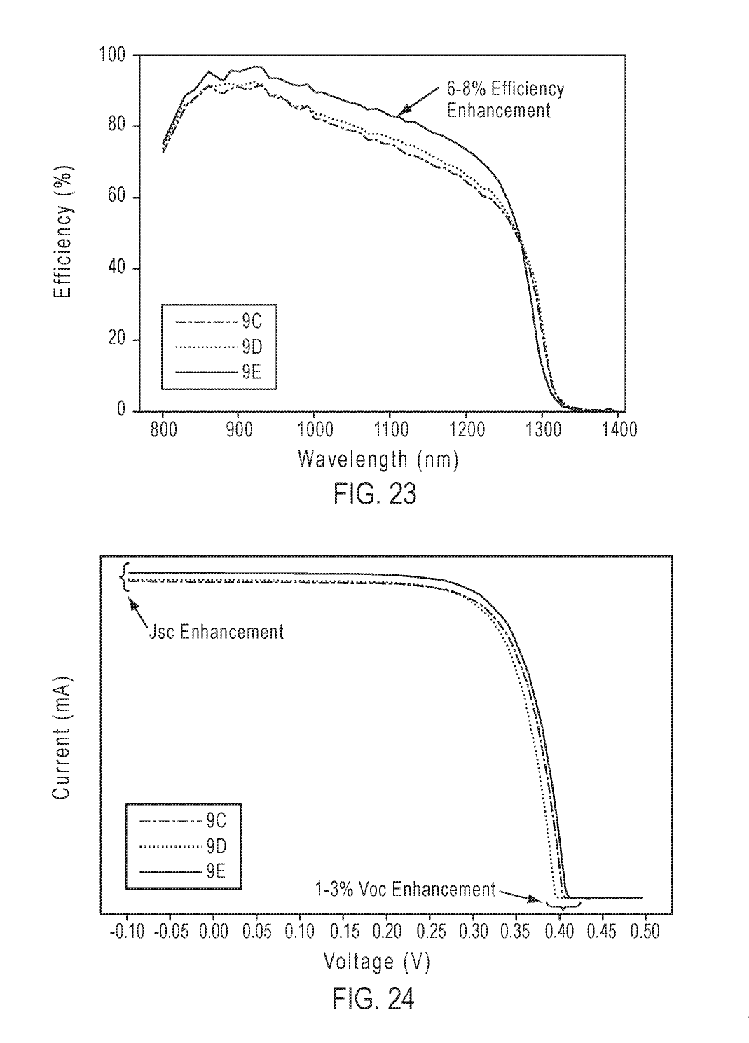

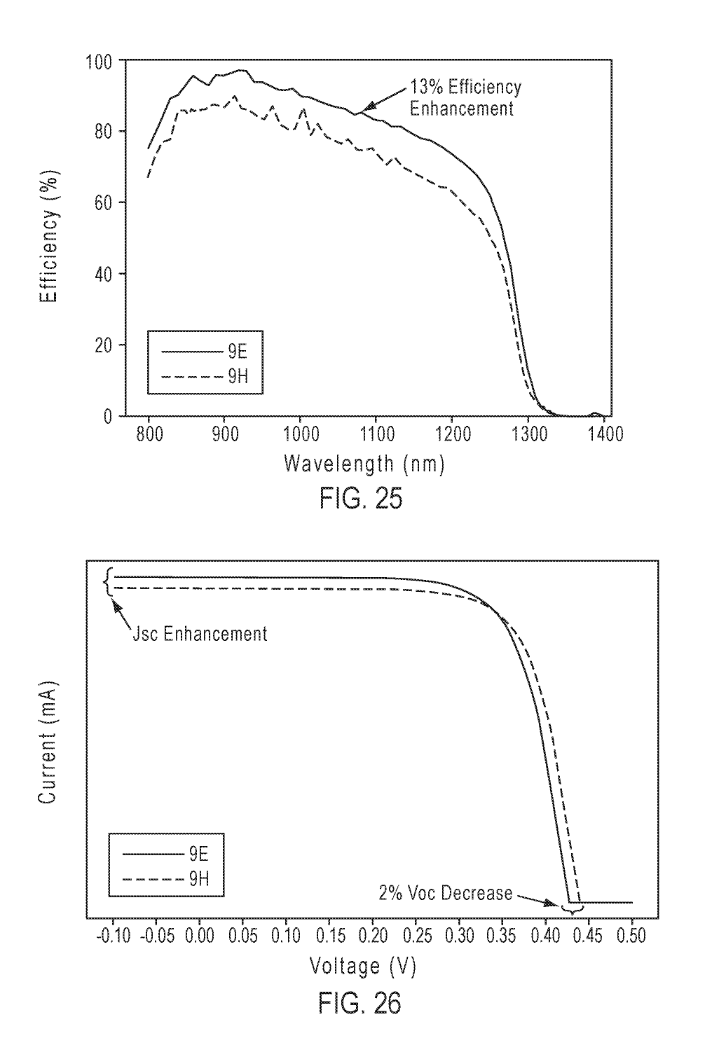

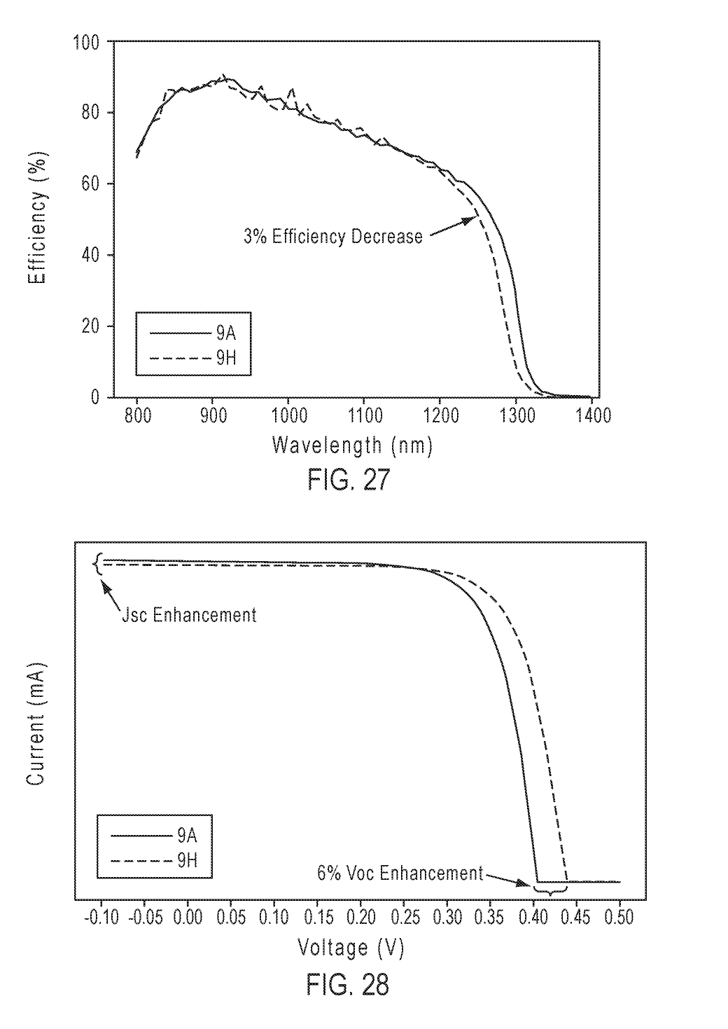

When considered together, the results presented in FIG. 18 show that subcell 9E, a subcell with exponential doping of Be from 1E16 atoms/cm³ to 1E17 atoms/cm³, exhibits the most improvement in efficiency. The performance characteristics of subcell 9E translate to an increase of approximately 14% in the overall efficiency of the dilute nitride subcell. The properties of the subcells presented in FIG. 19 are shown in FIGS. 19-28. FIGS. 19, 21, 23, 25, and 27 compare the efficiency curves of the dilute nitride subcells described in FIG. 18. FIGS. 20, 22, 24, 26, and 28 compare the IV curves of the dilute nitride subcells described in FIG. 18. FIG. 19 compares efficiency curves of undoped subcell 9A; constantly-doped subcells 9C and 9D; and exponentially-doped subcells 9B, 9E, 9F, and 9G. FIG. 20 shows the IV curves for these subcells. All subcells with either exponential or constant Be doping showed improved efficiency, Jsc, and Voc compared to that of undoped subcell 9A. FIGS. 21 and 22 show efficiency curves and IV curves for undoped subcell 9A and exponentially-doped subcell 9E. The results demonstrate that exponential doping improves efficiency, Jsc, and Voc compared to an absence of doping (or intrinsic doping alone). FIGS. 23 and 24 show efficiency curves and IV curves comparing constantly-doped subcells 9C and 9D to exponentially-doped subcells 9E. The results demonstrate that exponential doping improved efficiency, Jsc and Voc compared to constant doping. FIGS. 25 and 26 show efficiency curves and IV curves comparing exponentially-doped subcell 9E to linearly-doped subcell 9H. The results demonstrate that exponential doping improved the efficiency and Jsc but decreased the Voc compared to linear doping. FIGS. 27 and 28 show efficiency curves and IV curves comparing linearly-doped subcell 9H and undoped subcell 9A; linear doping improved subcell Voc but worsened efficiency and Jsc.

As shown in FIG. 3, a dilute nitride subcell can have an n-type Ge or GaAs substrate 302. An n-type (In)GaAs back surface field 304 overlies the substrate 302. A dilute nitride base layer 306 no thicker than 3,500 nm overlies the (In)GaAs back surface field. A 200 nm to 500 nm thick (In)GaAs emitter layer 308 forms the top layer of the dilute nitride subcell.

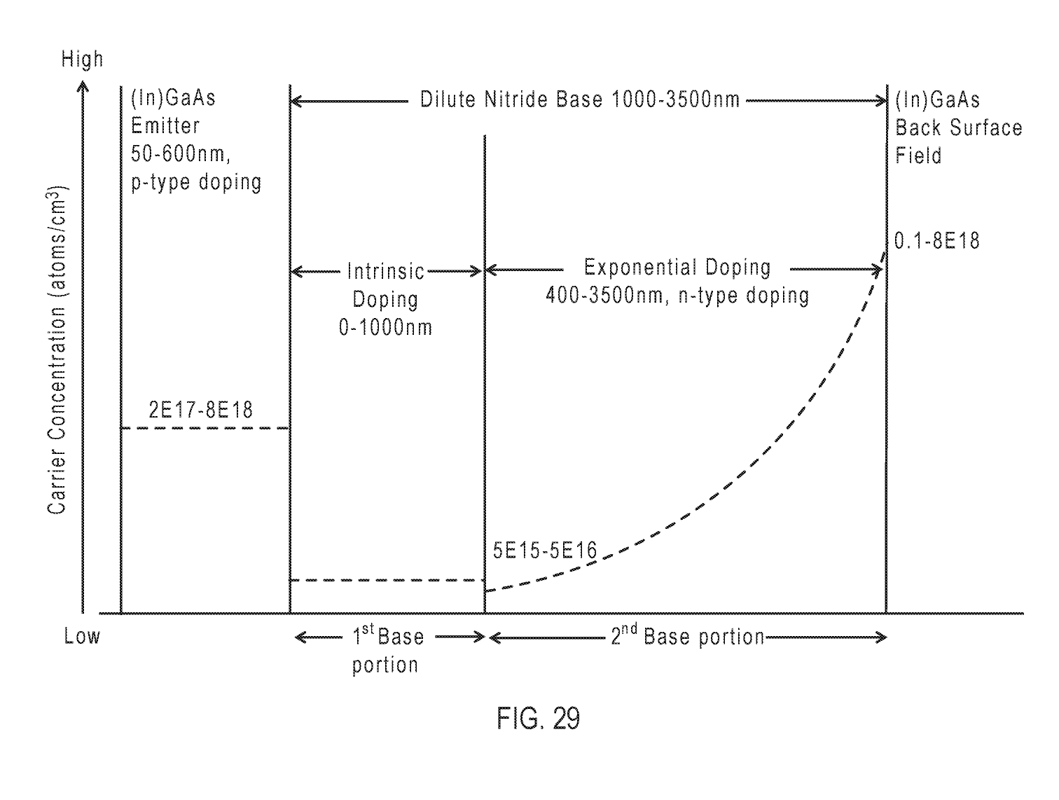

FIGS. 29-31 show embodiments having exponential doping of the dilute nitride base with Si or Te and resulting in an n-type dilute nitride base. As described above and summarized here, a dilute nitride subcell can be incorporated into a multijunction photovoltaic cell or can function as a single-junction photovoltaic cell or as a photodetector. Examples of dilute nitride alloys that can be used for the dilute nitride base include GaInNAsSb, GaInNAsBi, GaInNAsSbBi, GaNAsSb, GaNAsBi and GaNAsSbBi. The thickness of each layer can vary in order to maximize current and voltage outputs of the subcell. This is especially true for the optimal thickness of the dilute nitride base layer, where an optimal thickness is different for each type of dilute nitride alloy as thickness must change with varying elemental composition. A practitioner skilled in the art understands that other types of layers may be incorporated or omitted in a photovoltaic cell to create a functional device and are not described in detail.

FIG. 29 shows an embodiment in which the dilute nitride base 306 (FIG. 3) comprises two portions; a first base portion that extends from the emitter 208 to the second base portion, and a second base portion that extends from the first base portion to the (In)GaAs back surface field 304. The first base portion is no thicker than 1,000 nm and has intrinsic doping. For example, the first base portion can have a thickness from 10 nm to 1,000 nm, from 10 nm to 500, from 100 nm to 500 nm, or other thicknesses. The second base portion is no thicker than 3,500 nm and has a linear or an exponential doping profile. For example, the second base portion can have a thickness from 400 nm to 3,500 nm, from 400 nm to 2,500 nm, from 400 nm to 1,500 nm, or other thicknesses. The total thickness of the dilute nitride base 306 including the first portion (if present) and the second portion does not exceed 3,500 nm. The first base portion has intrinsic doping, and practitioners skilled in the art will understand that a basal level of non-specific doping exists during semiconductor growth. These intrinsic doping elements may be present in this first base portion at a concentration within the range from 5E15 atoms/cm³ to 5E16 atoms/cm³. The concentration of intrinsic dopants holds constant throughout the first base portion to form a linear (uniform) intrinsic doping profile. The second base portion can be doped with Si, Te, Se, or any combination thereof, making it n-type. Other n-type dopants may be employed. The second base portion can have an exponential doping profile, where the dopant concentration is low at the first base portion-second base portion interface and high at the second base portion-(In)GaAs back surface field interface. In certain embodiments, the dopant concentration increases exponentially between these two interfaces from 5E15 atoms/cm³ to 8E18 atoms/cm³. In certain embodiments, the dopant concentration at the first base portion-second base portion interface can be within the range from 5E15 atoms/cm³ to 5E16 atoms/cm³. In certain embodiments, the dopant concentration at the second base portion-(In)GaAs back surface field interface can be within the range from 0.1E18 atoms/cm³ to 8E18 atoms/cm³. The (In)GaAs emitter is p-type with a thickness within the range from 50 nm to 600 nm. The (In)GaAs emitter can also be doped with Be, C, Zn, or any combination thereof, at a concentration within the range from 2E17 atoms/cm³ to 8E18 atoms/cm³. The substrate can be n-type Ge or n-type GaAs.

Referring to FIGS. 3 and 29, a dilute nitride subcell can include a p-type (In)GaAs emitter 308 having a thickness within the range from 50 nm to 600 nm, an n-type doped dilute nitride base 306 having a thickness from 1,000 nm to 3,500 nm, which can comprise an intrinsically doped first base portion with a thickness from 0 nm to 1,000 nm, and an n-type doped second base portion having a doping concentration that exponentially increases from a concentration within the range from 5E15 atoms/cm³ to 5E16 atoms/cm³ at the interface with the first base portion (or with the emitter) to a concentration within the range from 1E17 atoms/cm³ to 8E17 atoms/cm³ at the interface with the back surface field 304.

The dilute nitride subcell can overly an n-type Ge or n-type GaAs substrate 302. The (In)GaAs emitter 308 can have a constant p-type dopant concentration, for example, within a range from 2E17 atoms/cm³ to 8E18 atoms/cm³, from 4E17 atoms/cm³ to 6E18 atoms/cm³, from 6E17 atoms/cm³ to 4E18 atoms/cm³, from 8E17 atoms/cm³ to 2E18 atoms/cm³, from 2E17 atoms/cm³ to 1E18 atoms/cm³, or within a range from 1E18 atoms/cm³ to 8E18 atoms/cm³. The base portion 306 may or may not include a first base portion. Embodiments in which the first base portion has a thickness of 0 nm means that the first base portion is absent. The first base portion can have an intrinsic level of dopant such as, for example, within a range of 5E15 atoms/cm³ to 5E16 atoms/cm³. The second base portion can have an exponential doping profile that increases from the first base portion (or if the first base portion is absent, from the emitter) to the back surface field 304. The concentration of the n-type dopant at the interface with the first base portion, or the emitter, can be an intrinsic doping concentration such as, for example, within the range from 5E15 atoms/cm³ to 5E16 atoms/cm³, from 5E15 atoms/cm³ to 1E16 atoms/cm³, from 1E16 atoms/cm³ to 5E16 atoms/cm³, or within the range from 8E15 atoms/cm³ to 2E16 atoms/cm³. At the interface with the back surface field, the p-type dopant concentration can be within the range, for example, of 1E17 atoms/cm³ to 8E18 atoms/cm³, from 3E17 atoms/cm³ to 6E18 atoms/cm³ from 5E17 atoms/cm³to 4E18 atoms/cm³, from 7E17 atoms/cm³to 2E18 atoms/cm³, from 1E17 atoms/cm³to 1E18 atoms/cm³, or within the range from 1E18 atoms/cm³ to 8E18 atoms/cm³. The back surface field can be p-type doped at a concentration within a range from 0.1E18 atoms/cm³ to 8E18 atoms/cm³. In certain embodiments, the concentration of the n-type dopant in the second base portion can exponentially increase by one order of magnitude, for example, from 1E16 atoms/cm³ to 1E17 atoms/cm³, or from 5E16 atoms/cm³ to 5E17 atoms/cm³. In certain embodiments, the concentration of the p-type dopant in the second base portion can increase, for example, from 5E15 atoms/cm³ to 1E17 atoms/cm³, from 5E15 atoms/cm³ to 5E17 atoms/cm³, from 5E15 atoms/cm³ to 1E18 atoms/cm³, or from 5E15 atoms/cm³ to 5E18 atoms/cm³; from 1E16 atoms/cm³ to 1E17 atoms/cm³, from 1E16 atoms/cm³ to 5E17 atoms/cm³, from 1E16 atoms/cm³ to 1E18 atoms/cm³, or from 1E16 atoms/cm³ to 5E18 atoms/cm³; from 5E16 atoms/cm³ to 1E17 atoms/cm³, from 5E16 atoms/cm³ to 5E17 atoms/cm³, from 5E16 atoms/cm³to 1E18 atoms/cm³, or can increase from 5E16 atoms/cm³ to 5E18 atoms/cm³.

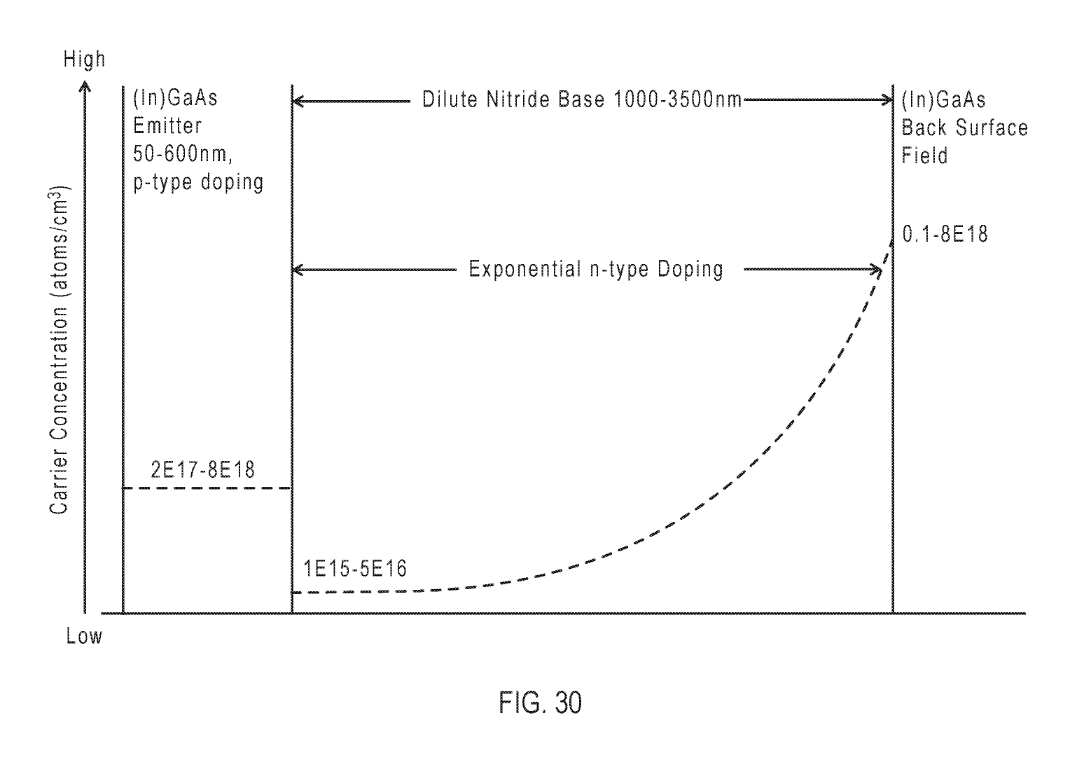

FIG. 30 shows an embodiment in which the dilute nitride base is no more than 3,500 nm thick. The dilute nitride base 306 extends from the (In)GaAs emitter 308 to the (In)GaAs back surface field 304 and is doped with Si, Te, Se or any combination thereof, if n-type. The dopant concentration of the dilute nitride base 306 is low at the (In)GaAs emitter-dilute nitride base interface (between layers 308-306) and high at the dilute nitride base-(In)GaAs back surface field interface (between layers 306 and 304). In certain embodiments, the dopant concentration at the (In)GaAs emitter-dilute nitride base interface can be within a range from 1E15 atoms/cm³ to 5E16 atoms/cm³. In certain embodiments, the dopant concentration at the dilute nitride base-(In)GaAs back surface field interface can be within a range from 0.1E18 atoms/cm³ to 8E18 atoms/cm³. In certain embodiments, the dopant concentration increases between these two interfaces from 1E15 atoms/cm³ to 8E18 atoms/cm³. The (In)GaAs emitter 308 is p-type with a thickness within the range from 50 nm to 600 nm. The (In)GaAs emitter 308 can also be doped with Be, C or Zn, or any combination of the foregoing, at a concentration within the range from 2E17 atoms/cm³ to 8E18 atoms/cm³. The substrate 302 is n-type Ge or n-type GaAs.

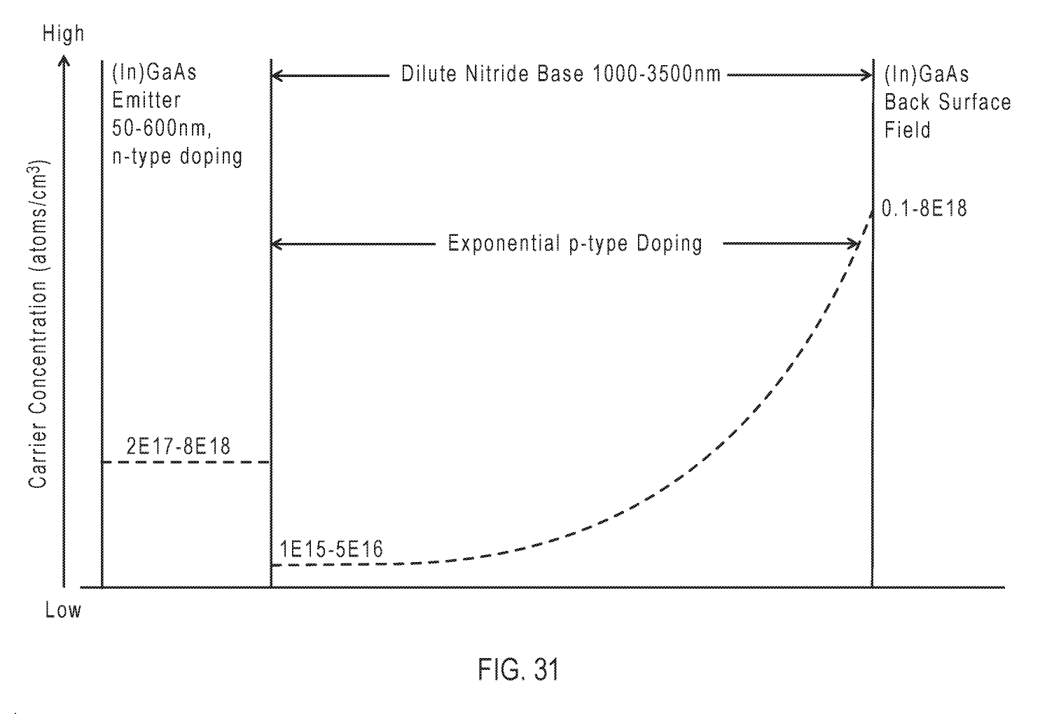

FIG. 31 shows an embodiment wherein the p-type dilute nitride base 106 comprises an exponential doping profile. The dilute nitride base 106 can be doped with Be, C, Zn, or any combination of the foregoing, making it p-type. The dilute nitride base 106 can be no more than 3,500 nm thick and can extend from the (In)GaAs emitter 108 to the (In)GaAs back surface field 104. The dilute nitride base doping profile can comprise a low dopant concentration at the (In)GaAs emitter-dilute nitride base interface and a high dopant concentration at the dilute nitride base-(In)GaAs back surface field interface. In certain embodiments, the dopant concentration increases exponentially between these two interfaces from 1E15 atoms/cm³ to 8E18 atoms/cm³. In certain embodiments, the dopant concentration at the (In)GaAs emitter-dilute nitride base interface is within the range from 1E15 atoms/cm³ to 5E16 atoms/cm³. In certain embodiments, the dopant concentration at the dilute nitride base-(In)GaAs back surface field interface is within the range from 0.1E18 atoms/cm³ to 8E18 atoms/cm³. In certain embodiments, the dopant concentration increases between these two interfaces from 1E15 atoms/cm³ to 8E18 atoms/cm³. The (In)GaAs emitter can have a thickness within the range from 50 nm to 600 nm and is doped with Si, Te, or Se, or any combination of the foregoing, making it n-type. The dopant concentration in the (In)GaAs emitter 108 can be within the range from 2E17 atoms/cm³ to 8E18 atoms/cm³. The substrate 102 can be p-type Ge or p-type GaAs.

Doped dilute nitride materials provided by the present disclosure can be incorporated as dilute nitride subcells into multijunction photovoltaic cells such as 3-junction, 4-junction, 5-junction, and 6-junction multijunction photovoltaic cells. When the dilute nitride subcell is the current limiting subcell of a multijunction cell, the efficiency of the multijunction photovoltaic cell will improve by about the same amount as the improvement in the efficiency of the dilute nitride subcell. For example, a 1% improvement in the efficiency of a rate-limiting dilute nitride subcell will result in an improvement in the multijunction photovoltaic cell efficiency of about 1%.

Seemingly small improvements in the efficiency of a dilute nitride subcell can result in significant improvements in the efficiency of a multijunction photovoltaic cell. Again, seemingly small improvements in the overall efficiency of a multijunction photovoltaic cell can result in dramatic improvements in output power, reduce the area of a photovoltaic array, and reduce costs associated with installation, system integration, and deployment.

Photovoltaic cell efficiency is important as it directly affects the photovoltaic module power output. For example, assuming a 1 m² photovoltaic panel having an overall 24% conversion efficiency, if the efficiency of multi junction photovoltaic cells used in a module is increased by 1% such as from 40% to 41% under 500 suns, the module output power will increase by about 2.7 KW.

Normally a photovoltaic cell contributes around 20% to the total cost of a photovoltaic power module. Higher photovoltaic cell efficiency means more cost-effective modules. Fewer photovoltaic devices are then needed to generate the same amount of output power, and higher power with fewer devices leads to reduces system costs, such as costs for mounting racks, hardware, wiring for electrical connections, etc. In addition, by using high efficiency photovoltaic cells, to generate the same power, less land area, fewer support structures, and lower labor costs are required for installation.

Photovoltaic modules are a significant component in spacecraft power systems. Lighter weight and smaller photovoltaic modules are always preferred because the lifting cost to launch satellites into orbit is expensive. Photovoltaic cell efficiency is especially important for space power applications to reduce the mass and fuel penalty due to large photovoltaic arrays. The higher specific power (watts generated over photovoltaic array mass), which indicates how much power one array will generate for a given launch mass, can be achieved with more efficient photovoltaic cells since the size and weight of the photovoltaic array would be less for getting the same power output.

As an example, compared to a nominal photovoltaic cell having a 30% conversion efficiency, a 1.5% increase in multijunction photovoltaic cell efficiency can result in a 4.5% increase in output power, and a 3.5% increase in multijunction photovoltaic cell efficiency can result in an increase a 11.5% increase in output power. For a satellite having a 60 kW power requirement, the use of higher efficiency subcells can result in photovoltaic cell module cost savings from $0.5 million to $1.5 million, and a reduction in photovoltaic array surface area of 6.4 m² to 15.6 m², for multijunction photovoltaic cells having increased efficiencies of 1.5% and 3.5%, respectively. The overall cost savings will be even greater when costs associated with system integration and launch are taken into consideration.

Exponentially doped dilute nitride subcells can be incorporated into multijunction photovoltaic cells. Examples of multijunction photovoltaic cells are disclosed in U.S. Application Publication No. 2013/0130431, U.S. Application Publication No. 2013/0118566, and in U.S. Application Publication No. 2017/0110613, each of which is incorporated by reference in its entirety.

GaInNAsSb semiconductor materials are advantageous as photovoltaic cell materials because the lattice constant can be varied to be substantially matched to a broad range of substrates and/or subcells formed from other than GaInNAsSb materials. The present invention includes multijunction photovoltaic cells with three or more subcells such as three-, four- and five junction subcells incorporating at least one Ga₁₋ₓInₓN_{y}As_{1-y-z}Sb_{z} subcell. For example, Ga₁₋ₓInₓN_{y}As_{1-y-z}Sb_{z}, disclosed in U.S. Application Publication No. 2010/0319764, can produce a high-quality material when substantially lattice-matched to a GaAs or Ge substrate in the composition range of 0.08≤x≤0.18, 0.025≤y≤0.04 and 0.001≤z≤0.03, with a band gap of at least 0.9 eV.

The band gaps of the Ga₁₋ₓInₓN_{y}As_{1-y-z}Sb_{z} materials can be in part tailored by varying the composition while controlling the overall composition of Sb. Thus, Ga₁₋ₓInₓN_{y}As_{1-y-z}Sb_{z} subcell with a band gap suitable for integrating with the other subcells may be fabricated while maintaining substantial lattice-matching to the other subcells. The band gaps and compositions of the Ga₁₋ₓInₓN_{y}As_{1-y-z}Sb_{z} subcells can be tailored so that the short-circuit current produced by the Ga₁₋ₓInₓN_{y}As_{1-y-z}Sb_{z} subcells will be the same as or slightly greater than the short-circuit current of the other subcells in the photovoltaic cell. Because Ga₁₋ₓInₓN_{y}As_{1-y-z}Sb_{z} materials provide high quality, lattice-matched and band gap tunable subcells, the disclosed photovoltaic cells comprising Ga₁₋ₓInₓN_{y}As_{1-y-z}Sb_{z} subcells can achieve high conversion efficiencies. The increase in efficiency is largely due to less light energy being lost as heat, as the additional subcells allow more of the incident photons to be absorbed by semiconductor materials with band gaps closer to the energy level of the incident photons. In addition, there will be lower series resistance losses in these multijunction photovoltaic cells compared with other photovoltaic cells due to the lower operating currents. At higher concentrations of sunlight, the reduced series resistance losses become more pronounced. Depending on the band gap of the bottom subcell, the collection of a wider range of photons in the solar spectrum may also contribute to the increased efficiency.

Designs of multijunction photovoltaic cells with more than three subcells in the prior art predominantly rely on metamorphic growth structures, new materials, or dramatic improvements in the quality of existing subcell materials in order to provide structures that can achieve high efficiencies. Photovoltaic cells containing metamorphic buffer layers may have reliability concerns due to the potential for dislocations originating in the buffer layers to propagate over time into the subcells, causing degradation in performance. In contrast, Ga₁₋ₓInₓN_{y}As_{1-y-z}Sb_{z} materials can be used in lattice matched photovoltaic cells with more than three subcells to attain high efficiencies while maintaining substantial lattice-matching between subcells, which is advantageous for reliability. For example, reliability testing on Ga₁₋ₓInₓN_{y}As_{1-y-z}Sb_{z} subcells provided by the present disclosure has shown that multijunction photovoltaic cells comprise a Ga₁₋ₓInₓN_{y}As_{1-y-z}Sb_{z} subcell, such devices can survive the equivalent of 390 years of on-sun operation at 100° C. with no failures. The maximum degradation observed in these subcells was a decrease in open-circuit voltage of about 1.2%.

For application in space, radiation hardness, which refers to minimal degradation in device performance when exposed to ionizing radiation including electrons and protons, is of great importance. Multijunction photovoltaic cells incorporating Ga₁₋ₓInₓN_{y}As_{1-y-z}Sb_{z} subcells provided by the present disclosure have been subjected to proton radiation testing to examine the effects of degradation in space environments. Compared to Ge-based triple junction photovoltaic cells, the results demonstrate that these Ga₁₋ₓInₓN_{y}As_{1-y-z}Sb_{z} containing devices have similar power degradation rates and superior voltage retention rates. Compared to non-lattice matched (metamorphic) triple junction photovoltaic cells, all metrics are superior for Ga₁₋ₓInₓN_{y}As_{1-y-z}Sb_{z} containing devices. In certain embodiments, the photovoltaic cells include (Al) InGaP subcells to improve radiation hardness compared to (Al,In)GaAs subcells.

Due to interactions between the different elements, as well as factors such as the strain in the layer, the relationship between composition and band gap for Ga₁₋ₓInₓN_{y}As_{1-y-z}Sb_{z} is not a simple function of composition. The composition that yields a desired band gap with a specific lattice constant can be found by empirically varying the composition.

The thermal dose applied to the Ga₁₋ₓInₓN_{y}As_{1-y-z}Sb_{z} material, which is controlled by the intensity of heat applied for a given duration of time (e.g., application of a temperature of 600° C. to 900° C. for a duration of between 10 seconds to 10 hours), that a Ga₁₋ₓInₓN_{y}As_{1-y-z}Sb_{z} material receives during growth and after growth, also affects the relationship between band gap and composition. In general, the band gap increases as thermal dose increases.

As the composition is varied within the Ga₁₋ₓInₓN_{y}As_{1-y-z}Sb_{z} material system, the growth conditions need to be modified. For example, for (Al,In)GaAs, the growth temperature will increase as the fraction of Al increases and decrease as the fraction of In increases, in order to maintain the same material quality. Thus, as a composition of either the Ga₁₋ₓInₓN_{y}As_{1-y-z}Sb_{z} material or the other subcells of the multijunction photovoltaic cell is changed, the growth temperature as well as other growth conditions can be adjusted accordingly.

Schematic diagrams of the three junction, four junction, and five junction photovoltaic cells are shown FIGS. 5A, 5B, and 5C to create a complete multijunction photovoltaic cell, including an anti-reflection coating, contact layers, tunnel junction, electrical contacts and a substrate or wafer handle. As discussed herein, FIG. 6 shows an example structure with these additional elements. Further, additional elements may be present in a complete photovoltaic cell, such as buffer layers, tunnel junctions, back surface field, window, emitter, and front surface field layers.

FIG. 5A shows an example of a multijunction photovoltaic cell that has three subcells, with the bottom subcell being a Ga₁₋ₓInₓN_{y}As_{1-y-z}Sb_{z} subcell. All three subcells are substantially lattice-matched to each of the other subcells and may be interconnected by tunnel junctions, which are shown as dotted regions. The Ga₁₋ₓInₓN_{y}As_{1-y-z}Sb_{z} subcell at the bottom of the stack has the lowest band gap of the three subcells and absorbs the lowest-energy light that is converted into electricity by the photovoltaic cell. The band gap of the Ga₁₋ₓInₓN_{y}As_{1-y-z}Sb_{z} material in the bottom subcell is between 0.7 eV and 1.1 eV. The upper subcells can comprise (Al)InGaP or AlInGaP. The Ga₁₋ₓInₓN_{y}As_{1-y-z}Sb_{z} base of the Ga₁₋ₓInₓN_{y}As_{1-y-z}Sb_{z} subcells considered in FIGS. 5A-5C, FIG. 6, and FIGS. 32-37 were exponentially doped according to profiles disclosed herein.

FIG. 5B shows a multijunction photovoltaic cell that has four subcells, with the bottom subcell being a Ge subcell and an overlying subcell being a Ga₁₋ₓInₓN_{y}As_{1-y-z}Sb_{z} subcell. All four subcells are substantially lattice-matched to each other and may be interconnected by two tunnel junctions (not shown). The band gap of the Ga₁₋ₓInₓN_{y}As_{1-y-z}Sb_{z} subcell can be between 0.7 eV and 1.1 eV. The upper subcells can comprise GaAs and either (Al,In)GaAs and (Al)InGaP.

In the example shown in FIG. 5B the bottom Ge subcell could be replaced with a Ga₁₋ₓInₓN_{y}As_{1-y-z}Sb_{z} subcell forming a multijunction solar cell having two dilute nitride subcells. The band gap of the bottom Ga₁₋ₓInₓN_{y}As_{1-y-z}Sb_{z} subcell is between 0.7 eV and 1.1 eV, and the band gap of the overlying Ga₁₋ₓInₓN_{y}As_{1-y-z}Sb_{z} subcell is between 0.7 eV and 1.3 eV. The upper subcells can comprise (Al,In)GaAs and (Al)InGaP.

FIG. 5C shows an example of a multijunction photovoltaic cell that has five subcells, with the bottom subcell being a Ge subcell and with two overlying Ga₁₋ₓInₓN_{y}As_{1-y-z}Sb_{z} subcells having different bandgaps. All five subcells are substantially lattice-matched to each other and may be interconnected by two tunnel junctions (not shown). The upper subcells can comprise GaAs and either (Al,In)GaAs and (Al)InGaP.

The specific band gaps of the subcells, within the ranges given in the preceding as well as subsequent embodiments, are dictated, at least in part, by the band gap of the bottom subcell, the thicknesses of the subcell layers, and the incident spectrum of light. Although there are numerous structures in the present disclosure that will produce efficiencies exceeding those of three junction photovoltaic cells, it is not the case that any set of subcell band gaps that falls within the disclosed ranges will produce an increased photovoltaic conversion efficiency. For a certain choice of bottom subcell band gap, or alternately the band gap of another subcell, incident spectrum of light, subcell materials, and subcell layer thicknesses, there is a narrower range of band gaps for the remaining subcells that will produce efficiencies exceeding those of other three junction photovoltaic cells.

In each of the embodiments described herein, the tunnel junctions are designed to have minimal light absorption. Light absorbed by tunnel junctions is not converted into electricity by the photovoltaic cell, and thus if the tunnel junctions absorb significant amounts of light, it will not be possible for the efficiencies of the multijunction photovoltaic cells to exceed those of the best triple junction photovoltaic cells. Accordingly, the tunnel junctions must be very thin (preferably less than 40 nm) and/or be made of materials with band gaps equal to or greater than the subcells immediately above the respective tunnel junction. An example of a tunnel junction fitting these criteria is a GaAs/AlGaAs tunnel junction, where each of the GaAs and AlGaAs layers forming the tunnel junction has a thickness between 5 nm and 15 nm. The GaAs layer can be doped with Te, Se, S and/or Si, and the AlGaAs layer can be doped with C.

In each of the embodiments described and illustrated herein, additional semiconductor layers are present in order to create a photovoltaic cell device. Specifically, cap or contact layer(s), anti-reflection coating (ARC) layers and electrical contacts (also denoted as the metal grid) can be formed above the top subcell, and buffer layer(s), the substrate or handle, and bottom contacts can be formed or be present below the bottom subcell. In certain embodiments, the substrate may also function as the bottom subcell, such as in a Ge subcell. Other semiconductor layers, such as additional tunnel junctions, may also be present. Multijunction photovoltaic cells may also be formed without one or more of the elements listed above, as known to those skilled in the art.

In operation, a multijunction photovoltaic cell is configured such that the subcell having the highest band gap faces the incident photovoltaic radiation, with subcells characterized by increasingly lower band gaps situated underlying or beneath the uppermost subcell.

In the embodiments disclosed herein, each subcell may comprise several layers. For example, each subcell may comprise a window layer, an emitter, a base, and a back surface field (BSF) layer.

In operation, the window layer is the topmost layer of a subcell and faces the incident radiation. In certain embodiments, the thickness of a window layer can be, for example, from about 10 nm to about 500 nm, from about 10 nm to about 300 nm, from about 10 nm to about 150 nm, and in certain embodiments, from about 10 nm to about 50 nm. In certain embodiments, the thickness of a window layer can be, for example, from about 50 nm to about 350 nm, from about 100 nm to about 300 nm, and in certain embodiments, from about 50 nm to about 150 nm.

In certain embodiments, the thickness of an emitter layer can be, for example, from about 10 nm to about 300 nm, from about 20 nm to about 200 nm, from about 50 nm to about 200 nm, and in certain embodiments, from about 75 nm to about 125 nm.

In certain embodiments, the thickness of a base layer can be, for example, from about 0.1 μm to about 6 μm, from about 0.1 μm to about 4 μm, from about 0.1 μm to about 3 μm, from about 0.1 μm to about 2 μm, and in certain embodiments, from about 0.1 μm to about 1 μm. In certain embodiments, the thickness of a base layer can be, for example, from about 0.5 μm to about 5 μm, from about 1 μm to about 4 μm, from about 1.5 μm to about 3.5 μm, and in certain embodiments, from about 2 μm to about 3 μm.

In certain embodiments the thickness of a BSF layer can be from about 10 nm to about 500 nm, from about 50 nm to about 300 nm, and in certain embodiments, from about 50 nm to about 150 nm.

In certain embodiments, an (Al)InGaP subcell comprises a window comprising AlInP, an emitter comprising (Al)InGaP, a base comprising (Al)InGaP, and a back surface field layer comprising AlInGaP.

In certain embodiments, an (Al)InGaP subcell comprises a window comprising AlInP having a thickness from 10 nm to 50 nm, an emitter comprising (Al)InGaP having a thickness from 20 nm to 200 nm, a base comprising (Al)InGaP having a thickness from 0.1 μm to 2 μm, and a BSF layer comprising AlInGaP having a thickness from 50 nm to 300 nm.

In certain of such embodiments, an (Al)InGaP subcell is characterized by a band gap within a range from about 1.9 eV to about 2.2 eV.

In certain embodiments, an (Al,In)GaAs subcell comprises a window comprising (Al)In(Ga)P or (Al,In)GaAs, an emitter comprising (Al)InGaP or (Al,In)GaAs, a base comprising (Al,In)GaAs, and a BSF layer comprising (Al,In)GaAs or (Al)InGaP. In certain embodiments, an (Al,In)GaAs subcell comprises a window comprising (Al)InGaP having a thickness from 50 nm to 400 nm, an emitter comprising (Al,In)GaAs having a thickness from 100 nm to 200 nm, a base comprising (Al,In)GaAs having a thickness from 1 μm to 4 μm, and a BSF layer comprising (Al,In)GaAs having a thickness from 100 nm to 300 nm.

In certain embodiments, an (Al,In)GaAs subcell comprises a window comprising (Al)InGaP having a thickness from 200 nm to 300 nm, an emitter comprising (Al,In)GaAs having a thickness from 100 nm to 150 nm, a base comprising (Al,In)GaAs having a thickness from 2 μm to 3.5 μm, and a BSF layer comprising (Al,In)GaAs having a thickness from 150 nm to 250 nm.

In certain of such embodiments, an (Al,In)GaAs subcell is characterized by a band gap within a range from about 1.4 eV to about 1.7 eV.

In certain embodiments, an (Al) InGaAsP subcell comprises a window comprising (Al)In(Ga)P, an emitter comprising (Al) InGaP or (Al) InGaAsP, a base comprising (Al) InGaAsP, and a BSF layer comprising (Al,In)GaAs or (Al)InGaP. In certain embodiments, an (Al) InGaAsP subcell comprises a window comprising (Al)In(Ga)P having a thickness from 50 nm to 300 nm, an emitter comprising (Al)InGaP or (Al) InGaAsP having a thickness from 100 nm to 200 nm, a base comprising (Al) InGaAsP having a thickness from 0.5 μm to 4 μm, and a BSF layer comprising Al(In)GaAs or (Al)InGaP having a thickness from 50 nm to 300 nm.

In certain of such embodiments, an (Al)InGaAsP subcell is characterized by a band gap within a range from about 1.4 eV to about 1.8 eV.

In certain embodiments, a Ga₁₋ₓInₓN_{y}As_{1-y-z}Sb_{z} subcell comprises a window comprising (Al)InGaP or (Al,In)GaAs, an emitter comprising (In)GaAs or a Ga₁₋ₓInₓN_{y}As_{1-y-z}Sb_{z}, a base comprising a Ga₁₋ₓInₓN_{y}As_{1-y-z}Sb_{z}, and a BSF layer comprising (In)GaAs.

In certain embodiments, a Ga₁₋ₓInₓN_{y}As_{1-y-z}Sb_{z} subcell comprises a window comprising (Al)InGaP or (In)GaAs, having a thickness from 0 nm to 300 nm, an emitter comprising (In)GaAs or a Ga₁₋ₓInₓN_{y}As_{1-y-z}Sb_{z} alloy having a thickness from 100 nm to 200 nm, a base comprising a Ga₁₋ₓInₓN_{y}As_{1-y-z}Sb_{z} having a thickness from 1 μm to 4 μm, and a BSF layer comprising (In)GaAs having a thickness from 50 nm to 300 nm. In certain embodiments, a Ga₁₋ₓInₓN_{y}As_{1-y-z}Sb_{z} alloy subcell comprises an emitter comprising InGaAs or a III-AsNV alloy having a thickness from 100 nm to 150 nm, a base comprising a Ga₁₋ₓInₓN_{y}As_{1-y-z}Sb_{z} alloy having a thickness from 2 μm to 3 μm, and a BSF layer comprising (In)GaAs having a thickness from 50 nm to 200 nm.

In certain of such embodiments, a Ga₁₋ₓInₓN_{y}As_{1-y-z}Sb_{z} subcell is characterized by a band gap within a range from about 0.7 to about 1.1 eV, or within a range from about 0.9 eV to about 1.3 eV. In certain of such embodiments, the Ga₁₋ₓInₓN_{y}As_{1-y-z}Sb_{z} subcell is a GaInNAsSb subcell.

In certain of such embodiments, a Ga₁₋ₓInₓN_{y}As_{1-y-z}Sb_{z} subcell has a compressive strain of less than 0.6%, meaning that the in-plane lattice constant of the Ga₁₋ₓInₓN_{y}As_{1-y-z}Sb_{z} material in its fully relaxed state is between 0.0% and 0.6% greater than that of the substrate. In certain of such embodiments, the Ga₁₋ₓInₓN_{y}As_{1-y-z}Sb_{z} subcell contains Sb and does not contain Bi.

In certain embodiments, a Ge subcell comprises a window comprising (Al)InGaP or (Al,In)GaAs, having a thickness from 0 nm to 300 nm, an emitter comprising (Al,In)GaAs, (Al,Ga)InP, or Ga₁₋ₓInₓN_{y}As_{1-y-z}Sb_{z}, having a thickness from 10 nm to 500 nm, and a base comprising the Ge substrate. It is to be noted that multijunction photovoltaic cells may also be formed on a Ge or GaAs substrate wherein the substrate is not part of a subcell.

In certain embodiments, one or more of the subcells has an emitter and/or a base in which there is a graded doping profile. The doping profile may be linear, exponential or with other dependence on position. In certain of such embodiments, one or more of the Ga₁₋ₓInₓN_{y}As_{1-y-z}Sb_{z} subcells has an exponential or linear doping profile over part or all of the base, with the doping levels between 1E15 atoms/cm³ and 1E¹⁹ atoms/cm³, or between 1E10¹⁶ atoms/cm³ and 5E18 atoms/cm³. Further, the region of the Ga₁₋ₓInₓN_{y}As_{1-y-z}Sb_{z} base that is closest to the emitter may have constant or no doping, as disclosed, for example, in U.S. Application Publication No. 2012/0103403, which is incorporated by reference in its entirety. Examples of dopants include, for example, Be, Mg, Zn, Te, Se, Si, C, and others known in the art.

A tunnel junction may be disposed between each of the subcells. Each tunnel junction comprises two or more layers that electrically connect adjacent subcells. The tunnel junction includes a highly doped n-type layer adjacent to a highly doped p-type layer to form a p-n junction. Typically, the doping levels in a tunnel junction are between 1E18 atoms/cm³ and 1E21 atoms/cm³.

In certain embodiments, a tunnel junction comprises an n-type (Al,In)GaAs or (Al)InGaP(As) layer and a p-type (Al,In)GaAs layer. In certain embodiments the dopant of the n-type layer comprises Si and the dopant of the p-type layer comprises C. A tunnel junction may have a thickness less than about 100 nm, less than 80 nm, less than 60 nm, less than 40 nm, and in certain embodiments, less than 20 nm. For example, in certain embodiments, a tunnel junction between (Al)InGaP subcells, between an (Al)InGaP subcell and an (Al,In)GaAs or (Al)InGaAsP subcell, or between (Al,In)GaAs subcells may have a thickness less than about 30 nm, less than about 20 nm, less than about 15 nm, and in certain embodiments, less than about 12 nm. In certain embodiments, a tunnel junction separating an (Al,In)GaAs and III-AsNV alloy subcell, separating adjacent III-AsNV alloy subcells, or separating a III-AsNV alloy and a (Si,Sn)Ge or Ge subcell may have a thickness less than 100 nm, less than 80 nm, less than 60 nm, and in certain embodiments, less than 40 nm.

A multijunction photovoltaic cell may be fabricated on a substrate such as a Ge substrate. In certain embodiments, the substrate can comprise GaAs, InP, Ge, or Si. In certain embodiments, all of the subcells are substantially lattice-matched to the substrate. In certain embodiments, one or more of the layers that are included within the completed photovoltaic cell but are not part of a subcell such as, for example, anti-reflective coating layers, contact layers, cap layers, tunnel junction layers, and buffer layers, are not substantially lattice-matched to the subcells.

In certain embodiments, the multijunction photovoltaic cell comprises an anti-reflection coating overlying the uppermost subcell. The materials comprising the anti-reflection coating and the thickness of the anti-reflection coating are selected to improve the efficiency of light capture in the multijunction photovoltaic cell. In certain embodiments, one or more contact layers overlie the uppermost subcell in the regions underlying or near the metal grid. In certain embodiments, the contact layers comprise (In)GaAs and the dopant may be Si or Be.

Dilute nitride-containing multijunction photovoltaic cells such as GaInNAsSb-containing multijunction photovoltaic cells provided by the present disclosure may be incorporated into a photovoltaic power system. A photovoltaic power system can comprise one or more photovoltaic cells provided by the present disclosure such as, for example, one or more photovoltaic cells having at least three, at least four subcells or at least five subcells, including one or more GaInNAsSb subcells. In certain embodiments, the one or more photovoltaic cells have a GaInNAsSb subcell as the bottom subcell or the subcell immediately above the bottom subcell. In certain embodiments, the photovoltaic power system may be a concentrating photovoltaic system, wherein the system may also comprise mirrors and/or lenses used to concentrate sunlight onto one or more photovoltaic cells. In certain embodiments, the photovoltaic power system comprises a single or dual axis tracker. In certain embodiments, the photovoltaic power system is designed for portable applications, and in other embodiments, for grid-connected power generation. In certain embodiments, the photovoltaic power system is designed to convert a specific spectrum of light, such as AM1.5G, AM1.5D or AM0, into electricity. In certain embodiments, the photovoltaic power system may be found on satellites or other extra-terrestrial vehicles and designed for operation in space without the influence of a planetary atmosphere on the impinging light source. In certain embodiments, the photovoltaic power system may be designed for operation on astronomical bodies other than earth. In certain embodiments, the photovoltaic power system may be designed for satellites orbiting about astronomical bodies other than earth. In certain embodiments, the photovoltaic power system may be designed for roving on the surface of an astronomical body other than earth.

Photovoltaic modules are provided comprising one or more multijunction photovoltaic cells provided by the present disclosure. A photovoltaic module may comprise one or more photovoltaic cells provided by the present disclosure to include an enclosure and interconnects to be used independently or assembled with additional modules to form a photovoltaic power system. A module and/or power system may include power conditioners, power converters, inverters and other electronics to convert the power generated by the photovoltaic cells into usable electricity. A photovoltaic module may further include optics for focusing light onto a photovoltaic cell provided by the present disclosure such as in a concentrated photovoltaic module. Photovoltaic power systems can comprise one or more photovoltaic modules, such as a plurality of photovoltaic modules.

As disclosed, for example, in U.S. Application Publication No. 2017/0110613, high efficiency GaInNAsSb dilute nitride subcells have been fabricated. The efficiency of these GaInNAsSb subcells employ the doping profiles provided by the present disclosure such as, for example, exponential doping in the Ga₁₋ₓInₓN_{y}As_{1-y-z}Sb_{z} base or a combination of constant and exponential doping in the Ga₁₋ₓInₓN_{y}As_{1-y-z}Sb_{z} base.

Three-, four-, and five junction photovoltaic cells comprising at least one Ga₁₋ₓInₓN_{y}As_{1-y-z}Sb_{z} subcell have been fabricated. The ability to provide high efficiency Ga₁₋ₓInₓN_{y}As_{1-y-z}Sb_{z}-based photovoltaic cells is predicated on the ability to provide a high quality Ga₁₋ₓInₓN_{y}As_{1-y-z}Sb_{z} subcell that is lattice matched to other semiconductor layers including Ge and GaAs substrates and that can be tailored to have a band gap within the range from 0.8 eV to 1.3 eV.

Ga₁₋ₓInₓN_{y}As_{1-y-z}Sb_{z} subcells provided by the present disclosure are fabricated to provide a high efficiency. Factors that contribute to providing a high efficiency Ga₁₋ₓInₓN_{y}As_{1-y-z}Sb_{z} subcells include, for example, the band gaps of the individual subcells, which in turn depends on the semiconductor composition of the subcells, doping levels and doping profiles, thicknesses of the subcells, quality of lattice matching, defect densities, growth conditions, annealing temperatures and profiles, and impurity levels.

Various metrics can be used to characterize the quality of a GaInNAsSb subcell including, for example, the Eg/q-Voc, the efficiency over a range of irradiance energies, the open circuit voltage Voc and the short circuit current density Jsc. The open circuit voltage Voc and short circuit current Jsc can be measured on subcells having a Ga₁₋ₓInₓN_{y}As_{1-y-z}Sb_{z} base layer that is 2 μm thick or other thickness such as, for example, a thickness from 1 μm to 4 μm. Those skilled in the art would understand how to extrapolate the open circuit voltage Voc and short circuit current Jsc measured for a subcell having a particular Ga₁₋ₓInₓN_{y}As_{1-y-z}Sb_{z} base thickness to other thicknesses.

The quality of a Ga₁₋ₓInₓN_{y}As_{1-y-z}Sb_{z} subcell can be reflected by a curve of the efficiency as a function of irradiance wavelength or irradiance energy. In general, a high quality Ga₁₋ₓInₓN_{y}As_{1-y-z}Sb_{z} subcell exhibits an efficiency of at least 60%, at least 70% or at least 80% over a wide range of irradiance wavelengths. FIG. 32 shows the dependence of the efficiency as a function of irradiance wavelength/energy for Ga₁₋ₓInₓN_{y}As_{1-y-z}Sb_{z} subcells having band gaps within a range from about 0.82 eV to about 1.24 eV.

The irradiance wavelengths for which the efficiencies of the Ga₁₋ₓInₓN_{y}As_{1-y-z}Sb_{z} subcell referred to in FIG. 32 is greater than 70% and greater than 80% is summarized in Table 1.

TABLE 1
Dependence of efficiency of Ga₁₋ₓInₓN_{y}As_{1-y-z}Sb_{z} subcells.

| GaInNAsSb | | | | | |
|---|---|---|---|---|---|
| Band Gap | | Efficiency (%) | | | |
| Wavelength | Energy | Wavelength/Energy (nm/eV) | | | |
| (nm) | (eV) | >70% | | >80% | |
| 1000 | 1.24 | <900/ | 970/ | <900/ | 930/ |
| | | <1.38 | 1.27 | <1.38 | 1.33 |
| 1088 | 1.14 | <900/ | 1000/ | <900/ | 950/ |
| | | <1.38 | 1.24 | <1.38 | 1.30 |
| 1127 | 1.10 | <900/ | 1050/ | <900/ | 950/ |
| | | <1.38 | 1.18 | <1.38 | 1.30 |
| 1181 | 1.05 | <900/ | 1100/ | <900/ | 1050/ |
| | | <1.38 | 1.13 | <1.38 | 1.18 |
| 1240 | 1.00 | <900/ | 1150/ | <900/ | 1100/ |
| | | <1.38 | 1.08 | <1.38 | 1.13 |
| 1291 | 0.96 | <900/ | 1200/ | <900/ | 1100/ |
| | | <1.38 | 1.03 | <1.38 | 1.13 |
| 1512 | 0.82 | <900/ | 1250/ | <900/ | 1100/ |
| | | <1.38 | 0.99 | <1.38 | 1.13 |

The Ga₁₋ₓInₓN_{y}As_{1-y-z}Sb_{z} subcells measured in FIG. 32 exhibit high efficiencies greater than 60%, greater than 70%, or greater than 80% over a broad irradiance wavelength range. The high efficiency of these Ga₁₋ₓInₓN_{y}As_{1-y-z}Sb_{z} subcells over a broad range of irradiance wavelengths/energies is indicative of the high quality of the semiconductor material forming the Ga₁₋ₓInₓN_{y}As_{1-y-z}Sb_{z} subcell.

As shown in FIG. 32, the range of irradiance wavelengths over which a particular Ga₁₋ₓInₓN_{y}As_{1-y-z}Sb_{z} subcell exhibits a high efficiency is bounded by the band gap of a particular Ga₁₋ₓInₓN_{y}As_{1-y-z}Sb_{z} subcell. Measurements are not extended to wavelengths below 900 nm because in a practical photovoltaic cell, a Ge subcell can be used to capture and convert radiation at the shorter wavelengths. The efficiencies in FIG. 32 were measured at an irradiance of 1 sun (1,000 W/m2) with the AM1.5D spectrum at a junction temperature of 25° C., for a GaInNAsSb subcell thickness of 2 μm. One skilled in the art will understand how to extrapolate the measured efficiencies to other irradiance wavelengths/energies, subcell thicknesses, and temperatures. The efficiency was measured by scanning the spectrum of a calibrated source and measuring the current generated by the photovoltaic cell. A GaInNAsSb subcell can include a GaInNAsSb subcell base, an emitter, a back surface field and a front surface field.

The Ga₁₋ₓInₓN_{y}As_{1-y-z}Sb_{z} subcells exhibited an efficiency as follows: an efficiency of at least 70% at an irradiance energy from 1.38 eV to 1.30 eV, and an efficiency of at least 80% at an irradiance energy from 1.38 eV to 1.30 eV; an efficiency of at least 70% at an irradiance energy from 1.38 eV to 1.18 eV, and an efficiency of at least 80% at an irradiance energy from 1.38 eV to 1.30 eV; an efficiency of at least 70% at an irradiance energy from 1.38 eV to 1.10 eV, and an efficiency of at least 80% at an irradiance energy from 1.38 eV to 1.18 eV; an efficiency of at least 70% at an irradiance energy from 1.38 eV to 1.03 eV, and an efficiency of at least 80% at an irradiance energy from 1.38 eV to 1.15 eV; an efficiency of at least 70% at an irradiance energy from 1.38 eV to 0.99 eV, and an efficiency of at least 80% at an irradiance energy from 1.38 eV to 1.15 eV; or an efficiency of at least 60% at an irradiance energy from 1.38 eV to 0.92 eV, an efficiency of at least 70% at an irradiance energy from 1.38 eV to 1.03 eV, and an efficiency of at least 80% at an irradiance energy from 1.38 eV to 1.15 eV; wherein the efficiency was measured at a junction temperature of 25° C.

Ga₁₋ₓInₓN_{y}As_{1-y-z}Sb_{z} subcells having a band gap between 1.18 eV and 1.24 eV, exhibited an efficiency of at least 70% at an irradiance energy from 1.38 eV to 1.30 eV, and an efficiency of at least 80% at an irradiance energy from 1.38 eV to 1.30 eV, measured at a junction temperature of 25° C.

Ga₁₋ₓInₓN_{y}As_{1-y-z}Sb_{z} subcells having a band gap between 1.10 eV and 1.14 eV, exhibited an efficiency of at least 70% at an irradiance energy from 1.38 eV to 1.18 eV, and an efficiency of at least 80% at an irradiance energy from 1.38 eV to 1.30 eV, measured at a junction temperature of 25° C.

Ga₁₋ₓInₓN_{y}As_{1-y-z}Sb_{z} subcells having a band gap between 1.04 eV and 1.06 eV, exhibited an efficiency of at least 70% at an irradiance energy from 1.38 eV to 1.10 eV, and an efficiency of at least 80% at an irradiance energy from 1.38 eV to 1.18 eV, measured at a junction temperature of 25° C.

Ga₁₋ₓInₓN_{y}As_{1-y-z}Sb_{z} subcells having a band gap between 0.99 eV and 1.01 eV, exhibited an efficiency of at least 70% at an irradiance energy from 1.38 eV to 1.03 eV, and an efficiency of at least 80% at an irradiance energy from 1.38 eV to 1.15 eV, measured at a junction temperature of 25° C.

Ga₁₋ₓInₓN_{y}As_{1-y-z}Sb_{z} subcells having a band gap between 0.90 eV and 0.98 eV, exhibited an efficiency of at least 70% at an irradiance energy from 1.38 eV to 0.99 eV, and an efficiency of at least 80% at an irradiance energy from 1.38 eV to 1.15 eV, measured at a junction temperature of 25° C. Ga₁₋ₓInₓN_{y}As_{1-y-z}Sb_{z} subcells having a band gap between 0.80 eV and 0.86 eV, exhibited an efficiency of at least 60% at an irradiance energy from 1.38 eV to 0.92 eV, an efficiency of at least 70% at an irradiance energy from 1.38 eV to 1.03 eV, and an efficiency of at least 80% at an irradiance energy from 1.38 eV to 1.15 eV, measured at a junction temperature of 25° C.

The Ga₁₋ₓInₓN_{y}As_{1-y-z}Sb_{z} subcells also exhibited an efficiency as follows: an efficiency of at least 70% at an irradiance energy from 1.38 eV to 1.27 eV, and an efficiency of at least 80% at an irradiance energy from 1.38 eV to 1.30 eV; an efficiency of at least 70% at an irradiance energy from 1.38 eV to 1.18 eV, and an efficiency of at least 80% at an irradiance energy from 1.38 eV to 1.30 eV; an efficiency of at least 70% at an irradiance energy from 1.38 eV to 1.10 eV, and an efficiency of at least 80% at an irradiance energy from 1.38 eV to 1.18 eV; an efficiency of at least 70% at an irradiance energy from 1.38 eV to 1.03 eV, and an efficiency of at least 80% at an irradiance energy from 1.38 eV to 1.13 eV; or an efficiency of at least 60% at an irradiance energy from 1.38 eV to 0.92 eV, an efficiency of at least 70% at an irradiance energy from 1.38 eV to 1.03 eV, and an efficiency of at least 80% at an irradiance energy from 1.38 eV to 1.08 eV; wherein the efficiency is measured at a junction temperature of 25° C.

Ga₁₋ₓInₓN_{y}As_{1-y-z}Sb_{z} subcells having a band gap between 1.18 eV and 1.24 eV, exhibited an efficiency of at least 70% at an irradiance energy from 1.38 eV to 1.27 eV, and an efficiency of at least 80% at an irradiance energy from 1.38 eV to 1.30 eV, measured at a junction temperature of 25° C.

Ga₁₋ₓInₓN_{y}As_{1-y-z}Sb_{z} subcells having a band gap between 1.10 eV and 1.14 eV, exhibited an efficiency of at least 70% at an irradiance energy from 1.38 eV to 1.18 eV, and an efficiency of at least 80% at an irradiance energy from 1.38 eV to 1.30 eV, measured at a junction temperature of 25° C.

Ga₁₋ₓInₓN_{y}As_{1-y-z}Sb_{z} subcells having a band gap between 1.04 eV and 1.06 eV, exhibited an efficiency of at least 70% at an irradiance energy from 1.38 eV to 1.10 eV, and an efficiency of at least 80% at an irradiance energy from 1.38 eV to 1.18 eV, measured at a junction temperature of 25° C.

Ga₁₋ₓInₓN_{y}As_{1-y-z}Sb_{z} subcells having a band gap between 0.94 eV and 0.98 eV, exhibited an efficiency of at least 70% at an irradiance energy from 1.38 eV to 1.03 eV, and an efficiency of at least 80% at an irradiance energy from 1.38 eV to 1.13 eV, measured at a junction temperature of 25° C.

Ga₁₋ₓInₓN_{y}As_{1-y-z}Sb_{z} subcells having a band gap between 0.80 eV and 0.90 eV, exhibited an efficiency of at least 60% at an irradiance energy from 1.38 eV to 0.92 eV, an efficiency of at least 70% at an irradiance energy from 1.38 eV to 1.03 eV, and an efficiency of at least 80% at an irradiance energy from 1.38 eV to 1.08 eV, measured ata junction temperature of 25° C.

The Ga₁₋ₓInₓN_{y}As_{1-y-z}Sb_{z} subcells exhibited an Eg/q-Voc of at least 0.55 V, at least 0.60 V, or at least 0.65 V over each respective range of irradiance energies listed in the preceding paragraphs. The Ga₁₋ₓInₓN_{y}As_{1-y-z}Sb_{z} subcells exhibited an Eg/q-Voc within the range of 0.55 V to 0.70 V over each respective range of irradiance energies listed in the preceding paragraphs.

A Ga₁₋ₓInₓN_{y}As_{1-y-z}Sb_{z} subcell can be characterized by a band gap of about 1.24 eV, an efficiency greater than 70% at irradiance energies from about 1.27 eV to about 1.38 eV and an efficiency greater than 80% at irradiance energies from about 1.33 eV to about 1.38 eV.

A Ga₁₋ₓInₓN_{y}As_{1-y-z}Sb_{z} subcell can be characterized by a band gap of about 1.14 eV, an efficiency greater than 70% at irradiance energies from about 1.24 eV to about 1.38 eV and an efficiency greater than 80% at irradiance energies from about 1.30 eV to about 1.38 eV.

A Ga₁₋ₓInₓN_{y}As_{1-y-z}Sb_{z} subcell can be characterized by a band gap of about 1.10 eV, an efficiency greater than 70% at irradiance energies from about 1.18 eV to about 1.38 eV and an efficiency greater than 80% at irradiance energies from about 1.30 eV to about 1.38 eV.

A Ga₁₋ₓInₓN_{y}As_{1-y-z}Sb_{z} subcell can be characterized by a band gap of about 1.05 eV, an efficiency greater than 70% at irradiance energies from about 1.13 eV to about 1.38 eV and an efficiency greater than 80% at irradiance energies from about 1.18 eV to about 1.38 eV.

A Ga₁₋ₓInₓN_{y}As_{1-y-z}Sb_{z} subcell can be characterized by a band gap of about 1.00 eV, an efficiency greater than 70% at irradiance energies from about 1.08 eV to about 1.38 eV and an efficiency greater than 80% at irradiance energies from about 1.13 eV to about 1.38 eV.

A Ga₁₋ₓInₓN_{y}As_{1-y-z}Sb_{z} subcell can be characterized by a band gap of about 0.96 eV, an efficiency greater than 70% at irradiance energies from about 1.03 eV to about 1.38 eV and an efficiency greater than 80% at irradiance energies from about 1.13 eV to about 1.38 eV.

A Ga₁₋ₓInₓN_{y}As_{1-y-z}Sb_{z} subcell can be characterized by a band gap of about 0.82 eV, an efficiency greater than 70% at irradiance energies from about 0.99 eV to about 1.38 eV and an efficiency greater than 80% at irradiance energies from about 1.13 eV to about 1.38 eV.

The quality of a Ga₁₋ₓInₓN_{y}As_{1-y-z}Sb_{z} subcell is reflected in a high short circuit current density Jsc, a low open circuit voltage Voc, a high fill factor, and a high efficiency over a broad range of irradiance wavelengths/energies.

These parameters are provided for certain Ga₁₋ₓInₓN_{y}As_{1-y-z}Sb_{z} subcells having a band gap from 0.907 eV to 1.153 eV in Table 2.

TABLE 2
Properties of certain Ga₁₋ₓInₓN_{y}As_{1-y-z}Sb_{z} subcells.

| Ga₁₋ₓInₓN_{y}As_{1-y-z}Sb_{z} | | | | | | Eg/q- | | | Base |
|---|---|---|---|---|---|---|---|---|---|
| Mole Fraction | | | | Jsc | Voc | Voc | FF | PL BG | thickness |
| Subcell | In(x) | N(y) | Sb(z) | (mA · cm²) | (V) | (V) | (%) | (eV) | (μm) |
| A | 6.8-7.8 | 1.0-1.7 | 0.4-0.8 | 9.72 | 0.53 | 0.623 | 0.75 | 1.153 | 2 |
| B | 7.9 | 1.7 | 0.7-0.8 | 9.6 | 0.48 | 0.633 | 0.74 | 1.113 | 2 |
| C | 7.8 | 1.82 | 0.4-0.8 | 9.8 | 0.46 | 0.655 | 0.73 | 1.115 | 2 |
| D | 17-18 | 4.3-4.8 | 1.2-1.6 | 15.2 | 0.315 | 0.592 | 0.62 | 0.907 | 2 |

In Table 2, FF refers to the fill factor and PL BG refers to the band gap as measured using photoluminescence.

For each of the Ga₁₋ₓInₓN_{y}As_{1-y-z}Sb_{z} subcells presented in Table 2, the efficiency (EQE) was about 87% and the efficiency was about 89% at a junction temperature of 25° C. The dependence of the efficiencies as a function of irradiance energy for subcells B, C, and D. Ga₁₋ₓInₓN_{y}As_{1-y-z}Sb_{z} subcells are shown in FIGS. 27A, 27B, and 27C, respectively. The efficiencies are greater than about 70% at irradiance energies from about 1.15 eV to about 1.55 eV (1078 nm to 800 nm).

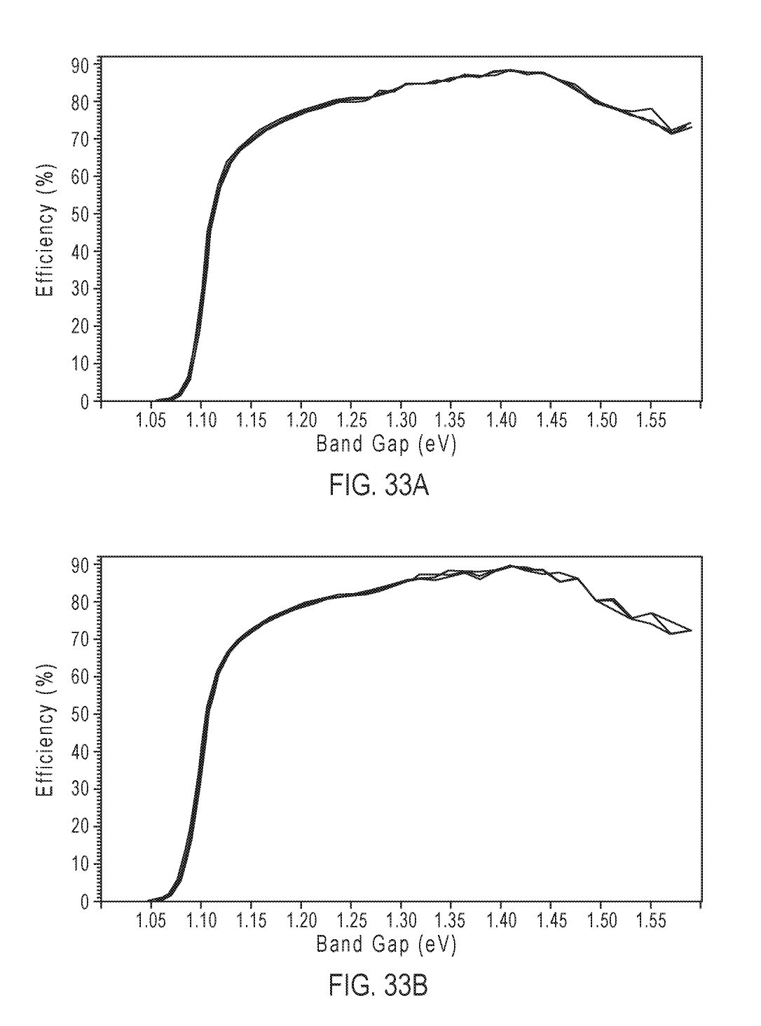

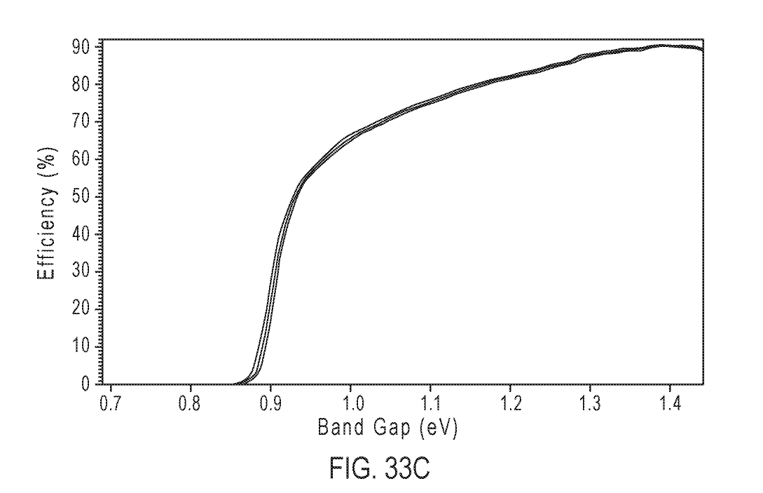

The efficiencies for Ga₁₋ₓInₓN_{y}As_{1-y-z}Sb_{z} subcells B, C, and D are presented in graphical form in FIGS. 33A, 33B, and 33C and are summarized in Table 3.

TABLE 3
Composition and efficiencies of Ga₁₋ₓInₓN_{y}As_{1-y-z}
Sb_{z} subcells as a function of irradiance energy.

| | | | | Band | | | | | | | |
|---|---|---|---|---|---|---|---|---|---|---|---|
| Ga₁₋ₓInₓN_{y}As_{1-y-z}Sb_{z} | | | | Gap | Efficiency (%) at Irradiance Energy (eV) | | | | | | |
| Mole Fraction | | | | (eV) | 0.95 | 1.05 | 1.15 | 1.25 | 1.35 | 1.45 | 1.55 |
| Subcell | In(x) | N(y) | Sb(z) | — | eV | eV | eV | eV | eV | eV | eV |
| B | 7.9 | 1.7 | 0.7-0.8 | 1.113 | — | — | 70 | 80 | 85 | 85 | 77 |
| C | 7.8 | 1.82 | 0.4-0.8 | 1.115 | — | — | 72 | 82 | 87 | 86 | 77 |
| D | 17-18 | 4.3-4.8 | 1.2-1.6 | 0.907 | 57 | 73 | 81 | 87 | 92 | 92 | — |

As shown in FIGS. 33A, 33B, and 33C, and in Table 3, Ga₁₋ₓInₓN_{y}As_{1-y-z}Sb_{z} subcells having a band gap of about 1.11 eV exhibit an efficiency greater than 70% over a range of irradiance energies from about 1.15 eV to at least 1.55 eV, and an efficiency greater than 80% over a range of irradiance energies from about 1.25 eV to about 1.45 eV.

Also, as shown in FIGS. 33A, 33B, and 33C, and in Table 3, Ga₁₋ₓInₓN_{y}As_{1-y-z}Sb_{z} subcells having a band gap of about 0.91 eV exhibit an efficiency greater than 70% over a range of irradiance energies from about 1.05 eV to at least 1.45 eV, and an efficiency greater than 80% over a range of irradiance energies from about 1.15 eV to at least 1.45 eV.

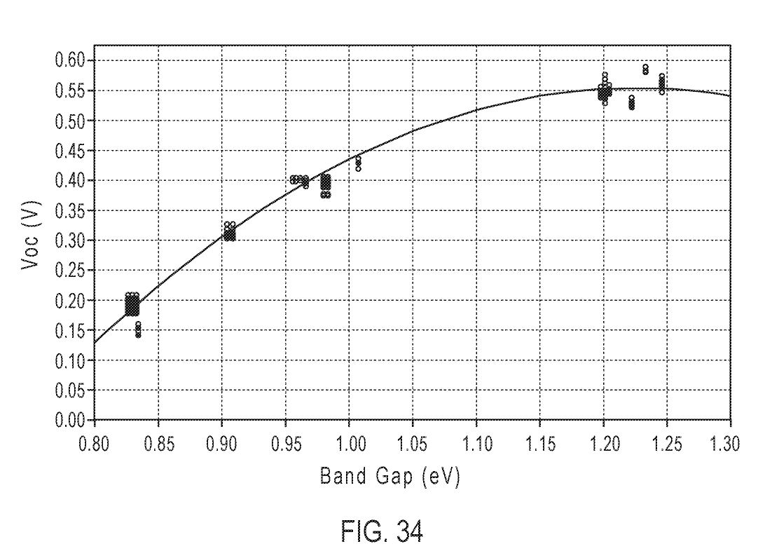

The quality of the Ga₁₋ₓInₓN_{y}As_{1-y-z}Sb_{z} compositions provided by the present disclosure is also reflected in the low open circuit voltage Voc, which depends in part on the band gap of the Ga₁₋ₓInₓN_{y}As_{1-y-z}Sb _{z} composition. The dependence of the open circuit voltage Voc with the band gap of the Ga₁₋ₓInₓN_{y}As_{1-y-z}Sb_{z} composition is shown in FIG. 34. As shown in FIG. 34, the open circuit voltage Voc changes from about 0.2 V for a Ga₁₋ₓInₓN_{y}As_{1-y-z}Sb_{z} composition with a band gap of about 0.85 eV, to an open circuit voltage Voc of about 0.5 V for a Ga₁₋ₓInₓN_{y}As_{1-y-z}Sb_{z} composition with a band gap of about 1.2 eV.

Ga₁₋ₓInₓN_{y}As_{1-y-z}Sb_{z} subcells exhibiting a band gap from 0.90 eV to 1.2 eV can have values for x, y, and z of 0.010≤x≤0.18, 0.015≤y≤0.083, 0.004≤z≤0.018. A summary of the element content, band gap, short circuit current density Jsc and open circuit voltage Voc for certain Ga₁₋ₓInₓN_{y}As_{1-y-z}Sb_{z} subcells is presented in Table 4.

TABLE 4
Composition and properties of Ga₁₋ₓInₓN_{y}As_{1-y-z}Sb_{z} subcells.

| | In (x) | N (y) | Sb (z) | Band Gap (eV) | Jsc (mA/cm²) | Voc (V) |
|---|---|---|---|---|---|---|
| D | 0.17-0.18 | 0.043-0.048 | 0.012-0.016 | 0.907 | 15.2 | 0.315 |
| E | 0.12-0.14 | 0.030-0.035 | 0.007-0.014 | 0.96-0.97 | — | — |
| F | 0.13 | 0.032 | 0.007-0.014 | 0.973 | — | — |
| B | 0.079 | 0.017 | 0.007-0.008 | 1.113 | 9.6 | 0.48 |
| C | 0.078 | 0.0182 | 0.004-0.008 | 1.115 | 9.8 | 0.46 |
| G | 0.083 | 0.018 | 0.013 | 1.12 | 9.7 | 0.49 |
| H | 0.079 | 0.022 | 0.013 | 1.12 | 13.12 | 0.63 |
| A | 0.068-0.078 | 0.010-0.017 | 0.004-0.008 | 1.153-1.157 | 9.72 | 0.53 |
| I | 0.05 | 0.013 | 0.018 | 1.16 | 6.57 | 0.54 |
| J | 0.035 | 0.014 | 0.018 | 1.2 | 6.32 | 0.55 |
| K | 0.028 | 0.016 | 0.007 | 1.2 | — | — |

In Table 3, the short circuit current density Jsc and open circuit voltage Voc were measured using a 1 sun AM1.5D spectrum at a junction temperature of 25° C. The Ga₁₋ₓInₓN_{y}As_{1-y-z}Sb_{z} subcells were 2 μm thick.

In certain embodiments, a Ga₁₋ₓInₓN_{y}As_{1-y-z}Sb_{z} subcell can be characterized by a Eg/q-Voc equal to or greater than 0.55 V measured using a 1 sun AM1.5D spectrum at a junction temperature of 25° C.

In certain embodiments, a Ga₁₋ₓInₓN_{y}As_{1-y-z}Sb_{z} subcell can be characterized by a Eg/q-Voc from 0.4 V to 0.7 V measured using a 1 sun AM1.5D spectrum at a junction temperature of 25° C.

In certain embodiments, a Ga₁₋ₓInₓN_{y}As_{1-y-z}Sb_{z} subcell can have values for x, y, and z of 0.016≤x≤0.19, 0.040≤y≤0.051, and 0.010≤z≤0.018; a band gap within the range from 0.89 eV to 0.92 eV; a short circuit current density Jsc greater than 15 mA/cm²; and an open circuit voltage Voc greater than 0.3 V. In such embodiments, the Ga₁₋ₓInₓN_{y}As_{1-y-z}Sb_{z} subcells can exhibit an efficiency of at least 70% at an irradiance energy from 1.38 eV to 1.03 eV, and an efficiency of at least 80% at an irradiance energy from 1.38 eV to 1.13 eV, measured at a junction temperature of 25° C.

In certain embodiments, a Ga₁₋ₓInₓN_{y}As_{1-y-z}Sb_{z} subcell can have values for x, y, and z of 0.010≤x≤0.16, 0.028≤y≤0.037, and 0.005≤z≤0.016; and a band gap within the range from 0.95 eV to 0.98 eV. In such embodiments, the Ga₁₋ₓInₓN_{y}As_{1-y-z}Sb_{z} subcells can exhibit an efficiency of at least 70% at an irradiance energy from 1.38 eV to 1.03 eV, and an efficiency of at least 80% at an irradiance energy from 1.38 eV to 1.13 eV, measured at a junction temperature of 25° C.

In certain embodiments, a Ga₁₋ₓInₓN_{y}As_{1-y-z}Sb_{z} subcell can have values for x, y, and z of 0.075≤x≤0.081, 0.040≤y≤0.051, and 0.010≤z≤0.018; a band gap within the range from 1.111 eV to 1.117 eV; a short circuit current density Jsc greater than 9 mA/cm²; and an open circuit voltage Voc greater than 0.4 V. In such embodiments, the Ga₁₋ₓInₓN_{y}As_{1-y-z}Sb_{z} subcells can exhibit an efficiency of at least 70% at an irradiance energy from 1.38 eV to 1.18 eV, and an efficiency of at least 80% at an irradiance energy from 1.38 eV to 1.30 eV, measured at a junction temperature of 25° C.

In certain embodiments, a Ga₁₋ₓInₓN_{y}As_{1-y-z}Sb_{z} subcell can have values for x, y, and z of 0.016≤x≤0.024, 0.077≤y≤0.085, and 0.011≤z≤0.015; a band gap within the range from 1.10 eV to 1.14 eV; a short circuit current density Jsc greater than 9 mA/cm²; and an open circuit voltage Voc greater than 0.4 V. In such embodiments, the Ga₁₋ₓInₓN_{y}As_{1-y-z}Sb_{z} subcells can exhibit an efficiency of at least 70% at an irradiance energy from 1.38 eV to 1.03 eV, and an efficiency of at least 80% at an irradiance energy from 1.38 eV to 1.13 eV, measured at a junction temperature of 25° C.

In certain embodiments, a Ga₁₋ₓInₓN_{y}As_{1-y-z}Sb_{z} subcell can have values for x, y, and z of 0.068≤x≤0.078, 0.010≤y≤0.017, and 0.011≤z≤0.004; a band gap within the range from 1.15 eV to 1.16 eV; a short circuit current density Jsc greater than 9 mA/cm²; and an open circuit voltage Voc greater than 0.5 V. In such embodiments, the Ga₁₋ₓInₓN_{y}As_{1-y-z}Sb_{z} subcells can exhibit an efficiency of at least 70% at an irradiance energy from 1.38 eV to 1.21 eV, and an efficiency of at least 80% at an irradiance energy from 1.38 eV to 1.30 eV, measured at a junction temperature of 25° C.

In certain embodiments, a Ga₁₋ₓInₓN_{y}As_{1-y-z}Sb_{z} subcell can have values for x, y, and z of 0.011≤x≤0.015, 0.04≤y≤0.06, and 0.016≤z≤0.020; a band gap within the range from 1.14 eV to 1.18 eV; a short circuit current density Jsc greater than 6 mA/cm²; and an open circuit voltage Voc greater than 0.5 V. In such embodiments, the Ga₁₋ₓInₓN_{y}As_{1-y-z}Sb_{z} subcells can exhibit an efficiency of at least 70% at an irradiance energy from 1.38 eV to 1.21 eV, and an efficiency of at least 80% at an irradiance energy from 1.38 eV to 1.30 eV, measured at a junction temperature of 25° C.

In certain embodiments, a Ga₁₋ₓInₓN_{y}As_{1-y-z}Sb_{z} subcell can have values for x, y, and z of 0.012≤x≤0.016, 0.033≤y≤0.037, and 0.016≤z≤0.020; a band gap within the range from 1.18 eV to 1.22 eV; a short circuit current density Jsc greater than 6 mA/cm²; and an open circuit voltage Voc greater than 0.5 V. In such embodiments, the Ga₁₋ₓInₓN_{y}As_{1-y-z}Sb_{z} subcells can exhibit an efficiency of at least 70% at an irradiance energy from 1.38 eV to 1.24 eV, and an efficiency of at least 80% at an irradiance energy from 1.38 eV to 1.30 eV, measured at a junction temperature of 25° C.

In certain embodiments, a Ga₁₋ₓInₓN_{y}As_{1-y-z}Sb_{z} subcell can have values for x, y, and z of 0.026≤x≤0.030, 0.024≤y≤0.018, and 0.005≤z≤0.009; a band gap within the range from 1.18 eV to 1.22 eV. In such embodiments, the Ga₁₋ₓInₓN_{y}As_{1-y-z}Sb_{z} subcells can exhibit an efficiency of at least 70% at an irradiance energy from 1.38 eV to 1.24 eV, and an efficiency of at least 80% at an irradiance energy from 1.38 eV to 1.30 eV, measured at a junction temperature of 25° C.

In certain embodiments, a Ga₁₋ₓInₓN_{y}As_{1-y-z}Sb_{z} subcell can have values for x, y, and z wherein 0.075≤x≤0.082, 0.016≤y≤0.019, and 0.004≤z≤0.010, and the subcell can be characterized by a band gap within the range from 1.12 eV to 1.16 eV; a short circuit current density Jsc of at least 9.5 mA/cm²; and an open circuit voltage Voc of at least 0.40 V, wherein the Jsc and the Voc are measured using a 1 sun AM1.5D spectrum at a junction temperature of 25° C. In such embodiments, the Ga₁₋ₓInₓN_{y}As_{1-y-z}Sb_{z} subcells can exhibit an efficiency of at least 70% at an irradiance energy from 1.38 eV to 1.24 eV, and an efficiency of at least 80% at an irradiance energy from 1.38 eV to 1.30 eV, measured at a junction temperature of 25° C.

In certain embodiments, a Ga₁₋ₓInₓN_{y}As_{1-y-z}Sb_{z} subcell can have values for x, y, and z wherein 0.011≤x≤0.016, 0.02≤y≤0.065, and 0.016≤z≤0.020, and the subcell can be characterized by a band gap within the range from 1.14 eV to 1.22 eV; a short circuit current density Jsc of at least 6 mA/cm²; and an open circuit voltage Voc of at least 0.50 V, wherein the Jsc and the Voc are measured using a 1 sun AM1.5D spectrum at a junction temperature of 25° C. In such embodiments, the Ga₁₋ₓInₓN_{y}As_{1-y-z}Sb_{z} subcells can exhibit an efficiency of at least 70% at an irradiance energy from 1.38 eV to 1.27 eV, and an efficiency of at least 80% at an irradiance energy from 1.38 eV to 1.34 eV, measured at a junction temperature of 25° C.

In certain embodiments, a Ga₁₋ₓInₓN_{y}As_{1-y-z}Sb_{z} subcell can have values for x, y, and z wherein 0.016≤x≤0.0.024, 0.077≤y≤0.085, and 0.010≤z≤0.016, and the subcell can be characterized by a band gap within the range from 1.118 eV to 1.122 eV; a short circuit current density Jsc of at least 9 mA/cm²; and an open circuit voltage Voc of at least 0.40 V, wherein the Jsc and the Voc are measured using a 1 sun AM1.5D spectrum at a junction temperature of 25° C. In such embodiments, the Ga₁₋ₓInₓN_{y}As_{1-y-z}Sb_{z} subcells can exhibit an efficiency of at least 70% at an irradiance energy from 1.38 eV to 1.21 eV, and an efficiency of at least 80% at an irradiance energy from 1.38 eV to 1.30 eV, measured at a junction temperature of 25° C.

In certain embodiments, a Ga₁₋ₓInₓN_{y}As_{1-y-z}Sb_{z} subcell can be characterized by a band gap within the range from 0.8 eV to 1.3 eV; and values for x, y, and z of 0.03≤x≤0.19, 0.008≤y≤0.055, and 0.001≤z≤0.05.

In certain embodiments, a Ga₁₋ₓInₓN_{y}As_{1-y-z}Sb_{z} subcell can have 0.06≤x≤0.09, 0.01≤y≤0.025, and 0.004≤z≤0.014, and the subcell can be characterized by, a band gap within the range from 1.12 eV to 1.16 eV; a short circuit current density Jsc equal to or greater than 9.5 mA/cm²; and an open circuit voltage Voc equal to or greater than 0.40 V, wherein the Jsc and the Voc are measured using a 1 sun AM1.5D spectrum at a junction temperature of 25° C. In such embodiments, the Ga₁₋ₓInₓN_{y}As_{1-y-z}Sb_{z} subcells can exhibit an efficiency of at least 70% at an irradiance energy from 1.38 eV to 1.21 eV, and an efficiency of at least 80% at an irradiance energy from 1.38 eV to 1.30 eV, measured at a junction temperature of 25° C.

In certain embodiments, a Ga₁₋ₓInₓN_{y}As_{1-y-z}Sb_{z} subcell can have values of 0.004≤x≤0.08, 0.008≤y≤0.02, and 0.004≤z≤0.014, and the subcell can be characterized by, a band gap within the range from 1.14 eV to 1.22 eV; a short circuit current density Jsc equal to or greater than 6 mA/cm²; and an open circuit voltage Voc equal to or greater than 0.50 V, wherein the Jsc and the Voc are measured using a 1 sun AM1.5D spectrum at a junction temperature of 25° C. In such embodiments, the Ga₁₋ₓInₓN_{y}As_{1-y-z}Sb_{z} subcells can exhibit an efficiency of at least 70% at an irradiance energy from 1.38 eV to 1.27 eV, and an efficiency of at least 80% at an irradiance energy from 1.38 eV to 1.30 eV, measured at a junction temperature of 25° C.

In certain embodiments, a Ga₁₋ₓInₓN_{y}As_{1-y-z}Sb_{z} subcell can have values of 0.06≤x≤0.09, 0.01≤y≤0.03, and 0.004≤z≤0.014, and the subcell can be characterized by, a band gap within the range from 1.118 eV to 1.122 eV; a short circuit current density Jsc equal to or greater than 9 mA/cm²; and an open circuit voltage Voc equal to or greater than 0.40 V, wherein the Jsc and the Voc are measured using a 1 sun AM1.5D spectrum at a junction temperature of 25° C. In such embodiments, the Ga₁₋ₓInₓN_{y}As_{1-y-z}Sb_{z} subcells can exhibit an efficiency of at least 70% at an irradiance energy from 1.38 eV to 1.21 eV, and an efficiency of at least 80% at an irradiance energy from 1.38 eV to 1.30 eV, measured at a junction temperature of 25° C.

Multijunction photovoltaic cells provided by the present disclosure can comprise at least one subcell comprising a Ga₁₋ₓInₓN_{y}As_{1-y-z}Sb_{z} semiconductor material or subcell provided by the present disclosure, and wherein each of the subcells is lattice matched to each of the other subcells. Such multijunction photovoltaic cells can comprise three junctions, four junctions, five junctions, or six junctions, in which at least one of the junctions or subcells comprises a Ga₁₋ₓInₓN_{y}As_{1-y-z}Sb_{z} semiconductor material provided by the present disclosure. In certain embodiments, a multijunction photovoltaic cell comprises one subcell comprising a Ga₁₋ₓInₓN_{y}As_{1-y-z}Sb_{z} semiconductor material provided by the present disclosure, and in certain embodiments, two subcells comprising a Ga₁₋ₓInₓN_{y}As_{1-y-z}Sb_{z} semiconductor material provided by the present disclosure. The Ga₁₋ₓInₓN_{y}As_{1-y-z}Sb_{z} semiconductor material can be selected to have a suitable band gap depending at least in part on the structure of the multijunction photovoltaic cell. The band gap of the Ga₁₋ₓInₓN_{y}As_{1-y-z}Sb_{z} semiconductor material can be, for example, within the range from about 0.80 eV to about 0.14 eV.

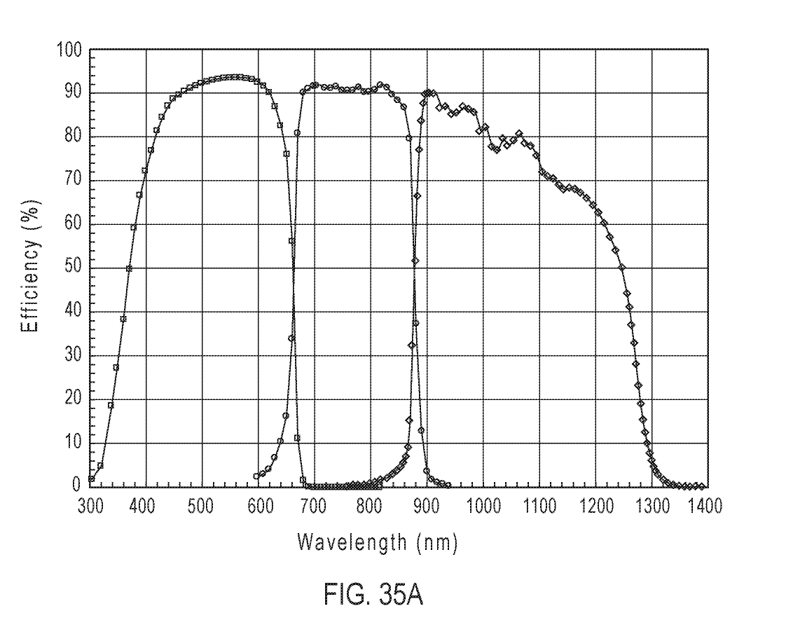

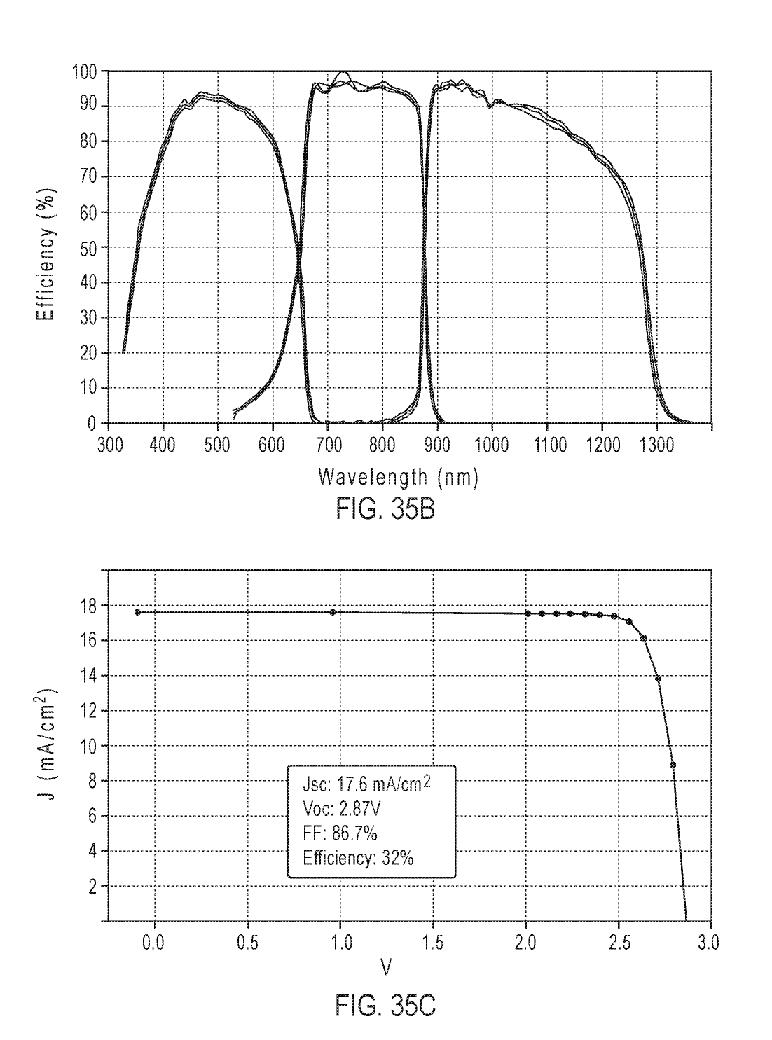

Three junction photovoltaic cells having a bottom Ga₁₋ₓInₓN_{y}As_{1-y-z}Sb_{z} subcell (J3), a second (Al,In)GaAs subcell (J2), and a top InGaP or AlInGaP subcell (J1) were fabricated. Each of the subcells is lattice matched to (Al,In)GaAs. Therefore, each of the subcells is lattice matched to each of the other subcells. The parameters for the three junction photovoltaic cells measured using a 1 sun (1,366 W/m²) AM0 spectrum at 25° C. are provided in Table 5. Examples of measurements made on three junction cells are shown in FIGS. 35A-35C.

TABLE 5
Properties of three-junction Ga₁₋ₓInₓN_{y}As_{1-y-z}Sb_{z}-containing
photovoltaic cells.

| | (Al)InGaP/(Al,In)GaAs/ |
|---|---|
| | GaInNAsSb |
| Voc (V) | 2.87 |
| Jsc (mA/cm²) | 17.6 |
| FF (%) | 86.7 |
| Efficiency (%) | 32 |
| J1 band gap (eV); (Al)InGaP | 1.9 |
| J2 band gap (eV); (Al,In)GaAs | 1.42 |
| J3 band gap (eV); GaInNAsSb | 0.96 |

The three junction photovoltaic cells using a bottom Ga₁₋ₓInₓN_{y}As_{1-y-z}Sb_{z} subcell (J3) exhibit a high Voc of about 2.9 V, a high Jsc of about 16 mA/cm², a high fill factor of about 85%, and a high efficiency of around 30%, illuminated with an AM0 spectrum. (Al)InGaP/(Al,In)GaAs/GaInNAsSb photovoltaic cells are characterized by an open circuit voltage Voc of at least 2.8 V, a short circuit current density of at least 17 mA, a fill factor of at least 80%, and an efficiency of at least 28%, measured using a 1 sun AM0 spectrum at a junction temperature of 25°.

(Al)InGaP/(Al,In)GaAs/GaInNAsSb photovoltaic cells are characterized by an open circuit voltage Voc from 2.8 V to 2.9 V, a short circuit current density from 16 mA/cm² to 18 mA/cm², a fill factor from 80% to 90% and an efficiency from 28% to 34%, illuminated with an AM0 spectrum.

(Al)InGaP/(Al,In)GaAs/GaInNAsSb photovoltaic cells are characterized by an open circuit voltage Voc from 2.85 V to 2.95 V, a short circuit current density from 15 mA/cm² to 17 mA/cm², a fill factor from 80% to 89% and an efficiency from 25% to 35%, measured using a 1 sun AM0 spectrum at a junction temperature of 25° C.

In certain embodiments, a three junction multijunction photovoltaic cell can comprise: a Ga₁₋ₓInₓN_{y}As_{1-y-z}Sb_{z} subcell characterized by a band gap from 0.9 eV to 1.1 eV; an (Al,In)GaAs subcell overlying the Ga₁₋ₓInₓN_{y}As_{1-y-z}Sb_{z} subcell, wherein the (Al,In)GaAs subcell is characterized by a band gap within the range from 1.3 eV to 1.5 eV; and an (Al)InGaP subcell overlying the (Al,In)GaAs subcell, wherein the (Al)InGaP subcell is characterized by a band gap within the range from 1.8 eV to 2.10 eV; wherein, each of the subcells is lattice matched to each of the other subcells; and the multijunction photovoltaic cell can be characterized by, an open circuit voltage Voc equal to or greater than 2.5 V; a short circuit current density Jsc equal to or greater than 12 mA/cm²; a fill factor equal to or greater than 75%; and an efficiency of at least 28%, measured using a 1 sun AM1.5D or AM0 spectrum at a junction temperature of 25° C.

In certain embodiments, a three junction multijunction photovoltaic cell can be characterized by, an open circuit voltage Voc within the range from 2.5 V to 3.2 V; a short circuit current density Jsc within the range from 15 mA/cm² to 17.9 mA/cm²; a fill factor within the range from 80% to 90%; and an efficiency within the range from 28% to 33%, measured using a 1 sun AM0 spectrum at a junction temperature of 25° C.

In certain embodiments, a three junction multijunction photovoltaic cell can be characterized by, an open circuit voltage Voc within the range from 2.55 V to 2.85 V; a short circuit current density Jsc within the range from 13.0 mA/cm² to 15 mA/cm²; a fill factor within the range from 75% to 87%; and an efficiency within the range from 28% to 35%, measured using a 1 sun AM1.5 D spectrum at a junction temperature of 25° C.

In certain embodiments, a multijunction photovoltaic cell can comprise: a Ga₁₋ₓInₓN_{y}As_{1-y-z}Sb_{z} subcell characterized by a band gap within the range from 0.9 eV to 1.05 eV; a (Al,In)GaAs subcell overlying the Ga₁₋ₓInₓN_{y}As_{1-y-z}Sb_{z} subcell, wherein the (Al,In)GaAs subcell is characterized by a band gap within the range from 1.3 eV to 1.5 eV; and an (Al)InGaP subcell overlying the (Al,In)GaAs subcell, wherein the (Al)InGaP subcell is characterized by a band gap within the range from 1.85 eV to 2.05 eV; wherein, each of the subcells is lattice matched to each of the other subcells; and the multijunction photovoltaic cell can be characterized by, an open circuit voltage Voc equal to or greater than 2.5 V; a short circuit current density Jsc equal to or greater than 15 mA/cm²; a fill factor equal to or greater than 80%; and an efficiency equal to or greater than 28%, measured using a 1 sun AM1.5D spectrum at a junction temperature of 25° C.

In certain embodiments, a three junction multijunction photovoltaic cell can be characterized by, an open circuit voltage Voc within the range from 2.6 V to 3.2 V; a short circuit current density Jsc within the range from 15.5 mA/cm² to 16.9 mA/cm²; a fill factor within the range from 81% to 91%; and an efficiency within the range from 28% to 32%, measured using a 1 sun AM0 spectrum at a junction temperature of 25° C.

In certain embodiments a four junction photovoltaic cell can have the general structure as shown in FIG. 5B, having a bottom Ge subcell (J4), an overlying GaInNAsSb subcell (J3), an overlying (Al,In)GaAs subcell (J2), and a top (Al)InGaP subcell (J1). Each of the subcells is substantially lattice matched to each of the other subcells and to the Ge subcell. The multijunction photovoltaic cells do not comprise a metamorphic buffer layer between adjacent subcells. The composition of each of the Ga₁₋ₓInₓN_{y}As_{1-y-z}Sb_{z} subcell, the (Al,In)GaAs subcell and the (Al)InGaP subcell is selected to provide lattice matching to the (Si,Sn)Ge subcell and to provide an appropriate band gap.

In certain four junction photovoltaic cells, the Ga₁₋ₓInₓN_{y}As_{1-y-z}Sb_{z} subcell (J3) can have a band gap within the range from 0.98 eV to 1.22 eV, from 0.98 eV to 1.20 eV, from 0.98 eV, to 0.18 eV, from 0.98 eV to 0.16 eV, from 0.98 eV to 0.14 eV, from 0.98 eV to 1.12 eV, from 0.99 eV to 1.11 eV, or within the range from 01.00 eV to 1.10 eV. The Ga₁₋ₓInₓN_{y}As_{1-y-z}Sb_{z} can be selected to substantially match the lattice constant of the (Si,Sn)Ge subcell and to provide a suitable band gap within a range, for example, within the range from 0.98 eV to 1.12 eV.

In certain embodiments of a four-junction photovoltaic cell, the Ga₁₋ₓInₓN_{y}As_{1-y-z}Sb_{z} subcell (J3) can have values for x, y, and z in which 0.075≤x≤0.083, 0.015≤y≤0.020, and 0.003≤z≤0.009.

In certain embodiments of a four-junction photovoltaic cell, the Ga₁₋ₓInₓN_{y}As_{1-y-z}Sb_{z} subcell (J3) can have values for x, y, and z in which 0.077≤x≤0.081, 0.0165≤y≤0.0185, and 0.004≤z≤0.009.

In certain embodiments of a four-junction photovoltaic cell, the Ga₁₋ₓInₓN_{y}As_{1-y-z}Sb_{z} subcell (J3) can have values for x, y, and z in which 0.078≤x≤0.080, 0.017≤y≤0.018, and 0.004≤z≤0.008.

In certain four junction photovoltaic cells the (Al,In)GaAs subcell (J2) can have a band gap within the range from 1.4 eV to 1.53 eV, from 1.42 eV to 1.51 eV, from 1.44 eV to 1.49 eV, or within the range from 1.46 eV to 1.48 eV.

The (Al,In)GaAs composition can be selected to match the lattice constant of the (Si,Sn)Ge subcell and to provide a suitable band gap with a range, for example, within the range from 1.4 eV to 1.53 eV.

In certain four junction photovoltaic cells the (Al)InGaP subcell (J1) can have a band gap within the range from 1.96 eV to 2.04 eV, from 1.97 eV to 2.03 eV, from 1.98 eV to 2.02 eV, or within the range from 1.99 eV to 2.01 eV. The (Al)InGaP composition is selected to match the lattice constant of the Ge subcell and to provide a suitable band gap within the range, for example, within the range within the range from 1.96 eV to 2.04 eV.

The composition of each of the subcells is selected to have an efficiency of at least 70% or at least 80% over a certain range of irradiance wavelengths or energies.

For example, a Ge subcell can exhibit an efficiency greater than 85% at irradiance energies within the range from about 0.77 eV to about 1.03 eV (about 1600 nm to 1200 nm), a Ga₁₋ₓInₓN_{y}As_{1-y-z}Sb_{z} subcell can exhibit an efficiency greater than 85% at irradiance energies within the range from 1.13 eV to 1.38 eV (1100 nm to 900 nm), a (Al,In)GaAs subcell can exhibit an efficiency greater than 90% at irradiance energies within the range from 1.51 eV to 2.00 eV (820 nm to 620 nm), and a (Al)InGaP subcell can exhibit an efficiency greater than 90% at irradiance energies within the range from 2.07 eV to 3.10 (600 nm to 400 nm).

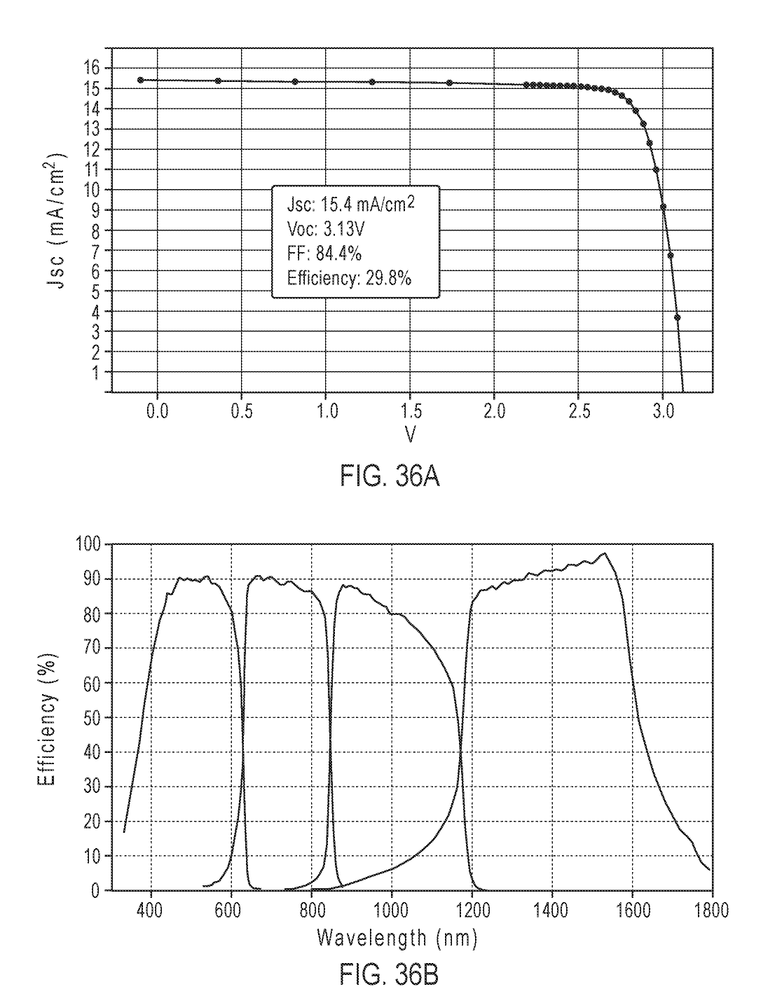

Certain properties of four junction (Si,Sn)Ge/GaInNAsSb/(Al,In)GaAs/(Al)InGaP photovoltaic cells are shown in FIG. 36A and FIG. 36B. FIG. 36A shows a IN curve for a four junction (Si,Sn)Ge/GaInNAsSb/(Al,In)GaAs/(Al)InGaP photovoltaic cell characterized by a short circuit current density Jsc of 15.4 mA/cm², an open circuit voltage Voc of 3.13 V, a fill factor of 84.4%, and an efficiency of 29.8%. The measurements were made using a 1 sun AM0 spectrum at a junction temperature of 25° C. FIG. 36B shows the efficiency for each of the four subcells as a function of irradiance wavelength. The efficiency is greater than about 90% over most of the irradiance wavelength range from about 400 nm to about 1600 nm.

Various properties of the four junction (Si,Sn)Ge/GaInNAsSb/(Al,In)GaAs/(Al)InGaP photovoltaic cells shown in FIG. 36A and FIG. 36B are provided in Table 6.

TABLE 6
Properties of four junction GaInNAsSb-containing photovoltaic cells.

| | (Al)InGaP/(Al,In)GaAs/GaInNAsSb/(Si,Sn)Ge | |
|---|---|---|
| | Four Junction Cell (1) | Four Junction Cell (2) |
| Voc (V) | 3.13 | 3.15 |
| Jsc (mA/cm²) | 15.4 | 15.2 |
| FF (%) | 84 | 85.5 |
| EQE (%) | 29.8 | 29.9 |
| J1-(Al)InGaP | — | 15.15/1.97 |
| Jsc (mA/cm²)/Eg (eV) | | |
| J2-(Al,In)GaAs | — | 15.67/1.47 |
| Jsc (mA/cm²)/Eg (eV) | | |
| J3-GaInNAsSb | — | 16/1.06 |
| Jsc (mA/cm²)/Eg (eV) | | |
| J4-(Si,Sn)Ge | — | 15.8/0.67 |
| Jsc (mA/cm²)/Eg (eV) | | |

In certain embodiments, a multijunction photovoltaic cell can comprise: a first subcell comprising (Al)InGaP; a second subcell comprising (Al,In)GaAs underlying the first subcell; a third subcell comprising Ga₁₋ₓInₓN_{y}As_{1-y-z}Sb_{z} underlying the second subcell; and a fourth subcell comprising (Si,Sn)Ge underlying the third subcell; wherein, each of the subcells is lattice matched to each of the other subcells; the third subcell is characterized by a band gap from 0.83 eV to 1.22 eV; and the third subcell is characterized by an efficiency greater than 70% at an irradiance energy throughout the range from 0.95 eV to 1.55 eV at a junction temperature of 25° C.

In certain embodiments, a multijunction photovoltaic cell can comprise Ga₁₋ₓInₓN_{y}As_{1-y-z}Sb_{z} subcell characterized by an efficiency greater than 80% at an irradiance energy throughout the range from 1.1 eV to 1.5 eV.

In certain embodiments, a four-junction multijunction photovoltaic cell comprising a Ga₁₋ₓInₓN_{y}As_{1-y-z}Sb_{z} subcell can be characterized by, an open circuit voltage Voc equal to or greater than 2.5 V; a short circuit current density Jsc equal to or greater than 8 mA/cm²; a fill factor equal to or greater than 75%; and an efficiency greater than 25%, measured using a 1 sun AM1.5D or AM0 spectrum at a junction temperature of 25° C.

In certain embodiments, a four-junction multijunction photovoltaic cell comprising a Ga₁₋ₓInₓN_{y}As_{1-y-z}Sb_{z} subcell can be characterized by, an open circuit voltage Voc equal to or greater than 3.0 V; a short circuit current density Jsc equal to or greater than 15 mA/cm²; a fill factor equal to or greater than 80%; and an efficiency greater than 25%, measured using a 1 sun AM1.5D or AM0 spectrum at a junction temperature of 25° C.

In certain embodiments, a four-junction multijunction photovoltaic cell comprising a Ga₁₋ₓInₓN_{y}As_{1-y-z}Sb_{z} subcell can be characterized by, an open circuit voltage Voc from 2.5 V to 3.5 V; a short circuit current density Jsc from 13 mA/cm² to 17 mA/cm²; a fill factor from 80% to 90%; and an efficiency from 28% to 36%, measured using a 1 sun AM0 spectrum at a junction temperature of 25° C.

In certain embodiments, a four-junction multijunction photovoltaic cell comprising a Ga₁₋ₓInₓN_{y}As_{1-y-z}Sb_{z} subcell can be characterized by, an open circuit voltage Voc from 3.0 V to 3.5 V; a short circuit current density Jsc from 8 mA/cm² to 14 mA/cm²; a fill factor from 80% to 90%; and an efficiency from 28% to 36%, measured using a 1 sun AM1.5D spectrum at a junction temperature of 25° C.

In certain embodiments, a four-junction multijunction photovoltaic cell comprising a Ga₁₋ₓInₓN_{y}As_{1-y-z}Sb_{z} subcell can comprise: a first subcell having a band gap from 1.9 eV to 2.2 eV; a second subcell having a band gap from 1.40 eV to 1.57 eV; a third subcell having a band gap from 0.98 eV to 1.2 eV; and a fourth subcell having a band gap from 0.67 eV.

In certain embodiments of a four-junction multijunction photovoltaic cell comprising a Ga₁₋ₓInₓN_{y}As_{1-y-z}Sb_{z} subcell values for x, y, and z are 0.075≤x≤0.083, 0.015≤y≤0.020, and 0.003≤z≤0.09.

In certain embodiments of a four-junction multijunction photovoltaic cell comprising a Ga₁₋ₓInₓN_{y}As_{1-y-z}Sb_{z} subcell, the Ga₁₋ₓInₓN_{y}As_{1-y-z}Sb_{z} subcell can be characterized by, an open circuit voltage Voc from 0.42 V to 0.57 V; a short circuit current density Jsc from 10 mA/cm² to 13 mA/cm²; and a band gap from 1.0 eV to 1.17 eV, measured using a 1 sun AM1.5D spectrum at a junction temperature of 25° C.

To increase the photovoltaic cell efficiency, five junction photovoltaic cells can be fabricated. Examples of the composition of photovoltaic cell stacks for three junction, four junction, and five junction photovoltaic cells are shown in FIG. 5. In some embodiments, such as five junction and six junction cells, two Ga₁₋ₓInₓN_{y}As_{1-y-z}Sb_{z} subcells may be used.

To demonstrate the feasibility of using adjacent Ga₁₋ₓInₓN_{y}As_{1-y-z}Sb_{z} subcells, four junction photovoltaic cells having a bottom Ga₁₋ₓInₓN_{y}As_{1-y-z}Sb_{z} subcell and an overlying Ga₁₋ₓInₓN_{y}As_{1-y-z}Sb_{z} subcell were fabricated and evaluated. The four junction photovoltaic cells were fabricated on a GaAs substrate. Each of the subcells is substantially lattice matched to each of the other subcells and to the GaAs substrate. The multijunction photovoltaic cells do not comprise a metamorphic buffer layer between adjacent subcells. The composition of each of the two Ga₁₋ₓInₓN_{y}As_{1-y-z}Sb_{z} subcells, the (Al,In)GaAs subcell, and the (Al)InGaP subcell is selected to lattice match to the GaAs substrate and to provide an appropriate band gap.

The four junction photovoltaic cells had a bottom Ga₁₋ₓInₓN_{y}As_{1-y-z}Sb_{z} subcell (J4), an overlying Ga₁₋ₓInₓN_{y}As_{1-y-z}Sb_{z} subcell (J3), an overlying (Al,In)GaAs subcell (J2), and a top (Al)InGaP subcell (J1). The band gaps and Jsc under a 1 sun AM1.5D or AM0 spectrum are shown in Table 7.

TABLE 7
Band gap and Jsc for four junction photovoltaic cells having two Ga₁₋ₓInₓN_{y}As_{1-y-z}Sb_{z} subcells.

| Subcell | Composition | Band Gap (eV) | Jsc (mA/cm²) |
|---|---|---|---|
| J1 | (Al)InGaP | 2.05-2.08 | 12.7-13.2 |
| J2 | (Al,In)GaAs | 1.60-1.64 | 11.8-14.2 |
| J3 | Ga₁₋ₓInₓN_{y}As_{1-y-z}Sb_{z} | 1.20-1.21 | 15.2-16.8 |
| J4 | Ga₁₋ₓInₓN_{y}As_{1-y-z}Sb_{z} | 0.88-0.89 | 12.9-13.2 |

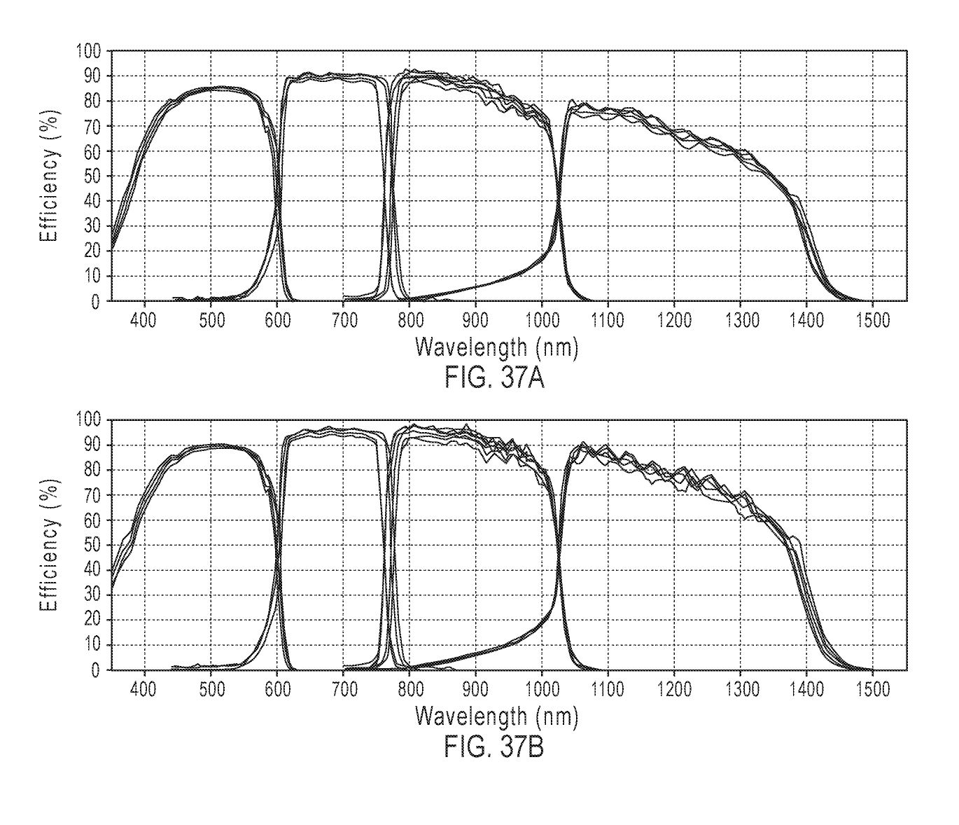

The internal and external quantum efficiencies for each of the subcells of the photovoltaic cell presented in Table 6 is shown in FIGS. 37A and 37B.

The four junction photovoltaic cells having two Ga₁₋ₓInₓN_{y}As_{1-y-z}Sb_{z} subcells exhibit internal and external quantum efficiencies over 70% throughout an irradiance wavelength range from about 400 nm (3.1 eV) to about 1300 nm (0.95 eV), and over 80% throughout an irradiance wavelength range from about 450 nm (2.75 eV) to about 1200 nm (1.03 eV).

Other four junction photovoltaic cells having two Ga₁₋ₓInₓN_{y}As_{1-y-z}Sb_{z} similar to those presented in Table 7 exhibit an open circuit voltage from about 3.67 eV to about 3.69 eV, a short circuit current density from about 9.70 mA/cm² to about 9.95 mA/cm², a fill factor from about 80% to about 85% and an external quantum efficiency from about 29.0% to about 31% measured using a 1 sun AM) or AM1.5D spectrum at a junction temperature of 25° C.

In these photovoltaic cells, the bottom Ga₁₋ₓInₓN_{y}As_{1-y-z}Sb_{z} subcell (J4) has a band gap from 0.95 eV to about 0.99 eV such as from 0.96 eV to 0.97 eV, and values for x, y, and z of 0.11≤x≤0.15, 0.030≤y≤0.034 and 0.007≤z≤0.14, and in certain embodiments, values for x, y, and z of 0.12≤x≤0.14, 0.031≤y≤0.033 and 0.007≤z≤0.14. In such embodiments, the Ga₁₋ₓInₓN_{y}As_{1-y-z}Sb_{z} subcells can exhibit an efficiency of at least 70% at an irradiance energy from 1.38 eV to 1.03 eV, and an efficiency of at least 80% at an irradiance energy from 1.38 eV to 1.15 eV, measured at a junction temperature of 25° C.

In these photovoltaic cells, the second Ga₁₋ₓInₓN_{y}As_{1-y-z}Sb_{z} subcell (J3) has a band gap from 1.1 eV to about 1.3 eV, and values for x, y, and z of 0.026≤x≤0.030, 0.014≤y≤0.018 and 0.005≤z≤0.009, and in certain embodiments, values for x, y, and z of 0.027≤x≤0.029, 0.015≤y≤0.017 and 0.006≤z≤0.008. In such embodiments, the Ga₁₋ₓInₓN_{y}As_{1-y-z}Sb_{z} subcells can exhibit an efficiency of at least 70% at an irradiance energy from 1.38 eV to 1.34 eV, and an efficiency of at least 80% at an irradiance energy from 1.38 eV to 1.34 eV, measured at a junction temperature of 25° C.

These results demonstrate the feasibility of incorporating two Ga₁₋ₓInₓN_{y}As_{1-y-z}Sb_{z} subcells into a photovoltaic cell to improve multijunction photovoltaic cell performance. As shown in FIGS. 5A-5C, to improve the collection efficiency at lower wavelengths, five junction and six junction photovoltaic cells having two Ga₁₋ₓInₓN_{y}As_{1-y-z}Sb_{z} subcells can also include a bottom active Ge subcell. Lattice matched five junction photovoltaic cells as shown in FIGS. 5A-5C are expected to exhibit external quantum efficiencies over 34% and over 36%, respectively, under 1 sun AM0 illumination at a junction temperature of 25° C.

A four-junction photovoltaic cell comprising two Ga₁₋ₓInₓN_{y}As_{1-y-z}Sb_{z} subcells can be adapted for use in five junction multijunction photovoltaic cells. The stack of (Al)InGaP/(Al,In)GaAs/Ga₁₋ₓInₓN_{y}As_{1-y-z}Sb_{z}/Ga₁₋ₓInₓN_{y}As_{1-y-z}Sb_{z} layers can overlies a Ge layer that can function as the fifth subcell. In photovoltaic cells having a Ge subcell, each of the base layers can be lattice matched to the Ge subcell.

In certain embodiments, a four- and five junction multijunction photovoltaic cell comprising two Ga₁₋ₓInₓN_{y}As_{1-y-z}Sb_{z} subcells can comprise: a first subcell comprising (Al)InGaP; a second subcell comprising (Al,In)GaAs underlying the first subcell; a third subcell comprising Ga₁₋ₓInₓN_{y}As_{1-y-z}Sb_{z} underlying the second subcell; and a fourth subcell comprising Ga₁₋ₓInₓN_{y}As_{1-y-z}Sb_{z} underlying the third subcell; wherein, each of the subcells is lattice matched to each of the other subcells; each of the fourth subcell and the third subcell is characterized by a band gap with a range from 0.83 eV to 1.3 eV; and each of the fourth subcell and the third subcell is characterized by an efficiency greater than 70% at an irradiance energy throughout the range from 0.95 eV to 1.55 eV.

In certain embodiments, a four- and five junction multijunction photovoltaic cell comprising two Ga₁₋ₓInₓN_{y}As_{1-y-z}Sb_{z} subcells, each of the two Ga₁₋ₓInₓN_{y}As_{1-y-z}Sb_{z} subcells can be characterized by an efficiency greater than 80% at an irradiance energy throughout the range from 1.1 eV to 1.5 eV.

In certain embodiments, a four- and five junction multijunction photovoltaic cell comprising two Ga₁₋ₓInₓN_{y}As_{1-y-z}Sb_{z} subcells, the multijunction photovoltaic cell can be characterized by, an open circuit voltage Voc equal to or greater than 2.8 V; a short circuit current density Jsc equal to or greater than 18 mA/cm²; a fill factor equal to or greater than 80%; and an efficiency equal to or greater than 29%, measured using a 1 sun 1.5 AM0 spectrum at a junction temperature of 25° C.

In certain embodiments, a four- and five junction multijunction photovoltaic cell comprising two Ga₁₋ₓInₓN_{y}As_{1-y-z}Sb_{z} subcells, the multijunction photovoltaic cell can comprise: a first subcell characterized by a band gap from 1.90 eV to 2.20 eV; a second subcell characterized by a band gap from 1.4 eV to 1.7 eV; a third subcell characterized by a band gap from 0.97 eV to 1.3 eV; and a fourth subcell characterized by a band gap from 0.8 eV to 1 eV.

In certain embodiments, a four- and five junction multijunction photovoltaic cell comprising two Ga₁₋ₓInₓN_{y}As_{1-y-z}Sb_{z} subcells, the multijunction photovoltaic cell can comprise: a fourth subcell comprising Ga₁₋ₓInₓN_{y}As_{1-y-z}Sb_{z} is characterized by a band gap from 0.9 eV to 1 eV; a third subcell comprising Ga₁₋ₓInₓN_{y}As_{1-y-z}Sb_{z} is characterized by a band gap from 1.1 eV to 1.3 eV; a second subcell comprising (Al,In)GaAs is characterized by a band gap from 1.5 eV to 1.7 eV; and a first subcell comprising (Al)InGaP is characterized by a band gap from 1.9 eV to 2.1 eV; wherein the multijunction photovoltaic cell can be characterized by, an open circuit voltage Voc equal to or greater than 3.5 V; a short circuit current density Jsc equal to or greater than 8 mA/cm²; a fill factor equal to or greater than 75%; and an efficiency equal to or greater than 27%, measured using a 1 sun AM1.5D spectrum at a junction temperature of 25° C.

In certain embodiments, a four- and five junction multijunction photovoltaic cell comprising two Ga₁₋ₓInₓN_{y}As_{1-y-z}Sb_{z} subcells, the multijunction photovoltaic cell can be characterized by, an open circuit voltage Voc from 3.65 V to 3.71 V; a short circuit current density Jsc from 9.7 mA/cm² to 10.0 mA/cm²; a fill factor from 80% to 85%; and an efficiency from 29% to 31%, measured using a 1 sun AM1.5D spectrum at a junction temperature of 25° C.

In certain embodiments, a four- and five junction multijunction photovoltaic cell comprising two Ga₁₋ₓInₓN_{y}As_{1-y-z}Sb_{z} subcells, the multijunction photovoltaic cell can be characterized by, an open circuit voltage Voc equal to or greater than 2.5 V; a short circuit current density Jsc equal to or greater than 8 mA/cm²; a fill factor equal to or greater than 75%; and an efficiency equal to or greater than 25%, measured using a 1 sun AM1.5D or AM0 spectrum at a junction temperature of 25° C.

In certain embodiments, a four- and five junction multijunction photovoltaic cell comprising two Ga₁₋ₓInₓN_{y}As_{1-y-z}Sb_{z} subcells, the multijunction photovoltaic cell can be characterized by, an open circuit voltage Voc from 2.5 V to 3.5 V; a short circuit current density Jsc from 13 mA/cm² to 17 mA/cm²; and a fill factor from 80% to 90%; and an efficiency from 28% to 36%, measured using a 1 sun AM0 spectrum at a junction temperature of 25° C.

In certain embodiments, a four- and five junction multijunction photovoltaic cell comprising two Ga₁₋ₓInₓN_{y}As_{1-y-z}Sb_{z} subcells, the multijunction photovoltaic cell can be characterized by, an open circuit voltage Voc from 3 V to 3.5 V; a short circuit current density Jsc from 8 mA/cm² to 14 mA/cm²; a fill factor from 80% to 90%; and an efficiency from 28% to 36%, measured using a 1 sun AM1.5D spectrum at a junction temperature of 25° C.

Five junction multijunction photovoltaic cells are also provided. A five junction multijunction photovoltaic cell an comprise two Ga₁₋ₓInₓN_{y}As_{1-y-z}Sb_{z} subcells. The two Ga₁₋ₓInₓN_{y}As_{1-y-z}Sb_{z} subcells can overlies a (Si,Sn)Ge subcell and can be lattice matched to the (Si,Sn)Ge subcell. Each of the subcells can be lattice matched to each of the other subcells and can be lattice matched to the (Si,Sn)Ge subcell. A (Si,Sn)Ge subcell can have a band gap with a range from 0.67 eV to 1.0 eV.

In certain embodiments, a five junction multijunction photovoltaic cell comprising two Ga₁₋ₓInₓN_{y}As_{1-y-z}Sb_{z} subcells can comprise: a first subcell comprising (Al)InGaP; a second subcell comprising (Al,In)GaAs underlying the first subcell; a third subcell comprising Ga₁₋ₓInₓN_{y}As_{1-y-z}Sb_{z} underlying the second subcell; a fourth subcell comprising Ga₁₋ₓInₓN_{y}As_{1-y-z}Sb_{z} underlying the third subcell; a fifth subcell comprising (Si,Sn)Ge underling the fourth subcell; wherein, each of the subcells is lattice matched to each of the other subcells; each of the fourth subcell and the third subcell is characterized by a band gap with a range from 0.83 eV to 1.3 eV; and each of the fourth subcell and the third subcell is characterized by an efficiency greater than 70% at an irradiance energy throughout the range from 0.95 eV to 1.55 eV.

In certain embodiments of a five junction multijunction photovoltaic cell each of the two Ga₁₋ₓInₓN_{y}As_{1-y-z}Sb_{z} subcells can be characterized by an efficiency greater than 80% at an illumination energy throughout the range from 1.1 eV to 1.5 eV.

In multijunction photovoltaic cells provided by the present disclosure, one or more subcells can comprise AlInGaAsP where the content each Group III and each Group V element can range from 0 to 1, and the AlInGaAsP base can be lattice matched to a substrate and to each of the other subcells in the multijunction photovoltaic cell. The band gap of an AlInGaAsP subcell can be from 1.8 eV to 2.3 eV. An AlInGaAsP subcell can comprise an (Al)InGaP subcell or an (Al,In)GaAs subcell. Multijunction photovoltaic cells provided by the present disclosure can comprise at least one Ga₁₋ₓInₓN_{y}As_{1-y-z}Sb_{z} and one or more of the other subcells can comprise an AlInGaAsP subcell.

In certain embodiments of multijunction photovoltaic cells, a subcell such as a Ga₁₋ₓInₓN_{y}As_{1-y-z}Sb_{z} and/or an AlInGaAsP subcell can be a homojunction in which the emitter and the base of a subcell comprise the same material composition and have the same band gap.

In certain embodiments of multijunction photovoltaic cells, a subcell such as a Ga₁₋ₓInₓN_{y}As_{1-y-z}Sb_{z} and/or an AlInGaAsP subcell can be a heterojunction in which the emitter and the base of a subcell comprise the same material but have a different composition such that the band gap of the emitter and the band gap of the base of a subcell are different. In certain embodiments, the band gap of the emitter is higher than the band gap of the base, and in certain embodiments, the band gap of the emitter is lower than the band gap of the base. Reverse heterojunction Ga₁₋ₓInₓN_{y}As_{1-y-z}Sb_{z} subcells are disclosed in U.S. Pat. No. 9,153,724, which is incorporated by reference in its entirety.

It should be noted that the embodiments specified above have specific profiles for doping that result in the creation of specific electric fields within the base and/or emitter of a dilute nitride solar cell. These examples are specified for illustration purposes and one skilled in the art can vary the doping profile in many other ways and configurations to achieve particular results. Recitation of these specific embodiments is not intended to limit the invention, which is set forth fully in the claims.

What is claimed is:

1. A dilute nitride subcell, comprising:
an (In)GaAs back surface field overlying the p-type substrate;
a dilute nitride base overlying the (In)GaAs back surface field, wherein,
the dilute nitride base comprises a first base portion, a second base portion, and an interface between the first base portion and the second base portion; and
the dilute nitride base comprises GaInNAsSb; and
an (In)GaAs emitter overlying the dilute nitride base, wherein,
the (In)GaAs emitter comprises an n-type doping profile characterized by a constant dopant concentration within a range from 2E17 atoms/cm³ to 8E18 atoms/cm³;
the first base portion extends from the (In)GaAs emitter to the second base portion;
the second base portion extends from the first base portion to the (In)GaAs back surface field;
the first base portion is intrinsically doped; and
the second base portion comprises a p-type dopant concentration that increases exponentially from a dopant concentration within a range from 5E15 atoms/cm³ to 5E16 atoms/cm³ at the interface to within a range from 1E18 atoms/cm³ to 8E18 atoms/cm³ at the (In)GaAs back surface field;
each of the (In)GaAs emitter, the dilute nitride base, and the (In)GaAs back surface field is lattice matched to a p-type GaAs or (Sn,Si)Ge substrate; and
the dilute nitride subcell is characterized by a band gap within a range from 0.9 eV to 1.25 eV.

2. A dilute nitride subcell of claim 1, wherein,
the (In)GaAs emitter is characterized by a thickness from 50 nm to 600 nm; and
the dilute nitride base is characterized by a thickness from 400 nm to 3,500 nm.

3. The dilute nitride subcell of claim 1, wherein,
the dilute nitride base comprises Ga₁₋ₓInₓN_{y}As_{1-y-z}Sb_{z} wherein 0.016≤x≤0.19, 0.040≤y≤0.051, and 0.010≤z≤0.018; and the dilute nitride base is characterized by a bandgap from 0.89 eV to 0.92 eV; or
the dilute nitride base comprises Ga₁₋ₓInₓN_{y}As_{1-y-z}Sb_{z} wherein 0.010≤x≤0.16, 0.028≤y≤0.037, and 0.005≤z≤0.016; and the dilute nitride base is characterized by a bandgap from 0.95 eV to 0.98 eV; or
the dilute nitride base comprises Ga₁₋ₓInₓN_{y}As_{1-y-z}Sb_{z} wherein 0.075≤x≤0.081, 0.040≤y≤0.051, and 0.010≤z≤0.018; and the dilute nitride base is characterized by a bandgap from 1.111 eV to 1.117 eV; or
the dilute nitride base comprises Ga₁₋ₓInₓN_{y}As_{1-y-z}Sb_{z} wherein 0.016≤x≤0.024, 0.077≤y≤0.085, and 0.011≤z≤0.015; and the dilute nitride base is characterized by a bandgap from 1.10 eV to 1.14 eV; or
the dilute nitride base comprises Ga₁₋ₓInₓN_{y}As_{1-y-z}Sb_{z} wherein 0.068≤x≤0.078, 0.010≤y≤0.017, and 0.011≤z≤0.004; and the dilute nitride base is characterized by a bandgap from 1.15 eV to 1.16 eV; or
the dilute nitride base comprises Ga₁₋ₓInₓN_{y}As_{1-y-z}Sb_{z} wherein 0.011≤x≤0.015, 0.04≤y≤0.06, and 0.016≤z≤0.020; and the dilute nitride base is characterized by a bandgap from 1.14 eV to 1.18 eV; or
the dilute nitride base comprises Ga₁₋ₓInₓN_{y}As_{1-y-z}Sb_{z} wherein 0.075≤x≤0.082, 0.016≤y≤0.019, and 0.004≤z≤0.010; and the dilute nitride base is characterized by a bandgap from 1.12 eV to 1.16 eV; or
the dilute nitride base comprises Ga₁₋ₓInₓN_{y}As_{1-y-z}Sb_{z} wherein 0.06≤x≤0.09, 0.01≤y≤0.025, and 0.004≤z≤0.014; and the dilute nitride base is characterized by a bandgap from 1.12 eV to 1.16 eV.

4. The dilute nitride subcell of claim 1, wherein,
the dilute nitride base comprises Ga₁₋ₓInₓN_{y}As_{1-y-z}Sb_{z} wherein 0.012≤x≤0.016, 0.033≤y≤0.037, and 0.016≤z≤0.020; and the dilute nitride base is characterized by a bandgap from 1.18 eV to 1.22 eV; or
the dilute nitride base comprises Ga₁₋ₓInₓN_{y}As_{1-y-z}Sb_{z} wherein 0.026≤x≤0.030, 0.024≤y≤0.018, and 0.005≤z≤0.009; and the dilute nitride base is characterized by a bandgap from 1.18 eV to 1.22 eV; or
the dilute nitride base comprises Ga₁₋ₓInₓN_{y}As_{1-y-z}Sb_{z} wherein 0.016≤x≤0.0.024, 0.077≤y≤0.085, and 0.010≤z≤0.016; and the dilute nitride base is characterized by a bandgap from 1.118 eV to 1.122 eV.

5. A dilute nitride subcell, comprising:
an (In)GaAs back surface field overlying the n-type substrate;
a dilute nitride base overlying the (In)GaAs back surface field, wherein,
the dilute nitride base comprises a first base portion, a second base portion, and an interface between the first base portion and the second base portion; and
the dilute nitride base comprises GaInNAsSb;
an (In)GaAs emitter overlying the dilute nitride base, wherein,
the (In)GaAs emitter comprises a p-type doping profile characterized by a constant p-type dopant concentration within a range from 2E17 atoms/cm³ to 8E18 atoms/cm³;
the first base portion extends from the (In)GaAs emitter to the second base portion;
the second base portion extends from the first base portion to the (In)GaAs back surface field;
the first base portion is intrinsically doped; and
the second base portion comprises an n-type dopant concentration that increases exponentially from a dopant concentration within a range from 5E15 atoms/cm³ to 5E16 atoms/cm³ at the interface to within a range from 0.1E18 atoms/cm³ to 8E18 atoms/cm³ at the (In)GaAs back surface field;
each of the (In)GaAs emitter, the dilute nitride base, and the (In)GaAs back surface field is lattice matched to an n-type GaAs or (Sn,Si)Ge substrate; and
the dilute nitride subcell is characterized by a band gap within a range from 0.9 eV to 1.25 eV.

6. A dilute nitride subcell of claim 5, wherein,
the (In)GaAs emitter is characterized by a thickness from 50 nm to 600 nm; and
the dilute nitride base is characterized by a thickness from 400 nm to 3,500 nm.

7. The dilute nitride subcell of claim 5, wherein,
the dilute nitride base comprises Ga₁₋ₓInₓN_{y}As_{1-y-z}Sb_{z} wherein 0.016≤x≤0.19, 0.040≤y≤0.051, and 0.010≤z≤0.018; and the dilute nitride base is characterized by a bandgap from 0.89 eV to 0.92 eV; or
the dilute nitride base comprises Ga₁₋ₓInₓN_{y}As_{1-y-z}Sb_{z} wherein 0.010≤x≤0.16, 0.028≤y≤0.037, and 0.005≤z≤0.016; and the dilute nitride base is characterized by a bandgap from 0.95 eV to 0.98 eV; or
the dilute nitride base comprises Ga₁₋ₓInₓN_{y}As_{1-y-z}Sb_{z} wherein 0.075≤x≤0.081, 0.040≤y≤0.051, and 0.010≤z≤0.018; and the dilute nitride base is characterized by a bandgap from 1.111 eV to 1.117 eV; or
the dilute nitride base comprises Ga₁₋ₓInₓN_{y}As_{1-y-z}Sb_{z} wherein 0.016≤x≤0.024, 0.077≤y≤0.085, and 0.011≤z≤0.015; and the dilute nitride base is characterized by a bandgap from 1.10 eV to 1.14 eV; or
the dilute nitride base comprises Ga₁₋ₓInₓN_{y}As_{1-y-z}Sb_{z} wherein 0.068≤x≤0.078, 0.010≤y≤0.017, and 0.011≤z≤0.004; and the dilute nitride base is characterized by a bandgap from 1.15 eV to 1.16 eV; or
the dilute nitride base comprises Ga₁₋ₓInₓN_{y}As_{1-y-z}Sb_{z} wherein 0.011≤x≤0.015, 0.04≤y≤0.06, and 0.016≤z≤0.020; and the dilute nitride base is characterized by a bandgap from 1.14 eV to 1.18 eV; or
the dilute nitride base comprises Ga₁₋ₓInₓN_{y}As_{1-y-z}Sb_{z} wherein 0.075≤x≤0.082, 0.016≤y≤0.019, and 0.004≤z≤0.010; and the dilute nitride base is characterized by a bandgap from 1.12 eV to 1.16 eV; or
the dilute nitride base comprises Ga₁₋ₓInₓN_{y}As_{1-y-z}Sb_{z} wherein 0.06≤x≤0.09, 0.01≤y≤0.025, and 0.004≤z≤0.014; and the dilute nitride base is characterized by a bandgap from 1.12 eV to 1.16 eV.

8. The dilute nitride subcell of claim 5, wherein,
the dilute nitride base comprises Ga₁₋ₓInₓN_{y}As_{1-y-z}Sb_{z} wherein 0.012≤x≤0.016, 0.033≤y≤0.037, and 0.016≤z≤0.020; and the dilute nitride base is characterized by a bandgap from 1.18 eV to 1.22 eV; or
the dilute nitride base comprises Ga₁₋ₓInₓN_{y}As_{1-y-z}Sb_{z} wherein 0.026≤x≤0.030, 0.024≤y≤0.018, and 0.005≤z≤0.009; and the dilute nitride base is characterized by a bandgap from 1.18 eV to 1.22 eV; or
the dilute nitride base comprises Ga₁₋ₓInₓN_{y}As_{1-y-z}Sb_{z} wherein 0.016≤x≤0.0.024, 0.077≤y≤0.085, and 0.010≤z≤0.016; and the dilute nitride base is characterized by a bandgap from 1.118 eV to 1.122 eV.

9. A dilute nitride subcell, comprising:
an (In)GaAs back surface field overlying the p-type substrate;
a dilute nitride base overlying the (In)GaAs back surface field, wherein
the dilute nitride base comprises GaInNAsSb;
an (In)GaAs emitter overlying the dilute nitride base,
the (In)GaAs emitter comprises a n-type doping profile characterized by a constant dopant concentration within a range from 2E17 atoms/cm³ to 8E18 atoms/cm³;
the dilute nitride base comprises a n-type doping profile that increases from an n-type dopant concentration within a range from 1E15 atoms/cm³ to 5E16 atoms/cm³ at the interface to within a range from 0.1E18 atoms/cm³ to 8E18 atoms/cm³ at the (In)GaAs back surface field, wherein,
the n-type doping profile comprises a linear profile, an exponential profile, a constant profile, a step-wise profile, or a combination of any of the foregoing;
each of the (In)GaAs emitter, the dilute nitride base, and the (In)GaAs back surface field is lattice matched to a p-type GaAs or (Sn,Si)Ge substrate; and
the dilute nitride subcell is characterized by a band gap within a range from 0.9 eV to 1.25 eV.

10. A dilute nitride subcell of claim 9, wherein,
the (In)GaAs emitter is characterized by a thickness from 50 nm to 600 nm; and
the dilute nitride base is characterized by a thickness from 400 nm to 3,500 nm.

11. The dilute nitride subcell of claim 9, wherein,
the dilute nitride base comprises Ga₁₋ₓInₓN_{y}As_{1-y-z}Sb_{z} wherein 0.016≤x≤0.19, 0.040≤y≤0.051, and 0.010≤z≤0.018; and the dilute nitride base is characterized by a bandgap from 0.89 eV to 0.92 eV; or
the dilute nitride base comprises Ga₁₋ₓInₓN_{y}As_{1-y-z}Sb_{z} wherein 0.010≤x≤0.16, 0.028≤y≤0.037, and 0.005≤z≤0.016; and the dilute nitride base is characterized by a bandgap from 0.95 eV to 0.98 eV; or
the dilute nitride base comprises Ga₁₋ₓInₓN_{y}As_{1-y-z}Sb_{z} wherein 0.075≤x≤0.081, 0.040≤y≤0.051, and 0.010≤z≤0.018; and the dilute nitride base is characterized by a bandgap from 1.111 eV to 1.117 eV; or
the dilute nitride base comprises Ga₁₋ₓInₓN_{y}As_{1-y-z}Sb_{z} wherein 0.016≤x≤0.024, 0.077≤y≤0.085, and 0.011≤z≤0.015; and the dilute nitride base is characterized by a bandgap from 1.10 eV to 1.14 eV; or
the dilute nitride base comprises Ga₁₋ₓInₓN_{y}As_{1-y-z}Sb_{z} wherein 0.068≤x≤0.078, 0.010≤y≤0.017, and 0.011≤z≤0.004; and the dilute nitride base is characterized by a bandgap from 1.15 eV to 1.16 eV; or
the dilute nitride base comprises Ga₁₋ₓInₓN_{y}As_{1-y-z}Sb_{z} wherein 0.011≤x≤0.015, 0.04≤y≤0.06, and 0.016≤z≤0.020; and the dilute nitride base is characterized by a bandgap from 1.14 eV to 1.18 eV; or
the dilute nitride base comprises Ga₁₋ₓInₓN_{y}As_{1-y-z}Sb_{z} wherein 0.075≤x≤0.082, 0.016≤y≤0.019, and 0.004≤z≤0.010; and the dilute nitride base is characterized by a bandgap from 1.12 eV to 1.16 eV; or
the dilute nitride base comprises Ga₁₋ₓInₓN_{y}As_{1-y-z}Sb_{z} wherein 0.06≤x≤0.09, 0.01≤y≤0.025, and 0.004≤z≤0.014; and the dilute nitride base is characterized by a bandgap from 1.12 eV to 1.16 eV.

12. The dilute nitride subcell of claim 9, wherein,
the dilute nitride base comprises Ga₁₋ₓInₓN_{y}As_{1-y-z}Sb_{z} wherein 0.012≤x≤0.016, 0.033≤y≤0.037, and 0.016≤z≤0.020; and the dilute nitride base is characterized by a bandgap from 1.18 eV to 1.22 eV; or
the dilute nitride base comprises Ga₁₋ₓInₓN_{y}As_{1-y-z}Sb_{z} wherein 0.026≤x≤0.030, 0.024≤y≤0.018, and 0.005≤z≤0.009; and the dilute nitride base is characterized by a bandgap from 1.18 eV to 1.22 eV; or
the dilute nitride base comprises Ga₁₋ₓInₓN_{y}As_{1-y-z}Sb_{z} wherein 0.016≤x≤0.0.024, 0.077≤y≤0.085, and 0.010≤z≤0.016; and the dilute nitride base is characterized by a bandgap from 1.118 eV to 1.122 eV.

13. A dilute nitride subcell, comprising:
an (In)GaAs back surface field overlying the n-type substrate;
a dilute nitride base overlying the (In)GaAs back surface field, wherein the dilute nitride base comprises GaInNAsSb;
an (In)GaAs emitter overlying the dilute nitride base,
wherein,
the (In)GaAs emitter comprises a p-type doping profile characterized by a constant p-type dopant concentration within a range from 2E17 atoms/cm³ to 8E18 atoms/cm³;
the dilute nitride base comprises a p-type doping profile that increases from a dopant concentration within a range from 1E15 atoms/cm³ to 5E16 atoms/cm³ at the interface to within a range from 0.1E18 atoms/cm³ to 8E18 atoms/cm³ at the dilute nitride base-(In)GaAs back surface field, wherein,
the p-type doping profile comprises a linear profile, an exponential profile, a constant profile, a step-wise profile, or a combination of any of the foregoing;
each of the (In)GaAs emitter, the dilute nitride base, and the (In)GaAs back surface field is lattice matched to a p-type GaAs or (Sn,Si)Ge substrate; and
the dilute nitride subcell is characterized by a band gap within a range from 0.9 eV to 1.25 eV.

14. A dilute nitride subcell of claim 13, wherein,
the (In)GaAs emitter is characterized by a thickness from 50 nm to 600 nm; and
the dilute nitride base is characterized by a thickness from 400 nm to 3,500 nm.

15. The dilute nitride subcell of claim 13, wherein,
the dilute nitride base comprises Ga₁₋ₓInₓN_{y}As_{1-y-z}Sb_{z} wherein 0.016≤x≤0.19, 0.040≤y≤0.051, and 0.010≤z≤0.018; and the dilute nitride base is characterized by a bandgap from 0.89 eV to 0.92 eV; or
the dilute nitride base comprises Ga₁₋ₓInₓN_{y}As_{1-y-z}Sb_{z} wherein 0.010≤x≤0.16, 0.028≤y≤0.037, and 0.005≤z≤0.016; and the dilute nitride base is characterized by a bandgap from 0.95 eV to 0.98 eV; or
the dilute nitride base comprises Ga₁₋ₓInₓN_{y}As_{1-y-z}Sb_{z} wherein 0.075≤x≤0.081, 0.040≤y≤0.051, and 0.010≤z≤0.018; and the dilute nitride base is characterized by a bandgap from 1.111 eV to 1.117 eV; or
the dilute nitride base comprises Ga₁₋ₓInₓN_{y}As_{1-y-z}Sb_{z} wherein 0.016≤x≤0.024, 0.077≤y≤0.085, and 0.011≤z≤0.015; and the dilute nitride base is characterized by a bandgap from 1.10 eV to 1.14 eV; or
the dilute nitride base comprises Ga₁₋ₓInₓN_{y}As_{1-y-z}Sb_{z} wherein 0.068≤x≤0.078, 0.010≤y≤0.017, and 0.011≤z≤0.004; and the dilute nitride base is characterized by a bandgap from 1.15 eV to 1.16 eV; or
the dilute nitride base comprises Ga₁₋ₓInₓN_{y}As_{1-y-z}Sb_{z} wherein 0.011≤x≤0.015, 0.04≤y≤0.06, and 0.016≤z≤0.020; and the dilute nitride base is characterized by a bandgap from 1.14 eV to 1.18 eV; or
the dilute nitride base comprises Ga₁₋ₓInₓN_{y}As_{1-y-z}Sb_{z} wherein 0.075≤x≤0.082, 0.016≤y≤0.019, and 0.004≤z≤0.010; and the dilute nitride base is characterized by a bandgap from 1.12 eV to 1.16 eV; or
the dilute nitride base comprises Ga₁₋ₓInₓN_{y}As_{1-y-z}Sb_{z} wherein 0.06≤x≤0.09, 0.01≤y≤0.025, and 0.004≤z≤0.014; and the dilute nitride base is characterized by a bandgap from 1.12 eV to 1.16 eV.

16. The dilute nitride subcell of claim 13, wherein,
the dilute nitride base comprises Ga₁₋ₓInₓN_{y}As_{1-y-z}Sb_{z} wherein 0.012≤x≤0.016, 0.033≤y≤0.037, and 0.016≤z≤0.020; and the dilute nitride base is characterized by a bandgap from 1.18 eV to 1.22 eV; or
the dilute nitride base comprises Ga₁₋ₓInₓN_{y}As_{1-y-z}Sb_{z} wherein 0.026≤x≤0.030, 0.024≤y≤0.018, and 0.005≤z≤0.009; and the dilute nitride base is characterized by a bandgap from 1.18 eV to 1.22 eV; or
the dilute nitride base comprises Ga₁₋ₓInₓN_{y}As_{1-y-z}Sb_{z} wherein 0.016≤x≤0.0.024, 0.077≤y≤0.085, and 0.010≤z≤0.016; and the dilute nitride base is characterized by a bandgap from 1.118 eV to 1.122 eV.

17. A multijunction photovoltaic cell comprising the dilute nitride subcell of claim 1.

18. A multijunction photovoltaic cell comprising the dilute nitride subcell of claim 5.

19. A multijunction photovoltaic cell comprising the dilute nitride subcell of claim 7.

20. A multijunction photovoltaic cell comprising the dilute nitride subcell of claim 13.
